(19) United States
(12) Patent Application Publication
(10) Pub. No.: US 2018/0074896 A1
(43) Pub. Date: Mar. 15, 2018

(54) MEMORY SYSTEM

(71) Applicant: TOSHIBA MEMORY CORPORATION, Minato-ku (JP)

(72) Inventors: Marie TAKADA, Yokohama (JP); Masanobu SHIRAKAWA, Chigasaki (JP)

(73) Assignee: TOSHIBA MEMORY CORPORATION, Minato-ku (JP)

(21) Appl. No.: 15/459,442

(22) Filed: Mar. 15, 2017

Related U.S. Application Data
(60) Provisional application No. 62/394,986, filed on Sep. 15, 2016.

(51) Int. Cl. G06F 11/10; G11C 11/56; G11C 16/34; G11C 29/52

(52) U.S. Cl. CPC G06F 11/1072; G11C 11/5628; G11C 29/52; G11C 16/3459; G11C 11/5642

(57) ABSTRACT

According to one embodiment, a system includes a memory device including a memory cell, the memory cell storing a piece of data among first to third data, each the first to third data including first and second bits, the first data having the first and second bits of a first value, the second data having the first bit of a second value and the second bit of the first value, and the third data having the first bit of the first value and the second bit of the second value. When the threshold voltage of the memory cell into which the first data is programmed is higher than a level between a first voltage corresponding to the first data and the second voltage corresponding to the second data, the device programs the third data to the memory cell.

### CROSS-REFERENCE TO RELATED APPLICATIONS

This application claims the benefit of U.S. Provisional Application No. 62/394,986, filed Sep. 15, 2016, the entire contents of which are incorporated herein by reference.

### FIELD

Embodiment herein described generally relate to a memory system.

### BACKGROUND

A memory system using a NAND flash memory is applied to various electronic devices.

### BRIEF DESCRIPTION OF THE DRAWINGS

FIG. 1 is a block diagram of a memory system according to an embodiment;

FIG. 2 is a circuit diagram of a memory cell and a sense amplifier of a memory device;

FIG. 3 is a graph showing an example of a threshold distribution that can be taken by a memory cell;

FIG. 4 is a flowchart illustrating an overview of the memory system according to an embodiment;

FIG. 5 is a flowchart illustrating an operation example of the memory system according to a first embodiment;

FIGS. 6 and 7 are timing charts illustrating an operation example of the memory system according to the first embodiment;

FIG. 8 is a waveform chart illustrating an operation example of the memory system according to the first embodiment;

FIG. 9 is a pattern diagram illustrating an operation example of the memory system according to the first embodiment;

FIG. 10 is a timing chart illustrating an operation example of the memory system according to the first embodiment;

FIG. 11 is a waveform chart illustrating an operation example of the memory system according to the first embodiment;

FIG. 12 is a pattern diagram illustrating an operation example of the memory system according to the first embodiment;

FIG. 13 is a graph showing an example of the threshold distribution that can be taken by the memory cell;

FIG. 14 is a circuit diagram of the memory cell and the sense amplifier of the memory device;

FIG. 15 is a pattern diagram illustrating an overview of the memory system according to a second embodiment;

FIG. 16 is a timing chart illustrating an operation example of the memory system according to the second embodiment;

FIG. 17 is a waveform chart illustrating an operation example of the memory system according to the second embodiment;

FIGS. 18 and 19 are timing charts illustrating the memory system according to the second embodiment;

FIG. 20 is a graph showing an example of the threshold distribution that can be taken by the memory cell;

FIG. 21 is a diagram illustrating an overview of the memory system according to a third embodiment;

FIGS. 22 and 23 are timing charts illustrating an operation example of the memory system according to the third embodiment;

FIG. 24 is a flowchart illustrating an operation example of the memory system according to a fourth embodiment;

FIG. 25 is a timing chart illustrating reading of data from the memory system;

FIGS. 26 to 29 are pattern diagrams illustrating an operation example of the memory system according to the fourth embodiment;

FIG. 30 is a timing chart illustrating an operation example of the memory system according to a fourth embodiment;

FIGS. 31 to 33 are pattern diagrams illustrating an operation example of the memory system according to the fourth embodiment;

FIG. 34 is a flowchart of an operation example of the memory system according to a fifth embodiment;

FIG. 35 is a timing chart illustrating an operation example of the memory system according to the fifth embodiment;

FIGS. 36 to 47 are diagrams illustrating an operation example of the memory system according to the fifth embodiment;

FIG. 48 is a timing chart illustrating an operation example of the memory system according to the fifth embodiment;

FIGS. 49 to 51 are diagrams illustrating an operation example of the memory system according to the fifth embodiment;

FIGS. 52 and 53 are timing charts illustrating an operation example of the memory system according to the fifth embodiment; and

FIGS. 54 to 57 are pattern diagrams illustrating a modification of the memory system according to an embodiment.

### DETAILED DESCRIPTION

In general, according to one embodiment, a memory system includes a memory device including a first memory cell, the first memory cell capable of storing a piece of data among first data, second data, and third data, each piece of the first to third data including a first bit and a second bit, the first data having the first and second bits set to a first value, the second data having the first bit set to a second value different from the first value and the second bit set to the first value, and the third data having the first bit set to the first value and the second bit set to the second value; and a controller configured to control the memory device, wherein a threshold voltage of the first memory cell storing the first data has a first voltage, the threshold voltage of the first memory cell storing the second data has a second voltage, and the threshold voltage of the first memory cell storing the third data has a third voltage, when the threshold voltage of the first memory cell into which the first data is programmed is higher than a first determination level between the first voltage and the second voltage, the memory device programs the third data to the first memory cell.

Hereinafter, embodiments will be described in detail with reference to the drawings. In the description that follows, elements having the same functions and configurations will be assigned the same reference numerals, and overlapping explanation will be omitted.

### Embodiments

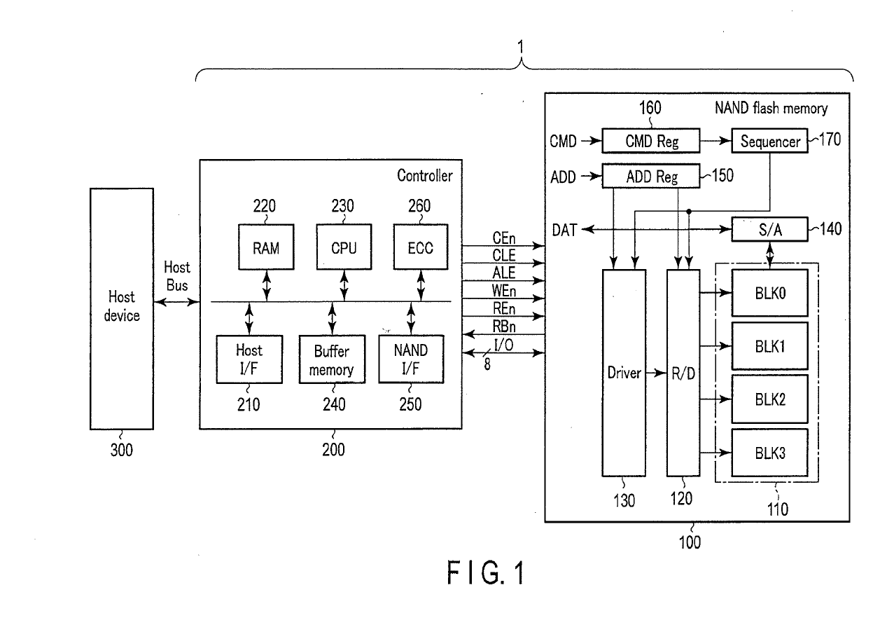

Memory systems according to the embodiments will be described with reference to FIGS. 1 to 57.

### (1) First Embodiment

A memory system according to the first embodiment and a control method thereof will be described with reference to FIGS. 1 to 12.

### (a) Configuration Example

<Overall Configuration of the Memory System>

The configuration of the memory system according to an embodiment will be described using FIG. 1.

FIG. 1 is a schematic block diagram of a memory system according to the present embodiment.

As shown in FIG. 1, a memory system 1 includes a memory device 100 and a controller 200. The memory device 100 and the controller 200 may, for example, be combined to construct one semiconductor device (for example, a storage device). For example, a memory card like an SD™ card, a solid state drive (SSD) or the like can be cited as the semiconductor device.

The memory device 100 is a flash memory. The flash memory 100 stores data in a nonvolatile manner. The flash memory 100 includes a plurality of memory cells. For example, the flash memory 100 is a NAND flash memory 100.

The controller 200 is connected to the NAND flash memory 100 by a NAND bus and connected to a host device 300 by a host bus. The controller 200 controls the NAND flash memory 100. The controller 200 accesses the NAND flash memory 100 in response to a request received from the host device 300.

The host device 300 is, for example, a future phone, a smart phone, a digital camera, a personal computer or the like. The host bus is, for example, a bus based on an SD™ interface.

The NAND bus sends and receives signals conforming to a NAND interface. Concrete examples of the signals include a chip enable signal CEn, a command latch enable signal CLE, an address latch enable signal ALE, a write enable signal WEn, a read enable signal REn, a ready/busy signal RBn, and an input/output signal I/O.

The signal CEn is a signal to enable the NAND flash memory 100. The signal CLE and the signal ALE are signals to notify the NAND flash memory 100 that an input signal I/O into the NAND flash memory 100 is a command and an address respectively. The signal WEn is a signal to cause the NAND flash memory 100 to fetch an input signal I/O. The signal REn is a signal to read an output signal I/O from the NAND flash memory 100. Each of the signals CEn, WEn, REn is asserted at a Low (“L”) level.

The ready/busy signal RBn is a signal that indicates that the NAND flash memory 100 is in a ready state (instructions from the controller 200 can be received) or a busy state (instructions from the controller 200 cannot be received). In the ready/busy signal RBn, the low level indicates a busy state.

The input/output signal I/O is, for example, an 8-bit signal. The input/output signal I/O is an entity of data sent/received between the NAND flash memory 100 and the controller 200. The input/output signal I/O is a command, an address, write data, read data or the like.

<Configuration of the Controller 200>

As illustrated in FIG. 1, the controller 200 includes a host interface circuit 210, a built-in memory (RAM) 220, a processor (CPU) 230, a buffer memory 240, a NAND interface circuit 250, and an ECC circuit 260.

The host interface circuit 210 is connected to the host device 300 via a host bus. The host interface circuit 210 transfers requests and data received from the host device 300 to the processor 230 and the buffer memory 240 respectively. Also, the host interface circuit 210 transfers data in the buffer memory 240 to the host device 300 in response to an instruction of the processor 230.

The processor 230 controls an overall operation of the controller 200. When, for example, a write request is received from the host device 300, the processor 230 issues a write command to the NAND interface circuit 250 in response to the received request. The processor 230 similarly issues a read command and an erase command in response to each request from the host device 300 for reading and erasure respectively. The processor 230 performs various processes to manage the flash memory 100 like wear leveling.

The NAND interface circuit 250 is connected to the NAND flash memory 100 via a NAND bus. The NAND interface circuit 250 governs communication between the controller 200 and the NAND flash memory 100. Based on instructions received from the processor 230, the NAND interface circuit 250 outputs signals CEn, ALE, CLE, WEn, REn to the NAND flash memory 100.

When writing, the NAND interface circuit 250 transfers a write command issued by the processor 230 and write data in the buffer memory 240 to the NAND flash memory 100 as an input/output signal I/O. When reading, the NAND interface circuit 250 transfers a read command issued by the processor 230 to the NAND flash memory 100 as an input/output signal I/O and further receives data read from the NAND flash memory 100 as an input/output signal I/O. The NAND interface circuit 250 transfers the received data to the buffer memory 240.

The buffer memory 240 temporarily holds write data and read data. The buffer memory 240 is SRAM.

The built-in memory 220 is, for example, a semiconductor memory like DRAM and is used as a work area of the processor 230. The built-in memory 220 holds firmware and various management tables to manage the flash memory 100.

The ECC circuit 260 detects and corrects errors in read data. Hereinafter, error detection and error corrections made by the ECC circuit 260 of the controller 200 will be called an ECC process. When writing the data, the ECC circuit 260 generates parity based on net data received from the host device 300. The net data and parity are written into the flash memory 100. When reading the data, the ECC circuit 260 generates a syndrome based on the read parity to determine whether there is any error in the read data. Then, if an error is contained in the data, the position of the error is identified to correct the error.

For example, the number of error bits that can be corrected by the ECC circuit 260 based on parity is determined by, for example, the number of parity bits. If error bits exceeding the number of correctable errors determined by the number of parity bits are contained in the read data, the errors cannot be corrected, leading to a failure of data reading. The ECC circuit 260 may include ECC technology like LDPC that is relatively efficient and has powerful correction capabilities.

<Configuration of the NAND Flash Memory 100>

As shown in FIG. 1, the NAND flash memory 100 includes a memory cell array 110, a row decoder 120, a driver circuit 130, a sense amplifier circuit 140, an address register 150, a command register 160, and a sequencer 170.

The memory cell array 110 stores data from the controller 200. The memory cell array 110 includes, for example, four blocks BLK (BLK0 to BLK3). The block BLK is an aggregate of a plurality of nonvolatile memory cells associated with the row and the column.

The row decoder 120 selects one of the blocks BLK0 to BLK3 and further selects the row direction of the selected block BLK.

The driver circuit 130 supplies a voltage to the selected block BLK via the row decoder 120.

When reading the data, the sense amplifier circuit 140 senses data read from the memory cell array 110 and performs an operation on the data (sense result). The sense amplifier circuit 140 outputs the data DAT to the controller 200. When writing the data, the sense amplifier circuit 140 transfers the data DAT received from the controller 200 to the memory cell array 110.

The address register 150 holds an address ADR received from the controller 200. The address register 150 outputs a signal based on the address ADR to the row decoder 120 and the driver circuit 130. The command register 160 holds a command CMD received from the controller 200.

The sequencer 170 controls the operation of the NAND flash memory 100 as a whole based on the command CMD held in the command register 160.

<Configuration of the Block BLK>

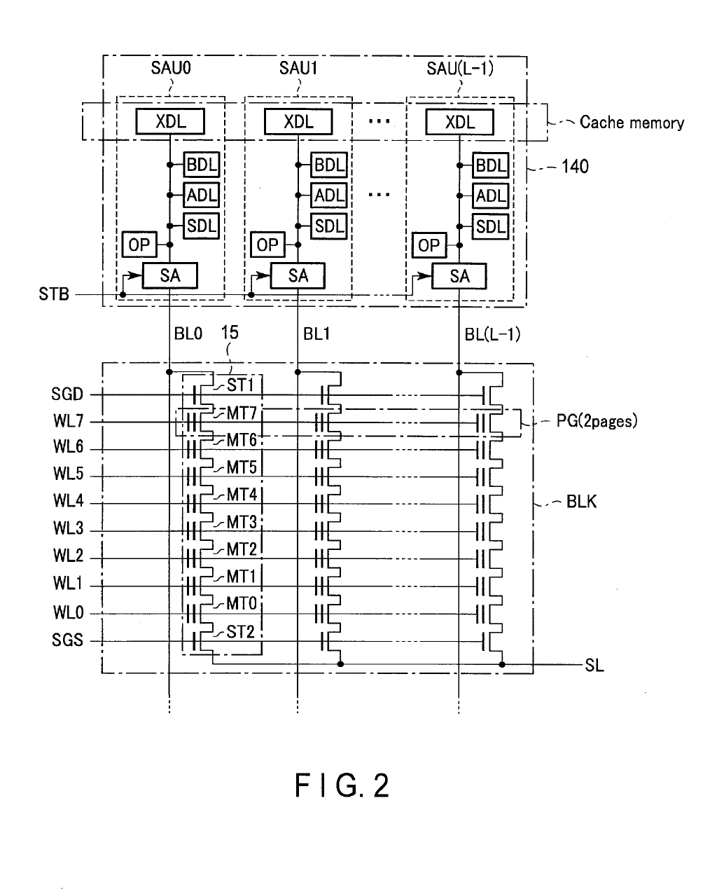

The configuration of the block BLK will be described using FIG. 2. FIG. 2 is a circuit diagram of the block BLK and the sense amplifier circuit 140.

As shown in FIG. 2, the block BLK includes a plurality of NAND strings 15. Each of the NAND strings 15 includes, for example, eight memory cells MT (MT0 to MT7) and two select transistors ST1, ST2. However, the number of memory cells MT contained in one NAND string is not limited to eight.

In the flash memory 100, the memory cell (also called a memory cell transistor) MT holds data in a nonvolatile manner. The memory cell MT has a control gate and a charge storage layer.

The charge storage layer includes at least one of a floating gate electrode (for example, a silicon layer) and a layer including a trap level (for example, a silicon nitride layer).

In each of the NAND strings 15, a plurality of memory cells MT is connected in series between the source of the select transistor ST1 and the drain of the select transistor ST2.

Within the same block, each gate of a plurality of select transistors ST1 is connected to a select gate line SGD in common and each gate of a plurality of select transistors ST2 is connected to a select gate line SGS in common. Within the same block, control gates of the memory cells MT0 to MT7 are connected to the word lines WL0 to WL7 respectively.

The drains of the select transistors ST1 of the NAND strings 15 in the same column within the memory cell array 110 are connected to a bit line BL (BL0 to BL(L−1), (L−1) is an integer equal to 1 or greater) in common. For example, the bit line BL connects the NAND strings 15 between a plurality of blocks BLK in common. The sources of a plurality of select transistors ST2 are connected to a source line SL in common.

In the present example, the flash memory 100 uses MLC (Multiple Level Cell). In MLC, one memory cell MT can hold, for example, 2-bit data. In the present example, the 2-bit data is called a lower bit and an upper bit from the lower side. Hereinafter, a set of lower bits held by memory cells connected to the same word line is called a lower page (or lower data) and a set of upper bits held by memory cells connected to the same word line is called an upper page (or upper data). In this case, two pages are allocated to one word line WL and the block BLK including eight word lines WL has the capacity for 16 pages. In other words, the “page” can be defined as a portion of memory space formed by memory cells connected to the same word line. Data may be written and read for each page (this reading method is called page-by-page reading). The page is used as an access unit for writing and reading data.

Data is erased in units of the block BLK. However, data can also be erased in units smaller than the block BLK.

Regarding an erase operation of the flash memory, the configuration described in U.S. patent application Ser. No. 12/679,991 filed on Mar. 25, 2010, entitled “Nonvolatile Semiconductor Memory Device and Manufacturing Method of the Same” and patent application Ser. No. 12/532,030 filed on Mar. 23, 2009, entitled “Semiconductor Memory and Manufacturing Method of the Same” is referred to and cited in the present embodiment.

Incidentally, the memory cell array 110 may have a configuration in which memory cells MT are three-dimensionally stacked above the semiconductor substrate.

The configuration of the memory cell array in a three-dimensional structure is described in, for example, U.S. patent application Ser. No. 12/407,403 filed on Mar. 19, 2009, entitled “Three-Dimensionally Stacked Nonvolatile Semiconductor Memory”. Also, the configuration thereof is described in U.S. patent application Ser. No. 12/406,524 filed on Mar. 18, 2009, entitled “Three-Dimensionally Stacked Nonvolatile Semiconductor Memory”, patent application Ser. No. 12/679,991 filed on Mar. 25, 2010, entitled “Nonvolatile Semiconductor Memory Device and Manufacturing Method of the Same”, and patent application Ser. No. 12/532,030 filed on Mar. 23, 2009, entitled “Semiconductor Memory and Manufacturing Method of the Same”. The entire contents of these patent applications are incorporated herein by reference.

<Configuration of the Sense Amplifier Circuit 140>

As shown in FIG. 2, the sense amplifier circuit 140 includes sense amplifier units SAU (SAU to SAU(L−1)). The sense amplifier unit SAU is provided for each bit line BL.

Each of the sense amplifier units SAU includes a sense amplifier section SA, an operation section OP, and a plurality (for example, four) of latch circuits ADL, BDL, SDL, XDL.

The sense amplifier section SA is a module that directly controls the bit line BL.

The sense amplifier section SA senses data read to the corresponding bit line BL. The sense amplifier section SA applies a voltage to the bit line BL to sense data. The sense amplifier section SA applies a voltage to the bit line BL in accordance with write data.

For example, a control signal STB is given to the sense amplifier section SA by the sequencer 170. The sense amplifier section SA determines the read data as “0” or “1” in the timing when the signal STB is asserted. The sense amplifier section SA transfers the determined data to one of the latch circuits ADL, BDL, SDL.

The latch circuits ADL, BDL, SDL temporarily hold read data and write data. The operation section OP performs various logical operations such as a negation (NOT) operation, a logical disjunction (OR(|)) operation, an logical conjunction (AND(&)) operation, and an exclusive disjunction (XOR) operation on data held in the latch circuits ADL, BDL, SDL. For example, a calculation process by the operation section OP is performed by charging and discharging the potential of a node connecting the latch circuits ADL, BDL, SDL and the operation section OP and the result of the calculation process is reflected in the potential of the node.

When writing data, data inside the latch circuits ADL, BDL shows data to be held by the memory cell (data to be written into the memory cell).

The sense amplifier section SA, the latch circuits ADL, BDL, SDL, and the operation section OP are connected by a bus so that data can mutually be sent and received. The bus is further connected to the latch circuit XDL.

Data is input and output in the sense amplifier circuit 140 via the latch circuit XDL. Data received from the controller 200 is transferred to the latch circuits ADL, BDL, SDL or the sense amplifier section SA via the latch circuit XDL.

Data in the latch circuits ADL, BDL, SDL or the sense amplifier section SA is sent to the controller 200 via the latch circuit XDL. The latch circuit XDL functions as a cache memory of the flash memory 100. Thus, even if the latch circuits ADL, BDL, SDL are in use, the flash memory 100 can be ready if the latch circuit XDL is not used.

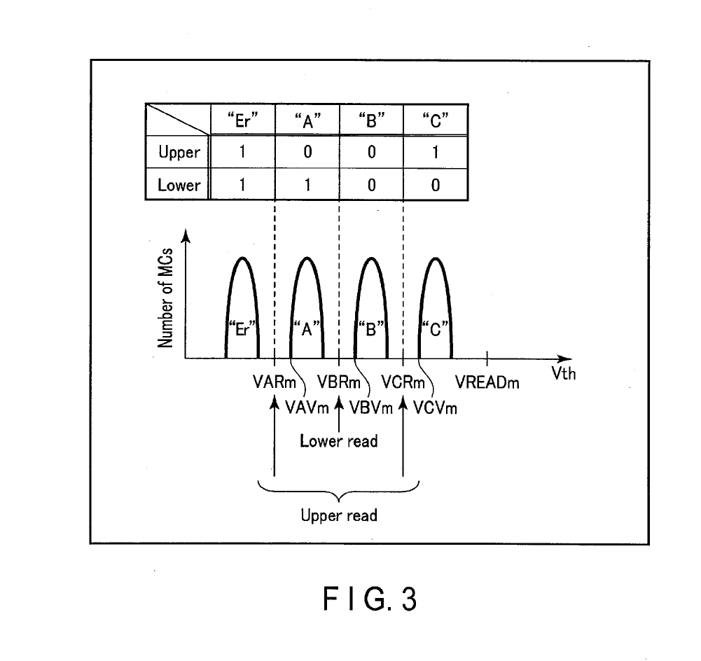

FIG. 3 is a diagram showing an example of data that can be taken by each memory cell MT in MLC, the threshold distribution, and the voltage used for the determination of the threshold voltage of the memory cell.

As described above, the memory cell MT can hold 2-bit data in accordance with the threshold voltage. The data represented by the 2 bits for the memory cell MT capable of holding 2-bit data is called an “Er(E)” level, an “A” level, a “B” level, and a “C” level in ascending order of threshold voltage.

The threshold voltage of the memory cell MT holding the “Er” level is less than the voltage value VARm and corresponds to an erase state of data. The threshold voltage of the memory cell MT of the “Er” level is, for example, a negative voltage value.

The threshold voltage of the memory cell MT holding the “A” level is the voltage value VARm or more and less than the voltage value VBRm (VBRm>VARm).

The threshold voltage of the memory cell MT holding the “B” level is the voltage value VBRm or more and less than the voltage value VCRm (VCRm>VBRm).

The threshold voltage of the memory cell MT holding the “C” level is the voltage value VCRm or more and less than the voltage value VREADm. The “C” level of 2-bit data corresponds to data of the highest threshold voltage.

When the reading method of data is page-by-page reading, an upper page of MLC is read by using, for example, the voltage value VARm and the voltage value VCRm as determination voltages (reading levels) to read data.

By reading the upper page, for example, whether the holding data held by the memory cell MT is equal to the “Er” level or the “A” level or more, and equal to the “C” level or the “B” level or less is identified.

A lower page is read by using the reading level VBRm. By reading the lower page, whether the holding data is equal to the “A” level or less or equal to the “B” level or more is determined.

For example, as shown in FIG. 3, “0” or “1” is allocated to the lower bit and the upper bit of each level.

A memory cell of the “Er” level holds the upper bit of “1” and the lower bit of “1”. A memory cell of the “A” level holds the upper bit of “0” and the lower bit of “1”. A memory cell of the “B” level holds the upper bit of “0” and the lower bit of “0” A memory cell of the “C” level holds the upper bit of “1” and the lower bit of “0”.

Hereinafter, when 2-bit data is written, the upper bit and the lower bit are written in this order from the left side toward the right side of the paper surface. In this case, data of the “A” level is represented as “01” and data of the “C” level is represented as “10”.

A memory cell of the erase state (“Er” level) is a memory cell in which “1” is programmed to all bits included in the data.

When data is, written, as shown in FIG. 3, a write condition (magnitude of the threshold voltage) of data in the memory cell is verified by using a verify voltage. The verify voltage includes a plurality of voltage values (verify levels) in accordance with write data. A verify level VAVm is used when the threshold voltage is set to the “A” level, a verify level VBVm is used when the threshold voltage is set to the “B” level, and a verify level VCVm is used when the threshold voltage is set to the “C” level.

Each verify level is set to a value between the lower limit of the threshold voltage distribution and the reading level for each piece of data. The verify levels VAVm, VBVm, VCVm of each level are voltages slightly larger than, for example, the reading levels VARm, VBVm, VCRm of each level.

The threshold voltage of the memory cell MT could rise or fall in accordance with retention characteristics of the memory cell MT. If, with the rise of the threshold voltage of the memory cell MT, the threshold voltage of the memory cell MT exceeds the reading level between the threshold distributions, an error occurs in data to be held by the memory cell MT.

Regarding the occurrence of such an error, the number of error occurrences may be concentrated in some bit (digit) of a plurality of bits that can be held by memory cell MT, in accordance with coding of data and characteristics of the memory cell. For example, the frequency at which the threshold voltage of the memory cell MT of the “Er” level becomes equal to the voltage value VARm corresponding to the “A” level or more is higher than the frequency at which the threshold voltage of the memory cells of other levels exceeds the reading voltage corresponding to the data to be stored.

For example, if the threshold voltage of the memory cell MT to be set to the “Er” level exceeds the reading level VARm of the “A” level in the flash memory 100 of MLC, data held by the memory cell is determined to be “01” data, instead of “11” data. The error of the memory cell MT of the “Er” level becomes an error of the upper bit.

When, like an error of the memory cell MT of the “Er” level, the frequency of occurrence of errors of the upper bit is higher than that of errors of the lower bit, the number of error bits is concentrated in the upper page.

In the determination of threshold voltage of the memory cell at the reading levels VARm, VBRm, VCRm, for example, the frequency of occurrence of errors at the reading level VARm is the highest. Then, the frequency of occurrence of errors at the reading level VCRm is the second highest and the frequency of occurrence of errors at the reading level VBRm is the lowest. In this case, the frequency of occurrence of errors of the upper bit is about two to four times that of errors of the lower bit.

Hereinafter, for the simplification of description, a memory cell in which an error occurs in data to be held due to variations of the value of the threshold voltage from the value corresponding to the data to be held is also called an error cell.

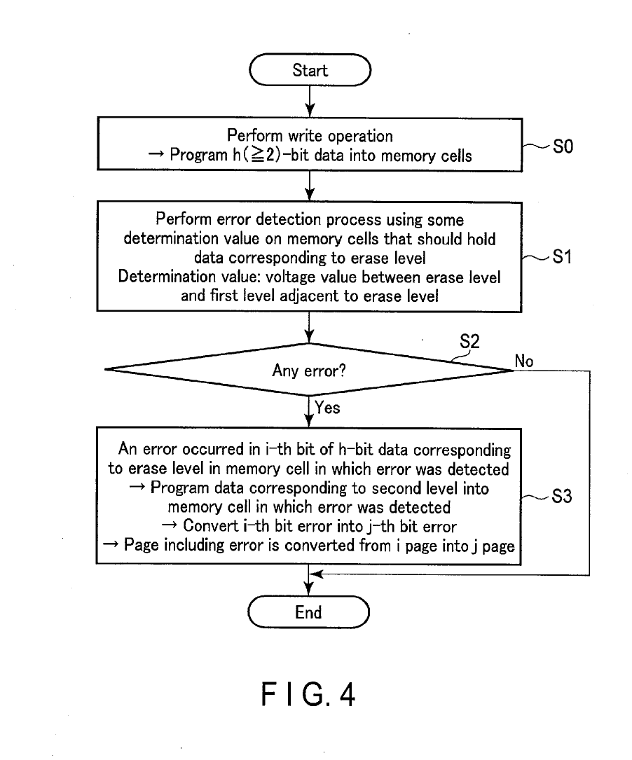

A memory system according to the present embodiment suppresses concentration of the number of error bits in some page among a plurality of pages by the process shown in FIG. 4.

FIG. 4 is a flowchart illustrating a basic process on the memory cell in which an error has occurred in the memory system according to the present embodiment.

As shown in FIG. 4, the memory system 1 according to the present embodiment performs a write operation of the flash memory (step S0). h-bit data is programmed into the memory cell by the write operation. h is a natural number equal to 2 or greater.

The memory system 1 performs a detection process of error on memory cells of the erase level (“Er” level) (step S1). The error detection process is performed by using a determination level VARm between the “Er” level and a first level (for example, the “A” level in MLC) adjacent to the “Er” level. The memory system 1 detects an error (error bit) of the i-th bit of the h-bit data by an error determination process using the determination level VARm.

The memory system 1 according to the present embodiment determines whether an error has occurred in data of the memory cells of the “Er” level based on the result of the error detection process (step S2). If no error has occurred in data of the memory cells of the “Er” level, the memory system terminates the process.

If an error has occurred in data of the memory cells of the “Er” level, the memory system performs an error conversion process as shown below.

The memory system executes a program of data of a second level on the memory cell containing the error bit (step S3).

The data corresponding to the second level (for example, the “C” level in MLC) is different from data corresponding to the “Er” level in the value of the j-th bit. Values of bits (digits) other than the j-th bit in the data of the second level are the same as those of bits other than the j-th bit in data of the “Er” level. Incidentally, the value of the j-th bit in the data of the second level is the same as that of the i-th bit in the data of the first level.

Accordingly, the error bit of an error that has occurred in a memory cell of the “Er” level changes from the i-th bit to the j-th bit. The value of the i-th bit in the memory cell of the “Er” level in which an error has occurred is the same as that of the data to be held.

As a result, the page in which an error has occurred in the memory cell of the “Er” level is converted from a page (i page) of a set of i-th bits to a page (j page) of a set of j-th bits.

With the step S1 to step S3 described above, the process on an error of the memory cell of the “Er” level in a memory system according to the present embodiment is completed.

Like the operation shown in FIG. 4, the memory system 1 according to the present embodiment can level concentration of error bits in some page among a plurality of pages allocated to one word line by converting data in the memory cell in which an error has occurred.

Accordingly, the memory system according to the present embodiment can improve reliability of data and upgrade operation characteristics.

Hereinafter, the process on an error of the memory cell in the memory system according to the present embodiment will be described more concretely.

### (1b) Operation Examples

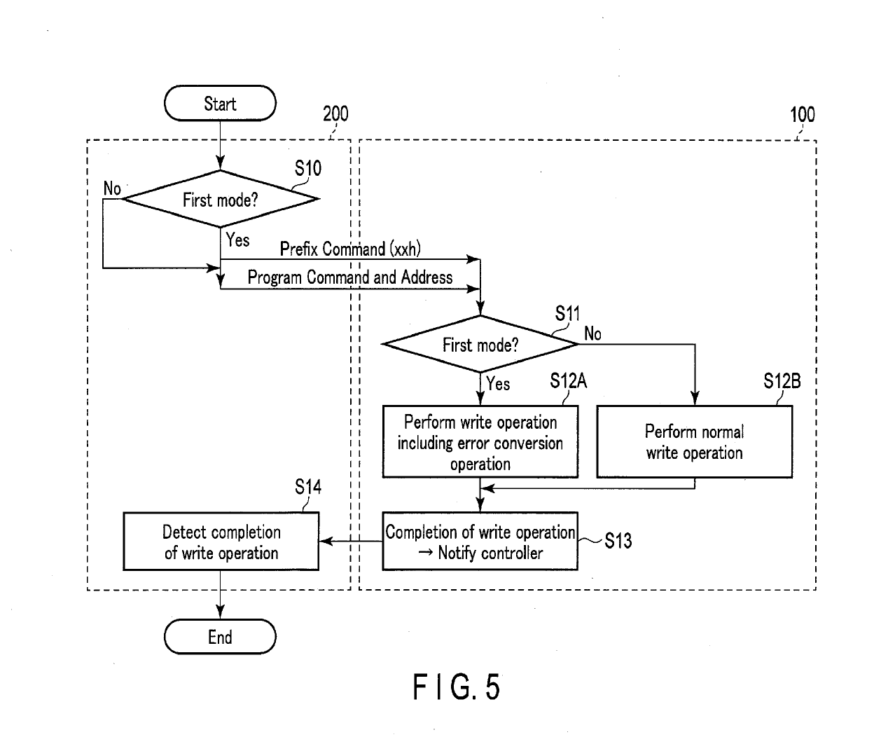

Operation examples of a memory system according to the present embodiment will be described using FIGS. 5 to 12. Hereinafter, in addition to FIGS. 5 to 12, FIGS. 1 to 3 are also used when appropriate to illustrate operation examples of the memory system according to the present embodiment.

### (1b-1) First Example

A first example of the operation example of the memory system according to the first embodiment will be described using FIGS. 5 to 9.

FIG. 5 is a flowchart illustrating the first example of the operation example of the memory system according to the present embodiment.

The controller 200 receives a request of writing data from the host device 300. The controller 200 receives data (net data) to be written from the host device 300. The controller 200 generates parity for data from the host device 300.

In the present embodiment, the memory system 1 has a first mode and a second mode for the write operation.

The controller 200 selects one of the first mode and the second mode (S10). When the controller 200 selects the first mode, the controller 200 starts the control for the flash memory 100 to perform data writing based on the first mode.

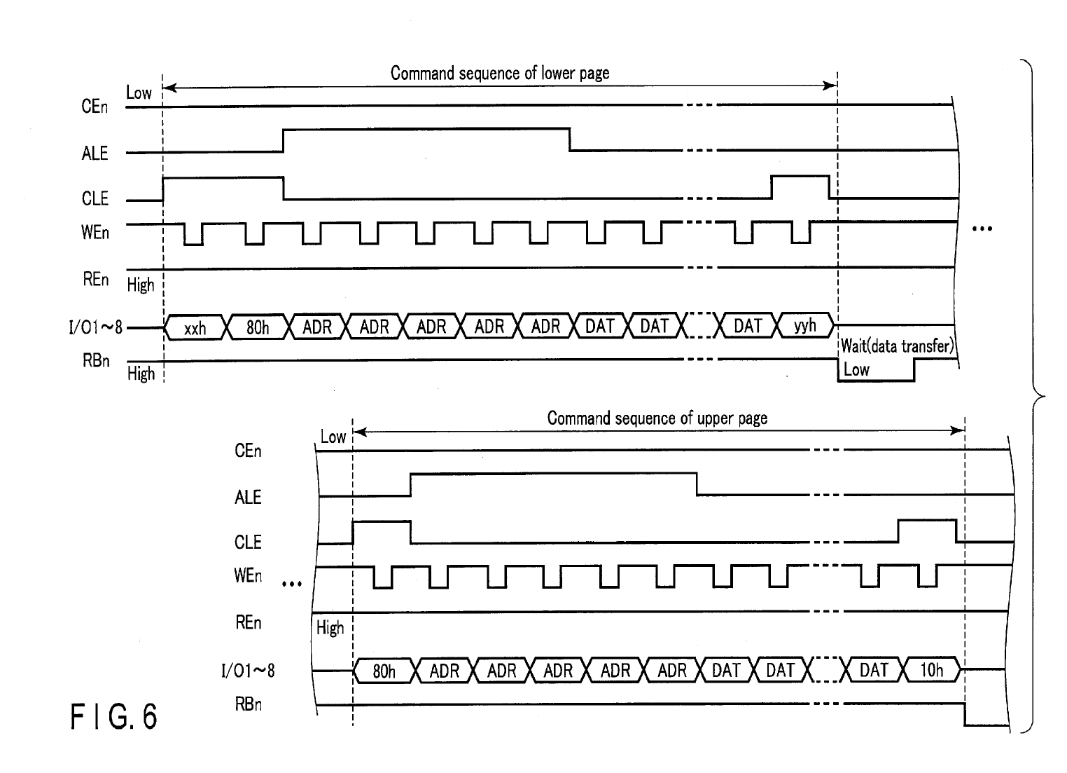

FIG. 6 is a timing chart illustrating a command sequence in an operation example of the memory system according to the present embodiment.

As shown in FIG. 6, before a command is input from the controller 200 into the flash memory 100, the chip enable signal CEn, the address latch enable signal ALE, and the command latch enable signal CLE are at a low level. Also, the write enable signal WEn and the read enable signal REn are at a high level. Also, the ready/busy signal R/Bn is in a “ready” state (high level).

To perform a write operation by the full sequence method, the controller 200 successively performs a command sequence concerning the lower page and a command sequence concerning the upper page.

When the controller 200 selects the first mode in the command sequence concerning the lower page, the controller 200 asserts the signal CLE and issues a prefix command “xxh” and a first write command “80h”. The first write command “80h” is a command defined for the NAND interface.

The flash memory 100 receives the prefix command “xxh” from the controller 200 in a period when the signal CLE is at the high level and sets the command “xxh” to the command register 160 in the timing when the write enable signal WEn changes to the low level. Subsequent to the command “xxh”, the flash memory 100 sets the command “80h” to the command register 160 in the timing when the write enable signal WEn changes to the low level.

Subsequent to the command “80h”, the controller 200 sends the address ADR. The flash memory 100 receives the address ADR from the controller 200 in a period when the signal ALE is at the high level. The address ADR is set to the address register 150 in the timing when the write enable signal WEn changes to the low level. The address ADR is a lower page address.

After sending the address ADR, the controller 200 sends data DAT to the flash memory 100. The data DAT includes net data and parity. Subsequent to the address ADR, the flash memory 100 receives the data DAT. The received data is stored in the latch circuit XDL.

The flash memory 100 receives the command “yyh” from the controller 200 in a period when the signal CLE is at the high level. Accordingly, a sequencer 19 stores data stored in latch circuit XDL in the latch circuit ADL. At this point, the ready/busy signal (R/Bn) is set to a “busy” state (low level).

Subsequent to the command sequence concerning the lower page, the command sequence concerning the upper page is performed.

In the command sequence related to the upper page, the controller 200 sends, subsequent to the command “yyh”, the command “80h” to the flash memory 100.

After the flash memory 100 receives the command “80h”, the flash memory 100 receives an address ADR of the upper page from the controller 200 in a period when the signal ALE is at the high level. Subsequent to the address ADR, the flash memory 100 receives data DAT.

After the input of the data DAT of the upper page is completed, the flash memory 100 receives a command “10h” from the controller 200 in a period when the command latch enable signal CLE is at the high level. The sequencer 19 stores data stored in the latch circuits XDL in the latch circuit BDL. At this point, the ready/busy signal (R/Bn) is set to a “busy” state (low level).

In this manner, data for two pages is stored in the latch circuits ADL, BDL in the flash memory 100.

The flash memory 100 starts a write operation of data based on the set command.

Based on the presence/absence of the prefix command “xxh”, the flash memory 100 makes sure whether the write operation to be performed is in the first mode (step S11).

If the prefix command “xxh” is set inside the command register 160, the flash memory 100 (sequencer 170) starts the control to perform a write operation based on the first mode (step S12A). In the present embodiment, the write operation in the first mode is a write operation including a detection operation of error (hereinafter, called an error check operation) in the memory cells of the “Er” level and a conversion operation of a detected error (hereinafter, called an error conversion operation).

The flash memory 100 writes the data DAT to an area corresponding to the address ADR sent from the controller 200. Based on the command “yyh”, the sequencer 19 executes a program in a full sequence method using data of the lower page and data of the upper page stored in the latch circuits ADL, BDL respectively.

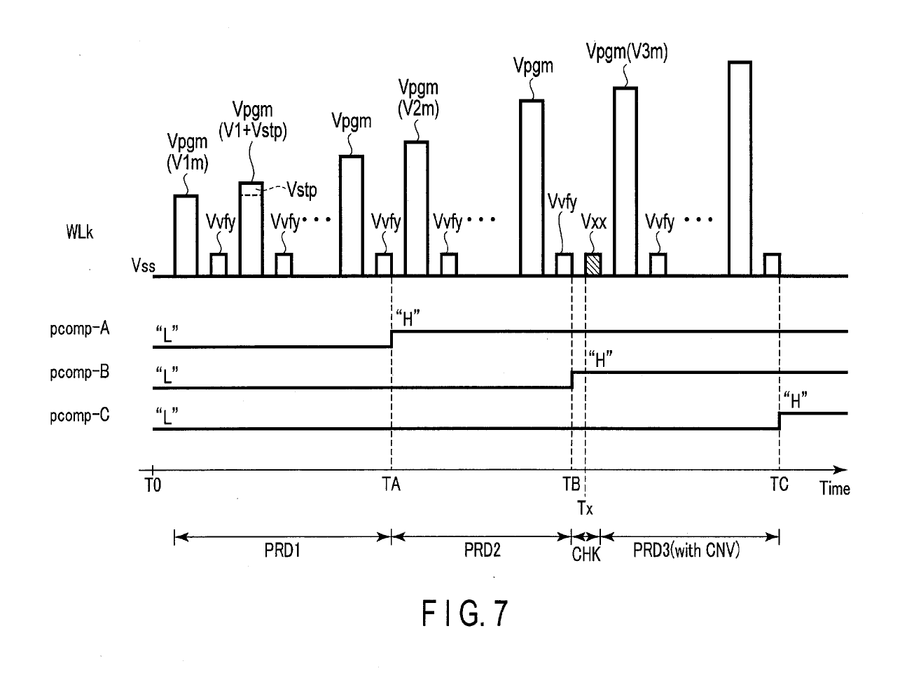

FIG. 7 is a timing chart schematically showing an overall flow of the write operation of the flash memory in the memory system according to the present embodiment.

As shown in FIG. 7, at time T0, the flash memory 100 starts a write operation. The write operation is performed by one write loop or more. One write loop includes a program operation and a verify operation.

When charges are injected into the charge storage layer of the memory cell inside the area corresponding to the address ADR to raise the threshold voltage of the memory cell MT in the program operation, the sense amplifier circuit 140 applies, for example, 0 V to the bit line BL. When the threshold voltage of the memory cell MT is retained, by contrast, the sense amplifier circuit 140 applies, for example, a positive voltage VDD to the bit line BL. By applying the positive voltage VDD to the bit line BL-Er, the memory cell of the “Er” level is set to a programming inhibited state.

The row decoder 120 selects, for example, a word line WLk (hereinafter, called a selected word line) indicated by the address ADR and applies a positive high voltage (program voltage) Vpgm to the selected word line WLk. In the present embodiment, k is a natural number between 0 to 7. The row decoder 12 applies a positive voltage Vpass to word lines (non-selected word lines) other than the selected word line WLk. The voltage Vpgm is a high voltage to inject charges of the charge storage layer through FN tunneling. The voltage Vpass is a voltage to prevent erroneous writing to memory cells in a programming inhibited state while turning on the memory cell MT regardless of the threshold voltage (holding data) of the memory cell MT. The program voltage Vpgm is a voltage higher than the non-selection voltage Vpass.

The driver circuit 130 applies a positive voltage VSGD to the select gate line SGD that is selected via the row decoder 120 and applies a voltage VSGS (for example, 0 to 0.3 V) to the select gate line SGS.

Accordingly, the memory cells MT0 to MT7 are turned on. The select transistor ST1 whose bit line BL has 0 V applied is turned on and the select transistor ST1 whose bit line BL has the voltage VDD applied is cut off. The select transistor ST2 is in an off state.

Therefore, 0 V is transferred to a channel of the memory cell MT connected to the selected word line WLk in the NAND string 15 whose select transistor ST1 is turned on. Accordingly, charges are injected into the charge storage layer through FN tunneling and the threshold voltage of the memory cell MT is raised.

In the NAND string 15 whose select transistor ST1 is cut off, by contrast, the channel of the memory cell MT is electrically floated. Accordingly, the potential of the channel of the memory cell MT rises close to the voltage value Vpass due to coupling between the word line WL and the channel (semiconductor area). As a result, the potential difference between the control gate and the channel decreases in the memory cell MT connected to the select transistor ST1 in a cutoff state and charges are not injected into the charge storage layer. Thus, among memory cells set to a programming inhibited state (memory cells of the “Er” level and memory cells whose threshold voltage has reached a value corresponding to the data to be written), the threshold voltage of the memory cell MT is retained (or variations of the threshold voltage are small because the amount of charges injected into the charge storage layer can be reduced to an extremely small amount and thus, data is practically not written).

After the program operation, a verify operation (program verification) is performed.

In the verify operation, the sense amplifier circuit 140 applies, for example, a positive voltage VBL to the bit line BL. To reduce power consumption of the flash memory, the sense amplifier circuit 140 may apply, for example, a voltage VSS to the bit line BL of the memory cell MT that should hold the “Er” level or the bit line BL of the memory cell determined to have verify-passed.

The driver circuit 130 applies a positive voltage VSG to the select gate lines SGD, SGS that are selected via the row decoder 120. Accordingly, the select transistors ST1, ST2 are turned on.

The driver circuit 130 applies a verify voltage Vvfy to the selected word line WLk via the row decoder 120. The verify voltage Vvfy includes one verify level (voltage value) or more. Accordingly, for each of a plurality of memory cells, whether the magnitude of the threshold voltage of the memory cell MT into which data should be written is equal to the verify level corresponding to the data to be written or more is determined.

If the threshold voltage of the memory cell MT is equal to a certain verify level or less, the memory cell MT is in an on state. If the threshold voltage of the memory cell MT is higher than a certain verify level, the memory cell MT is in an off state.

In accordance with on/off of the memory cell MT, a current flows through the bit line BL to which the voltage VBL is applied (node connected to the bit line) or the potential of the bit line BL varies. The sense amplifier section SA senses generation of a current or variations of the potential in the bit line BL.

The detection result is stored in the latch circuit SDL as a program verify result (“0” or “1” data).

If the memory cell MT is turned off by the application of the verify level corresponding to data to be written (the memory cell is verify-passed), the threshold voltage of the memory cell MT has reached the value corresponding to the data to be written and data writing to the memory cell MT is completed.

If the memory cell MT is turned on by the application of the verify level corresponding to data to be written (if the memory cell verify-fails), by contrast, the memory cell MT has not yet reached the threshold voltage corresponding to the data to be written. Thus, the program operation is continued for the verify-failed memory cell MT.

The verify-passed memory cell MT is set to, like a memory cell of the “Er” level, a programming inhibited state during program operation on the verify-failed memory cell MT. To set a verify-passed memory cell to a programming inhibited state, the positive voltage VDD is applied to the bit line BL based on the data (verify result) of the latch circuit SDL. Accordingly, the injection of charges into the charge storage layer of the verify-passed memory cell is suppressed during program operation.

After the program verification, a step-up voltage Vstp is added to the voltage value of the program voltage (value of the program voltage of the previous write loop). Accordingly, a program operation is performed on the verify-failed memory cell using a program voltage having a higher voltage value than the previous write loop.

A write loop including such a program operation and a verify operation is repeated until data writing is completed.

For example, the data write method of flash memory shown in FIG. 7 is a full sequence method. In the full sequence method, writing of all levels is started simultaneously. For example, data writing is completed in ascending order of threshold voltage, that is, in the order of the A level (“01” data), the B level (“00” data), and the C level (“10” data).

In the period PRD1 before programming of data of the “A” level is completed (program period of data of the “A”, “B”, and “C” levels), the threshold voltages of memory cells into which data of the “A” level, the “B” level, or the “C” level should be written are shifted in the positive direction.

In the period PRD1, the verify voltage Vvfy includes verify levels VAVm, VBVm, VCVm concerning the “A” level, the “B” level, and the “C” level respectively.

If no verify failure is detected in a memory cell into which data of the “A” level should be written (for example, if all memory cells into which data of the “A” level should be written have verify-passed), the signal level of a signal pcomp-A concerning the “A” level is changed from the low level to the high level at time TA. In this manner, the completion of programming of data of the “A” level becomes detectable based on a verify result.

If the number of verify-passed memory cells regarding memory cells into which data of the “A” level should be written satisfies a certain value, the signal level of the signal pcomp-A may be set to the high level even if all memory cells into which data of the “A” level should be written have not verify-passed. The signal level of the signal pcomp-A may be set to the high level based on the number of times of the write loop performed. The control of the signal level of signals pcomp-A, pcomp-B, pcomp-C to notify/detect the completion of programming of each level is also applicable to other levels other than the “A” level.

The program operation and program verification are continued for memory cells into which data of the “B” level or the “C” level should be written.

In a period PRD2 in which programming of data of the “B” level and the “C” level is performed, the program voltage Vpgm is applied to the selected word line WLk. The voltage value of the program voltage Vpgm is successively increased by adding a step voltage for each write loop so that the threshold voltage of the memory cell MT reaches the value corresponding to at least the “B” level during programming of the “B” and “C” levels in the period PRD2.

After the application of the program voltage Vpgm, the verify voltage Vvfy is applied. In the period PRD2, the program operation and the verify operation are repeatedly performed.

In accordance with the verify result concerning the “B” level, the completion of writing of data of the “B” level is determined. At time TB when writing of data of the “B” level is determined to be completed, the signal level of the signal pcomp-B concerning the “B” level is changed from the low level to the high level. Accordingly, the program operation on memory cells in which data of the “B” level should be written is completed.

In the present embodiment, after the signal level of the signal pcomp-B is set to the high level, a read operation (verify operation) of the “A” level is performed before the program operation is performed on verify-failed memory cells (for example, memory cells into which data of the “C” level should be written). Accordingly, an error in which the threshold voltage of a memory cell that should hold the “Er” level (memory cell that should be in an erase state) becomes equal to the “A” level or more is detected.

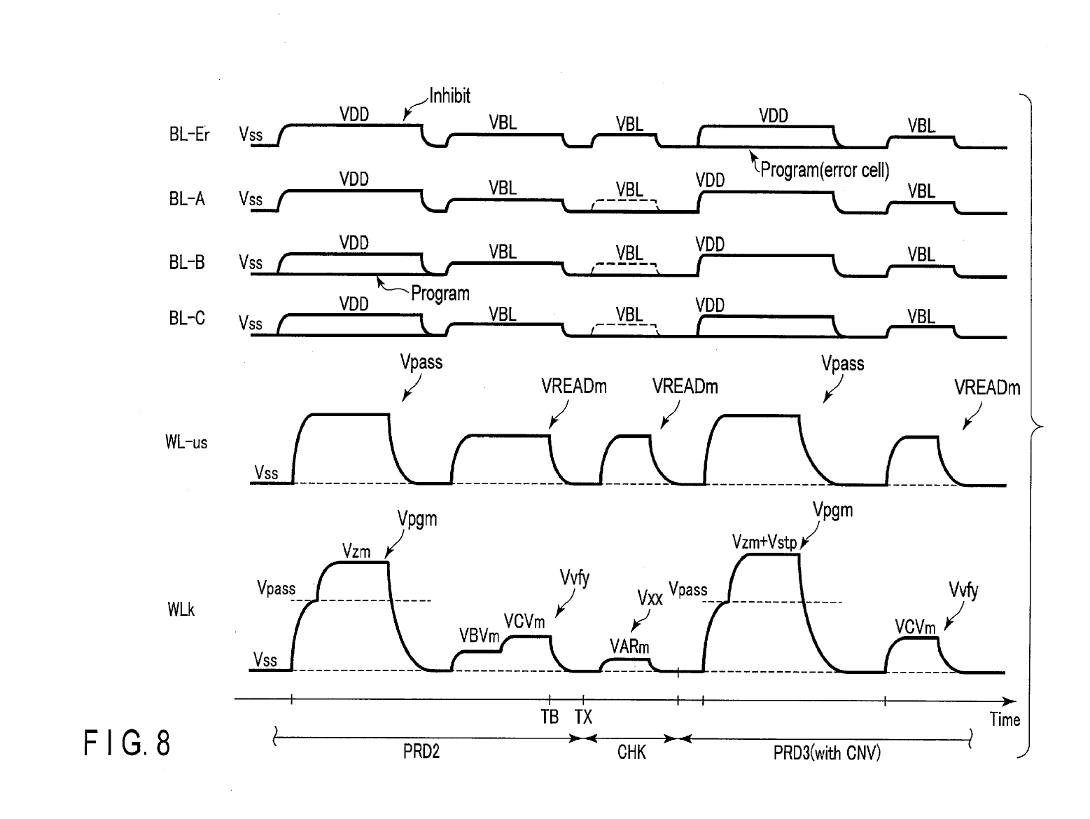

FIG. 8 is a waveform chart illustrating a first example of an operation example of the memory system according to the present embodiment. FIG. 8 is a waveform chart showing waveforms of the word line voltage in periods before and after a detection operation of an error in the memory cell.

As shown in FIG. 8, the program voltage Vpgm is applied to the selected word line WLk and the non-selection voltage (pass voltage) Vpass is applied to the non-selected word lines WL-us in the period (period of the programming of the “B” and “C” levels) PRD2.

The potential of the selected word line WLk is raised from a ground voltage Vss to about the pass voltage Vpass simultaneously with the application of the voltage Vpass to the non-selected word lines WL-us. The potential of the selected word line WLk is raised from the non-selection voltage Vpass to a certain voltage Vzm (≧V2m).

While the program voltage Vpgm is applied, the voltage VDD is applied to the bit lines BL-Er, BL-A connected to memory cells set to a programming inhibited state. Memory cells set to the programming inhibited state are, for example, memory cells of the “Er” level or the “A” level and verify-passed memory cells. After the application of the program voltage Vpgm, program verification is performed.

The positive voltage VBL is applied to bit lines BL-Er, BL-A, BL-B, BL-C. For example, a lockout process may be performed on memory cells of the “Er” level and memory cells verify-passed regarding the “A”, “B”, or “C” level. In this case, the ground voltage Vss is applied to the bit lines BL-A, BL-B, BL-C corresponding to verify-passed memory cells. The lockout process is a process (operation) of applying the ground voltage Vss to the bit lines BL connected to memory cells that are not verified during verify operation.

The verify voltage Vvfy is applied to the selected word line WLk and a non-selection voltage VREADm is applied to the non-selected word lines WL-us. The verify voltage Vvfy includes the verify level VBVm of the “B” level and the verify level VCVm of the “C” level.

Accordingly, whether the memory cell MT is turned on or turned off at the verify level VBVm is detected and whether the memory cell MT is turned on or turned off at the verify level VCVm is detected.

If all memory cells into which data of the “B” level should be written at time TBm have verify-passed (or the number of verify-passed memory cells is equal to a certain value or more), the signal pcom-B is set to the high level.

After the completion of programming of memory cells into which data of the “B” level should be written (signal pcomp-B of the high level) is detected, the sequencer 170 performs a detection operation of an error concerning the “Er” level at time TX. The detection operation of an error (error check operation) of the “Er” level is a determination operation of the threshold voltage of the memory cell MT using the reading level VARm of the “A” level.

Each of the sense amplifier units SA applies the voltage VBL to the bit line BL-Er corresponding to the memory cell MC of the “Er” level during error check operation. The voltage VBL may be applied to the bit lines BL-A, BL-B, BL-C corresponding to memory cells of other levels or the ground voltage VSS may be applied by the lockout process.

For the error check operation, the voltage including the reading level VARm (hereinafter, also called an error check voltage) Vxx is applied to the selected word line WLk and the non-selection voltage VREADm is applied to the non-selected word lines WL-us in a period CHK.

Whether the memory cell MT is turned on or turned off is determined by the reading level VARm. Accordingly, an error in memory cells of the “Er” level is detected.

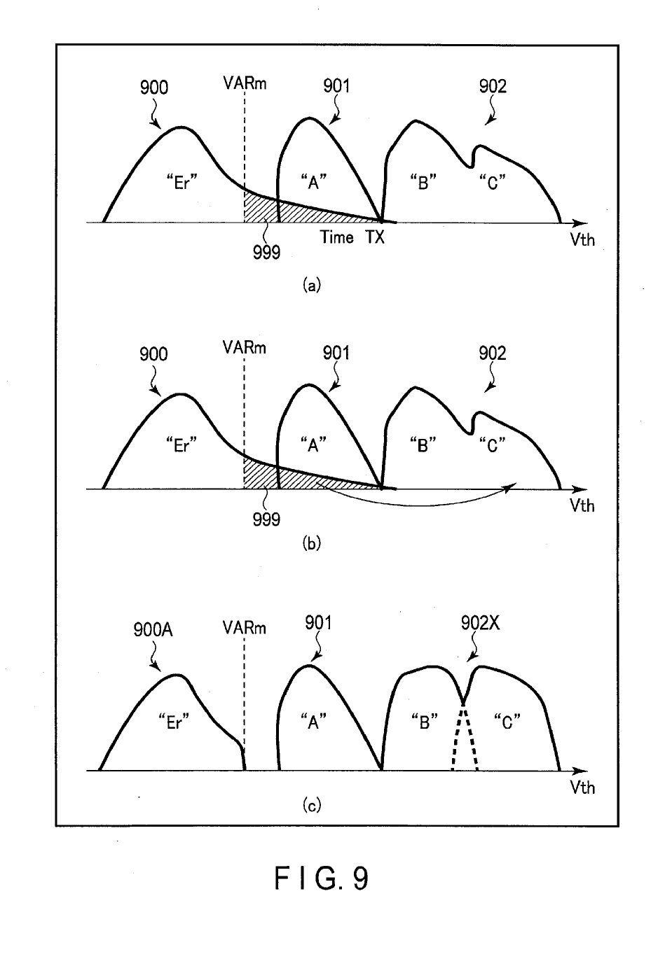

Here, to describe a process on a memory cell including an error, in addition to FIG. 8, FIG. 9 is used.

FIG. 9 is a diagram schematically showing the threshold distribution of memory cells during error detection operation in FIG. 8.

(a) of FIG. 9 shows the threshold distribution of memory cells after completion of programming of memory cells into which data of the “B” level should be written. As shown in (a) of FIG. 9, a distribution 900 of the “Er” level and a distribution 901 of the “A” level are formed after programming completion of the “B” level (times TB, TX in FIG. 7). Even if programming of memory cells of the “B” level is completed, programming of memory cells of the “C” level is not completed and thus, the threshold distribution of the “B” level is not separated from that of the “C” level and the distribution of the “B” level and that of the “C” level become one continuous distribution 902.

As shown in FIG. 3 described above, memory cells of the “Er” level have the threshold voltage of the reading level VARm or less. Thus, memory cells of the “Er” level are turned on by applying the reading level VARm.

Of the memory cells MT of the “Er” level in the distribution 900, memory cells having the threshold voltage of the reading level VARm or less are turned on by applying the reading level VARm. Thus, memory cells turned on by the application of the reading level VARm maintains the “Er” level and holds data without error (data corresponding to an erase state).

If, like memory cells inside a portion 999 in (a) of FIG. 9, the threshold voltage of memory cells shifts to a threshold voltage higher than the reading level VARm, memory cells in the portion 999 are turned off when the reading level VARm is applied. In this case, the memory cell MT that should hold the “Er” level of the off state is determined to be a memory cell of the “A” level.

Thus, in the memory cell MT of the “Er” level in an off state when the reading level VARm is applied, an error (error bit) occurs in the upper bit (upper page) of the memory cell. Incidentally, the threshold voltage of the memory cell MT that should hold the “Er” level may rise to a value corresponding to the “B” level.

In the present embodiment, an error in which the threshold voltage of the memory cell MT changes from the “Er” level (“11” data) to the “A” level (“01” data) (or the “B” level) due to a read operation from the memory cell MT that should hold the “Er” level can be detected during write operation.

For example, the result of an error check operation of the memory cell MT concerning the “Er” level is stored in the latch circuit SDL corresponding to the memory cell of the “Er” level. Incidentally, the error check operation using the reading level VARm may selectively be performed on only memory cells of the “Er” level. Also, memory cells of the “Er” level including an error may be identified by performing an error check operation on all memory cells MT connected to the selected word line WLk and performing a calculation process with data of the latch circuits ADL, BDL.

After the error check operation, the program operation is performed on memory cells that should hold data of the “C” level.

In the present embodiment, as shown in (b) of FIG. 9, the flash memory 100 shifts the threshold voltage of the memory cells MT present inside the portion 999 to the threshold voltage corresponding to the “C” level by a program operation of data of the “C” level. Accordingly, an error of the upper bit in a memory cell of the “Er” level including the error is converted into an error of the lower bit.

For example, the operation section OP performs a calculation process on data (error check result) inside the latch circuit SDL and data (data to be stored) inside the latch circuits ADL, BDL for the program operation of the “C” level on the memory cell of the “Er” level of the error. Accordingly, an error cell of the “Er” level is identified.

For example, by the calculation process, regarding the latch circuits ADL, BDL corresponding to memory cells of the “Er” level including an error, “11” data stored in the latch circuit ADL and the latch circuit BDL is converted into “10” data. If the signal indicating an error inside the latch circuit SDL is indicated as “0”, “0” data in the latch circuit SDL may be transferred to the latch circuit BDL.

Together with the program operation on memory cells that should hold the “C” level, a program operation of data of the “C” level is performed on memory cells of an error concerning the “Er” level. Thus, the program operation of data of the “C” level includes an error conversion operation. A period for error conversion (hereinafter, called an error conversion period) CNV coexists within a program period PRD of data of the “C” level.

Returning to FIG. 8, a sense amplifier 13 applies 0 V to the bit line BL connected to, among memory cells that should hold the “Er” level, the memory cell MT determined to be in error based on holding data of the latch circuits. The sense amplifier 13 applies the positive voltage VDD to the bit lines BL connected to memory cells of the “Er” level including no error.

The program voltage Vpgm having a voltage value Vzm+Vstp is applied to the word line WLk for programming of data of the “C” level. Charges are injected into memory cells of the “Er” level of the error, together with memory cells that should hold the “C” level. The threshold voltage of memory cells inside the portion 999 shifts to the voltage value corresponding to the “C” level.

Accordingly, like (c) of FIG. 9C, a distribution 902X of memory cells that should hold the “C” level accompanying the change of the threshold voltage changes and also a portion of the voltage VARm or more in a distribution 900A of the “Er” level is removed. As a result, in an error of memory cells that should hold the “Er” level, an error of the upper bit is converted into an error of the lower bit.

As shown in FIGS. 7 and 8, program verification concerning the “C” level is performed.

The verify voltage Vvfy includes the verify level VCVm concerning the “C” level when programming of the “C” level is verified.

In a period PRD3 (program operation of the “C” level), memory cells that should hold the “A” level or the “B” level are set to a programming inhibited state.

When programming of data of the “C” level is determined to be completed based on a verify result of the “C” level, at time TC, the signal level of the signal pcomp-C is changed from the low level to the high level. Accordingly, the write operation in the flash memory of MLC is completed.

When the write operation is completed, the flash memory 100 notifies the controller 200 of the completion of the write operation (step S13). For the notification of the completion of the write operation, the sequencer 170 sets the signal level of the signal RBn to the low level based on the signals pcomp-A, pcomp-B, pcomp-C at the high level.

The controller 200 detects the completion of the write operation based on the signal RBn at the low level (step S14).

Incidentally, even if a verify failure is included in a verify result, the completion of the write operation may be determined if the number of times of the write loop performed reaches a predetermined value.

As an operation different from the above operation, in step S10, when the second mode is selected, the command CMD (80h, 10h), the address ADR, and the data DAT are sent in the same order as that shown in FIG. 4 without the prefix command (xxh). The flash memory 100 performs a known write operation (called a normal write operation) based on the command CMD (step S12B). That is, the flash memory 100 repeatedly performs the program operation and the program verification without an error check operation after the notification of the completion of programming of the “B” level in data writing in the second mode.

With the above operation, the write operation of data in a memory system according to the present embodiment is completed.

As described using FIGS. 5 to 9, the memory system according to the present embodiment checks whether there is any error in data of memory cells that should hold the “Er” level during write operation of the flash memory.

Among memory cells that should hold the “Er” level, memory cells including an error (error of some bit) hold data other than “11” data, for example, “01” data. The error is an error of the upper bit.

When the memory cell MC of the “Er” level including an error is detected, programming of data of the “C” level is performed for the memory cell MC.

Accordingly, the memory cell in error (memory cell that should originally hold the “Er” level) MC holds, instead of “01” data, “10” data corresponding to the “C” level. In this case, the error occurs in the lower bit in an error cell at the “Er” level.

Thus, the memory system according to the present embodiment shifts the threshold voltage of the memory cell of the “Er” level in which an error occurred while writing data to a level corresponding another level (for example, the “C” level) and converts the bit (digit) in which the error occurred to another bit.

As a result, the memory system according to the present embodiment can prevent concentration of the number of errors in an upper page as a set of upper bits.

### (1b-2) Second Example

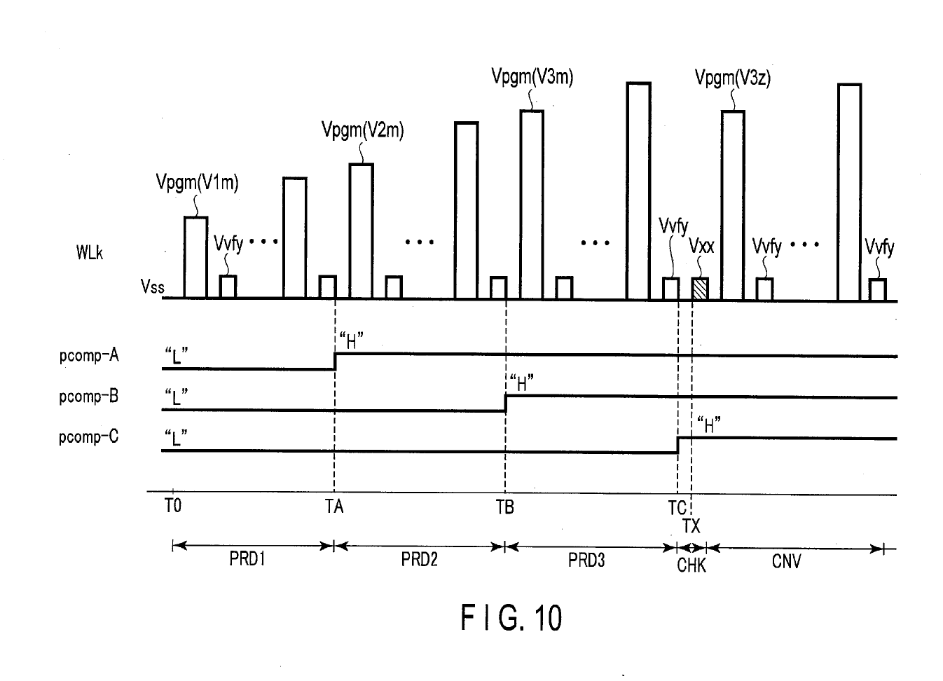

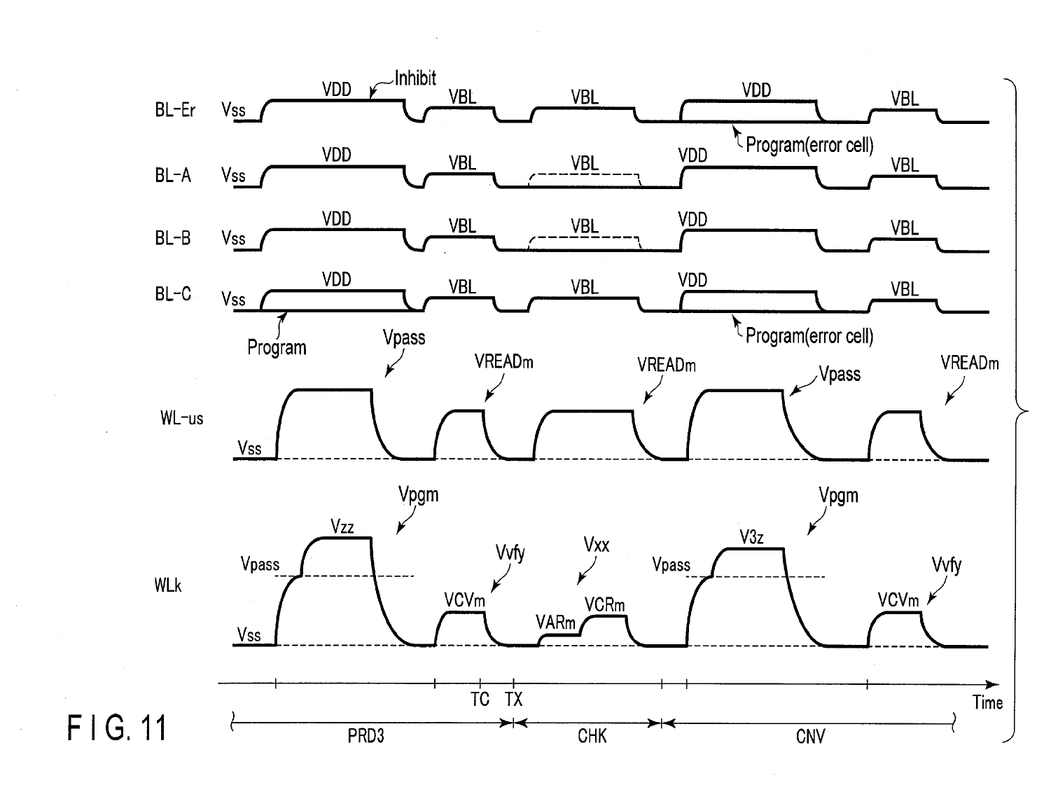

A second example of the operation example of the memory system according to the first embodiment will be described with reference to FIGS. 10 and 11.

In the flash memory to which programming of the full sequence method is applied, an error check operation and an error conversion operation concerning the “Er” level may be performed after programming of the level programmed last (for example, the highest level) is completed.

FIG. 10 is a diagram illustrating the second example of the operation example of the memory system according to the present embodiment. FIG. 10 is a timing chart schematically showing an overall flow of the write operation in the operation of the memory system in the present example.

In the present example, as shown in FIG. 10, a program operation is performed on verify-failed memory cells that should hold data of the “C” level without error check operation after programming of data is completed in the order of the “A” level and the “B” level.

After the program operation of the “C” level, the signal pcomp-C is set to the high level based on the program verify result concerning the “C” level (or the number of write loops).

In the present example, the sequencer 170 performs an error check operation in the period CHK through detection of the signal pcomp-C at the high level. To do checks of memory cells of the “Er” level including an error, the error check voltage Vxx is applied to the selected word line WLk.

Based on the result of the error check operation after programming of the “C” level is completed, programming for memory cells including an error is performed in the period CNV.

FIG. 11 is a waveform chart illustrating the second example of the operation example of the memory system according to the present embodiment. FIG. 11 is a waveform chart showing waveforms of the word line voltage in periods before and after a detection operation of any memory cell including an error in the present example.

When, as shown in FIG. 11, programming of data of the “C” level is completed, the voltage Vxx is applied to the selected word line WLk to detect an error cell. The voltage Vxx includes the reading level VARm.

If, as described above, a memory cell of the “Er” level including an error of the upper bit (memory cell of the “Er” level turned off at the reading level VARm) is detected, the sequencer 170 performs writing of data of the “C” level into the error cell. Accordingly, the error of the upper bit is converted into an error of the lower bit.

As a result, in the present example, the number of errors in the upper page is leveled with that of errors in the lower page.

For example, as shown in FIG. 11, the error check voltage Vxx may further include, in addition to the reading level VARm, the reading level VCRm.

The threshold voltage of memory cells that should hold the “C” level may fall from a value corresponding to the “C” level to a value corresponding to the “B” level in accordance with characteristics of the memory cell. A memory cell whose threshold voltage changes from the “C” level to the “B” level is an error cell.

The change of the threshold voltage from the “C” level to the “B” level is an error of the upper bit. Thus, errors originating from the change of the threshold voltage from the “C” level to the “B” level are also a factor in an uneven distribution of error bits in the upper page.

The memory system 1 according to the present embodiment detects, like in the present example, among memory cells that should hold the “C” level, memory cells whose threshold voltage falls from the “C” level to the “B” level during write operation by applying the reading level VCRm. When the reading level VCRm is applied, memory cells of the “C” level including errors originating from the fall of the threshold voltage are turned on. Thus, among memory cells that should hold data of the “C” level, memory cells whose threshold voltage has changed to a level lower than the “C” level are detected.

The memory system 1 according to the present embodiment performs a program operation that shifts the threshold voltage to the “C” level on memory cells that should hold the “C” level including an error simultaneously with memory cells that should hold the “Er” level including an error.

For example, an initial voltage value V3z of the program voltage Vpgm for an error variation operation is lower than a maximum voltage Vzz of the program voltage Vpgm in a period PRDC. For example, the voltage value V3z has a value equal to an initial voltage value V3m at the start of the period PRDC. The voltage value V3z may be lower than the voltage value V3m.

Accordingly, in the present example, the memory system 1 according to the present example can bring back the threshold voltage of the memory cells MT whose threshold voltage has fallen from the “C” level to the “B” level to the “C” level.

As a result, along with leveling of the number of error bits between pages, the memory system 1 according to the present embodiment can reduce errors of data originating from the fall of the threshold voltage.

### (1b-3) Third Example

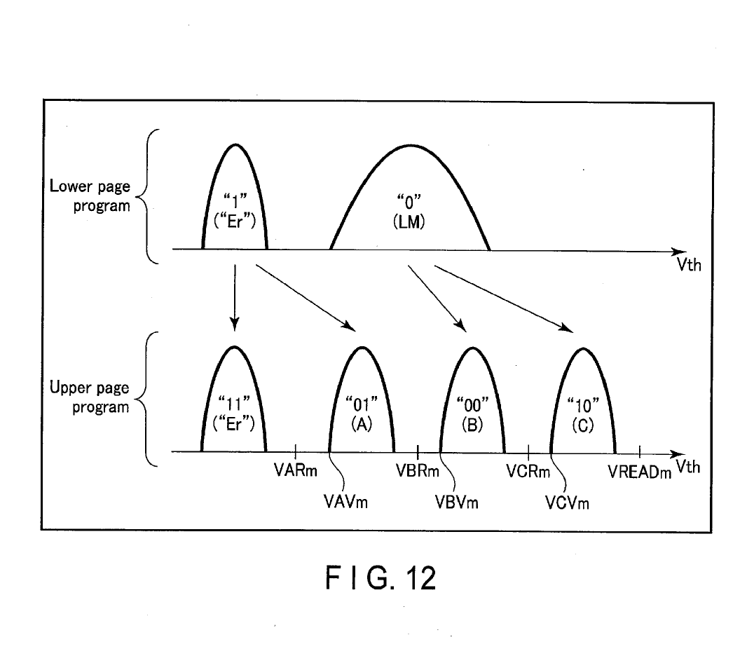

A third example of the operation example of the memory system according to the first embodiment will be described with reference to FIG. 12.

In the memory system according to the present embodiment, the lower at middle (LM) method may be used as the programming method of the flash memory.

Programming of pages by the LM method is performed page by page for the lower page and the upper page allocated to a certain word line. In the LM method, programming is performed for the lower page and the upper page at times that are not continuous.

The order of programming of each page and each level in programming of the LM method will be described with reference to FIG. 12.

As shown in (a) of FIG. 12, the threshold voltage of the memory cell into which data is written is shifted from the “Er” level to an “LM” level when writing into the lower page for a certain word line WLi. Here, the upper limit of the threshold distribution of the “LM” level is set to a value that does not exceed the upper limit of the threshold distribution of the “B” level after the influence of interference between cells (for example, the Yupin effect) is given to memory cells.

Writing into the upper page for the word line WLi is performed after programming for pages allocated to other word lines WLi−1, WLi+1 is performed in the order based on the address of the lower/upper page allocated to each word line.

Reading of data of the lower page of the word line WLi is performed when programming of the upper page of the word line WLi. The data holding state of the latch circuits ADL, BDL is controlled based on data (upper bit) to be written into the upper page from outside and data (lower bit) of the lower page read from inside. As a result, the distribution of memory cells whose threshold voltage should be shifted is determined for each memory cell connected to the word line WLi.

In programming of the upper bit, as shown in (b) of FIG. 12, a program operation that shifts the threshold voltage of, among memory cells of the “Er” level, memory cells into which data of the “A” level should be written to the “A” level is performed. Also, among memory cells of the “LM” level, a program operation that shifts the threshold voltage of memory cells into which data of the “B” level should be written to the “B” level and a program operation that shifts the threshold voltage of memory cells into which data of the “C” level should be written to the “C” level are performed.

Writing of the upper page in the LM method is different from the full sequence method in the shift amount of the threshold voltage, but is performed by the control that is substantially the same as that for a write operation in the full sequence method. Thus, an error check process concerning the “Er” level can be performed during write operation of the upper page of programming in the LM method.

For example, a write operation including the error check process shown in FIGS. 7 and 8 is performed during write operation of the upper page of programming in the LM method.

Accordingly, the memory system including the flash memory to which a write operation in the LM method is applied can detect an error occurring in memory cells of the “Er” level.

When an error of the “Er” level is detected, the flash memory 100 performs a program operation on the memory cell of the “Er” level where the error is detected to shift the threshold voltage of the memory cell to a value corresponding to the “C” level.

As a result, the memory system according to the present embodiment converts data of the “Er” level (data of the “A” level) including the error in the lower bit to data of the “C” level.

Incidentally, as shown in FIGS. 10 and 11, the error check operation and the error conversion process may be performed after programming of the “C” level.

In the memory system 1 according to the present embodiment, as described above, the number of error bits in the lower page and that of error bits in the upper page of the flash memory 100 are leveled also in the flash memory 100 to which a write operation in the LM method is applied.

### (1c) Summary

In a flash memory included in a memory system, an error may occur in data to be stored due to an unintended rise or fall of the threshold voltage of memory cells.

The frequency of occurrence of errors originating from the rise of the threshold voltage of memory cells at the erase level is higher than the frequency of occurrence of errors in memory cells of other levels (data). Such an unintended rise of the threshold voltage of memory cells at the erase level occurs regardless of during write operation or after the write operation.

When the threshold voltage of memory cells of the erase level rises to a voltage value corresponding to another level in the flash memory of MLC, when compared with the lower page, error bits may be concentrated in the upper page.

When data in memory cells is rewritten in a common flash memory, programming of data is performed after an erase operation as an operation sequence of the flash memory.

If based on the operation sequence, when data including an error originating from the rise of the threshold voltage is corrected to data that should be held in memory cells, an erase operation and a write operation are performed and thus, corrections of errors of data in memory cells may cause the memory system to operate longer.

Errors of data in the flash memory can be corrected by an ECC process being performed on data read from the flash memory by the controller. However, if the number of error bits in the page exceeds the correction capabilities of the ECC circuit, errors in data cannot be corrected. Thus, if error bits are unevenly distributed in a certain page, errors may not be correctable by the ECC process. When errors cannot be corrected by the ECC process, a read error occurs in data reading of the memory system.

When correction capabilities of the ECC circuit and the number of parity bits attached to data are set such that the maximum number of error bits that can be expected to occur in the page can be handled, a more expensive ECC circuit is designed and thus, the manufacturing cost of the memory system may increase.

The memory system according to the first embodiment detects, among memory cells that should hold the erase level, memory cells whose threshold voltage has shifted to a level higher than the value corresponding to the erase level during write operation into the flash memory of MLC. Accordingly, the memory system according to the present embodiment detects memory cells of the erase level including an error of, among a plurality of bits contained in data that can be held by memory cells, a certain bit (for example, the upper bit).

The memory system according to the present embodiment performs a program operation (injection of charges into the charge storage layer) on the detected memory cell of the erase level including an error. Here, the level at which the threshold voltage of memory cells including an error is shifted by a program operation is a level having a different value in a certain 1 bit (for example, the lower bit) from the erase level and also having the same value in one other bit (here, the upper bit) or more as that of a bit or more contained in the erase level.

As a result, in the present embodiment, an error of a certain bit that occurred in a memory cell of the erase level due to an unintended rise of the threshold voltage is converted into an error of another bit. In the flash memory of MLC, an error of the upper bit is converted into an error of the lower bit.

Accordingly, the memory system according to the present embodiment can level the number of errors in the flash memory in a plurality of pages. Thus, the memory system according to the present embodiment can suppress an uneven distribution of error in, among upper and lower pages allocated to one word line WL, the upper page.

As a result, the memory system according to the present embodiment can reduce the frequency of occurrence of read errors. Also, the memory system according to the present embodiment can expect a longer life of data and maintain reliability of data in the flash memory for a long period of time.

Due to leveling of the error rate per page, the memory system according to the present embodiment may be able to limit the upper limit of correction capabilities of the ECC circuit to a value adapted to the leveled error rate.

As a result, the memory system according to the present embodiment can suppress an increase of the manufacturing cost of the memory system.

The memory system according to the present embodiment can, as described above, maintain reliability of data. Also, the memory system according to the present embodiment can improve operation characteristics concerning error corrections.

### (2) Second Embodiment

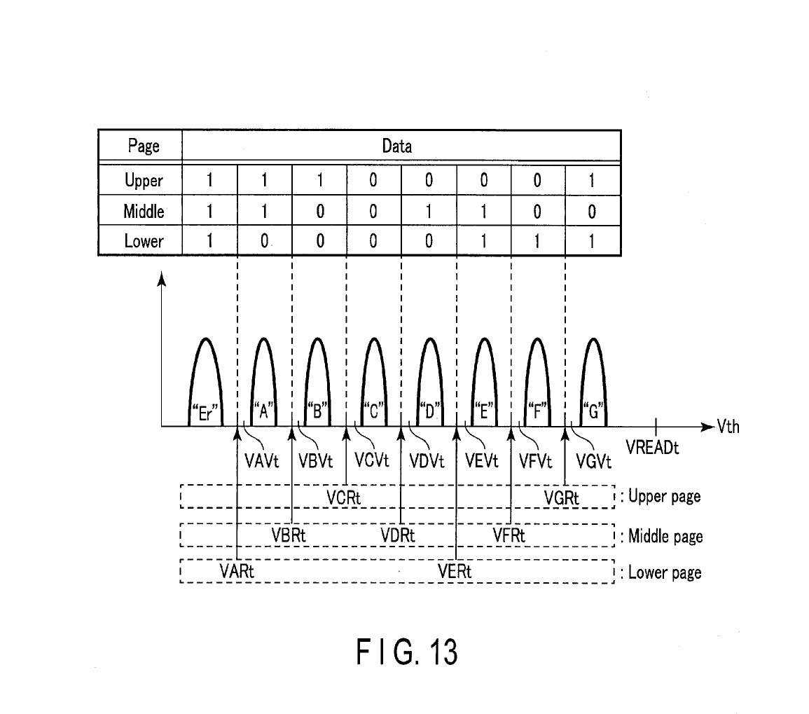

A memory system according to a second embodiment will be described with reference to FIGS. 13 to 19.

### (2a) Configuration Example

In the second embodiment, one memory cell can hold 3-bit data. Hereinafter, memory cells capable of holding 3-bit data in one memory cell will be called TLC (Triple Level Cell).

FIG. 13 is a diagram showing an example of data that can be taken by each memory cell MT in TLC, the threshold distribution, and the voltage used for the determination of the threshold voltage of the memory cell.

As shown in FIG. 13, data represented by 3 bits in TLC is called an “Er” level, an “A” level, a “B” level, a “C” level, a “D” level, an “E” level, an “F” level, and a “G” level in ascending order of threshold voltage. TLC includes a middle bit between an upper bit and a lower bit. A set of middle bits is called a middle page. Hereinafter, when 3-bit data is written, the upper bit, the middle bit, and the lower bit are written in this order as each digit of 3 bits from the left side toward the right side of the paper surface.

The threshold voltage of the memory cell MT holding the “Er” level (“111” data) is less than a reading level VARt and corresponds to an erase state. The threshold voltage of the memory cell MT of the “Er” level is a negative value.

The threshold voltage of the memory cell MT holding the “A” level (“110” data) is equal to the reading level VARt or more and less than a reading level VBRt.

The threshold voltage of the memory cell MT holding the “B” level (“100” data) is equal to the reading level VBRt or more and less than a reading level VCRt.

The threshold voltage of the memory cell MT holding the “C” level (“000” data) is equal to the reading level VCRt or more and less than a reading level VDRt.

The threshold voltage of the memory cell MT holding the “D” level (“010” data) is equal to the reading level VDRt or more and less than a reading level VERt.

The threshold voltage of the memory cell MT holding the “E” level (“011” data) is equal to the reading level VERt or more and less than a reading level VFRt.

The threshold voltage of the memory cell MT holding the “F” level (“001” data) is equal to the reading level VFRt or more and less than a reading level VGRt.

The threshold voltage of the memory cell MT holding the “G” level (“101” data) is equal to the reading level VGRt or more and less than a reading level VREADt.

Of 3-bit data, the “G” level corresponds to data of the highest threshold voltage.

Reading of 3-bit data is performed by reading the upper page, the lower page, and the middle page.

For example, reading of the upper page is performed by using the reading level VCRt and the reading level VGRt. By reading the upper page, whether the holding data is one of the “C” to “F” levels, or one of the “Er” to “B” levels and the “G” level is identified.

Reading of the middle page is performed by using the reading level VBRt, the reading level VDRt, and the reading level VFRt. By reading the middle page, whether the holding data is one of the “B”, “C”, “F”, and “G” levels, or one of the “Er”, “A”, “D”, and “E” levels is identified.

Reading of the lower page is performed by using the reading level VARt and the reading level VERt. By reading the lower page, whether the holding data is one of the “A” to “D” levels, or one of the “Er” level and the “E” to “G” levels is identified.

For the threshold distribution of each level, verify levels VAVt, VBVt, VCVt, . . . , VFVt, and VGVt are set.

In a flash memory using TLC, three pages are allocated to one word line WL and a block BLK including eight word lines WL has the capacity for 24 pages.

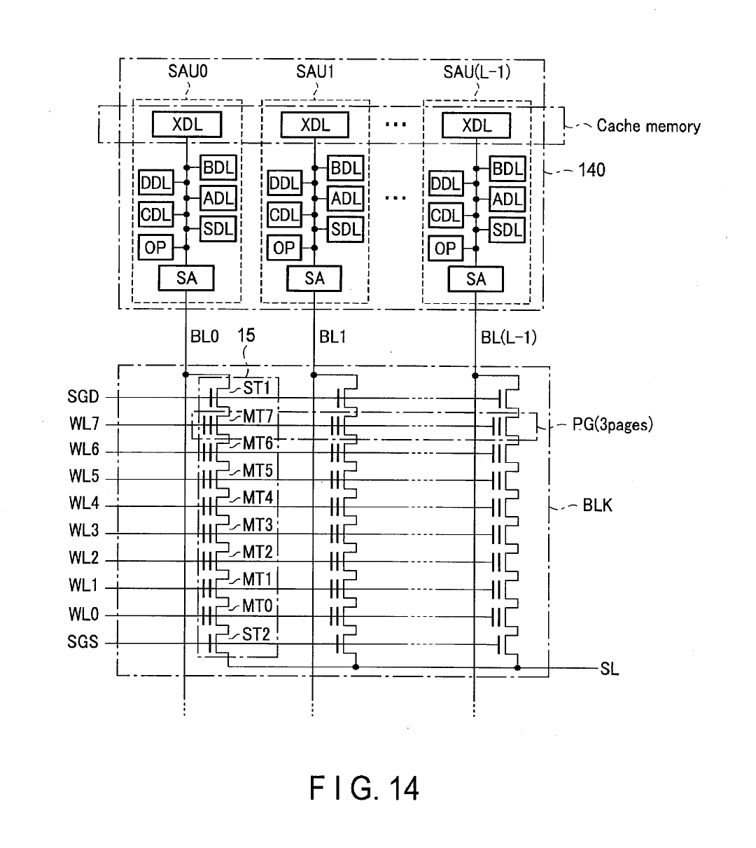

FIG. 14 shows a circuit diagram of the sense amplifier of the memory device in the flash memory according to the present embodiment.

When, as shown in FIG. 14, the memory cell MT can hold 3-bit data, each sense amplifier unit SAU includes at least five latch circuits ADL, BDL, CDL, DDL, SDL in a sense amplifier circuit 140 to hold 3-bit data, a verify result, and various calculation results.

Even if one memory cell MT can hold 3-bit data, the threshold voltage of the memory cell MT may shift to a value different from the threshold voltage corresponding to data to be held after the threshold voltage of the memory cell MT unintentionally rises (or falls).

For example, also in TLC, like in MLC, the frequency of occurrence of errors originating from the rise of the threshold voltage of memory cells that should hold the “Er” level to the reading level VARt or more is higher than the frequency of occurrence of errors of other levels.

Thus, if the threshold voltage of memory cells and data are associated by the relation as shown in FIG. 13, the number of error bits is more likely to concentrate in the lower page than the upper page and the middle page in a memory system including a flash memory using TLC.

In the memory system according to the present embodiment, like in the first embodiment, the flash memory detects memory cells of the “Er” level in which an error occurred by an error check operation in the period CHK during write operation and performs programming of data (injection of charges into the charge storage layer) for memory cells of the “Er” level in which an error occurred.

Accordingly, like the memory system according to the first embodiment, the memory system according to the present embodiment changes the bit (digit) in which an error occurred in 3-bit data.

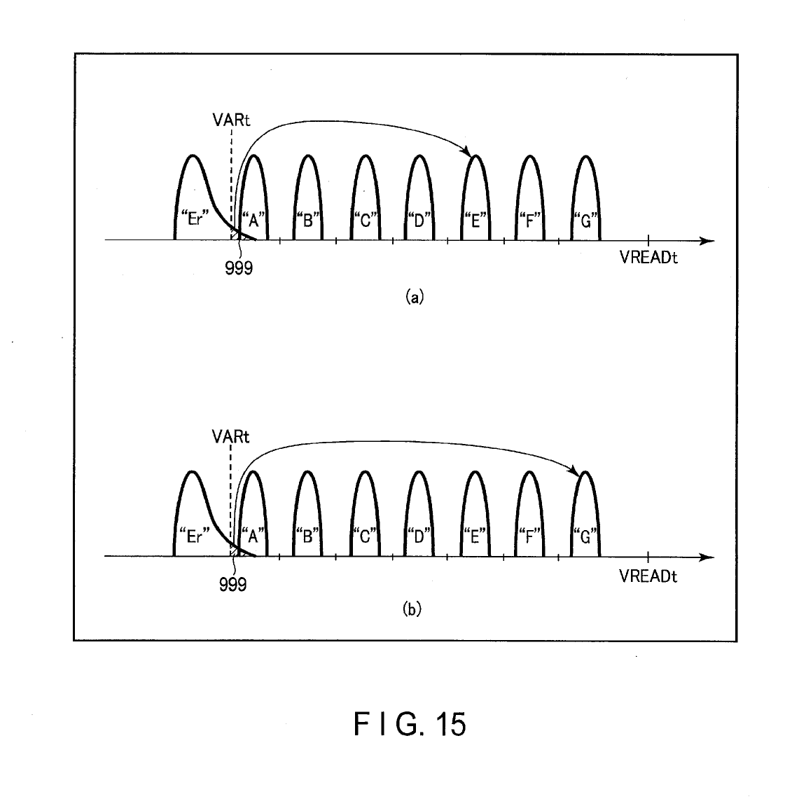

FIG. 15 is a pattern diagram illustrating an error conversion process in the memory system according to the present embodiment.

As shown in (a) of FIG. 15, data of the “E” level is programmed into memory cells including an error concerning the “Er” level inside a portion 999 (memory cells that has the threshold voltage of the voltage value VARt or more and should hold the “Er” level).

Accordingly, data (“110”) including an error of the lower bit is converted into data (“011”) including an error of the upper bit in memory cells that should hold the “111” data.

As shown in (b) of FIG. 15, data of the “G” level may be programmed into memory cells including an error concerning the “Er” level.

In this case, data (“110”) including an error of the lower bit is converted into data (“101”) including an error of the middle bit in memory cells that should hold the “111” data.

Thus, a memory system 1 according to the present embodiment can convert a detected error of the lower bit into an error of the middle bit or the upper bit in the flash memory using TLC.

Therefore, the memory system 1 according to the present embodiment suppresses an uneven distribution of errors in a certain page.

As described above, a memory system according to the present embodiment can improve reliability of data.

### (2b) Operation Examples

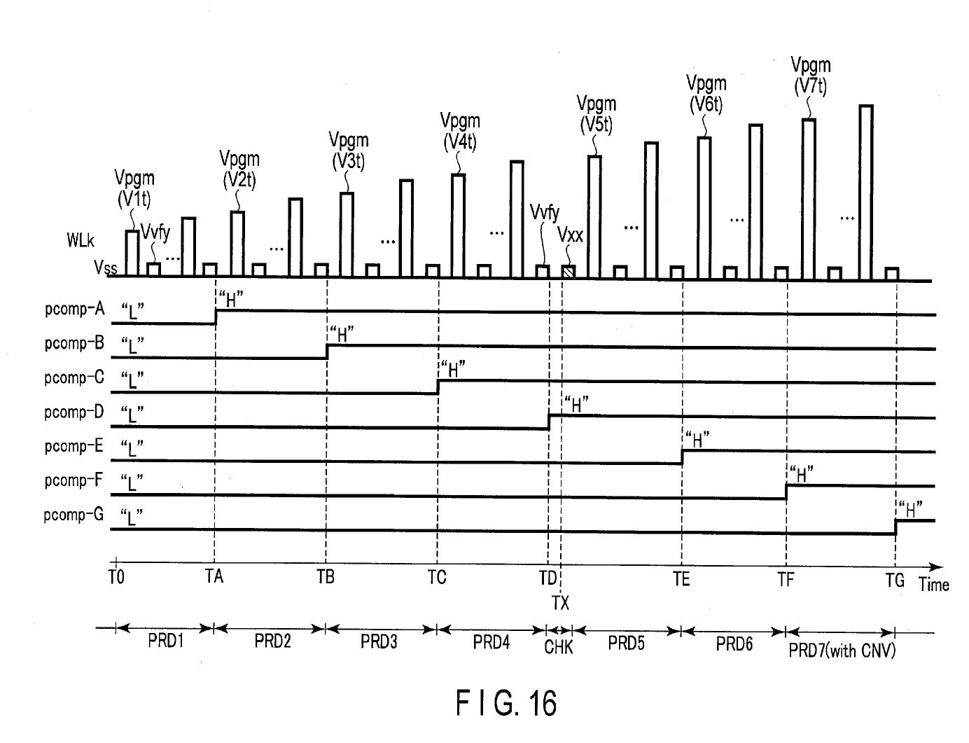

Operation examples of a memory system according to the second embodiment will be described with reference to FIGS. 16 to 19.

### (2b-1) First Example

A first example of the operation example of the memory system according to the second embodiment will be described with reference to FIGS. 16 to 19.

FIG. 16 is a timing chart showing an overall flow of the write operation of the flash memory in the memory system according to the present embodiment.

As shown in FIG. 16, in the present embodiment, a flash memory 100 performs a write operation of TLC by the full sequence method. Programming of data is started simultaneously for all levels equal to the “A” level or more.

A program voltage Vpgm and a verify voltage Vvfy are alternately applied to a selected word line WLk. The voltage value (V1t, V2t, . . . , V6t, V7t) of the program voltage Vpgm is successively increased so that programming of data proceeds. Accordingly, writing of data of each level is completed in ascending order of threshold voltage.

At times TA, TB, . . . , TF, TG when determined that writing of data of each level is completed, respective signals pcomp (pcomp-A, pcomp-B, . . . , pcomp-F, pcomp-G) are set to the high level. In each period PRD1, PRD2, . . . , PRD6, PRD7, programming of data is continued for memory cells for which writing of desired data is not completed.

In the present embodiment, an error check operation on memory cells of the “Er” level is performed after programming of data of a certain level is completed.

When, like in (a) of FIG. 15 described above, an error of the lower bit of memory cell of the “Er” level is converted into an error of the upper bit, an operation for error checking concerning the “Er” level is performed in the timing (time TD) when the signal pcomp-D is set to the high level.

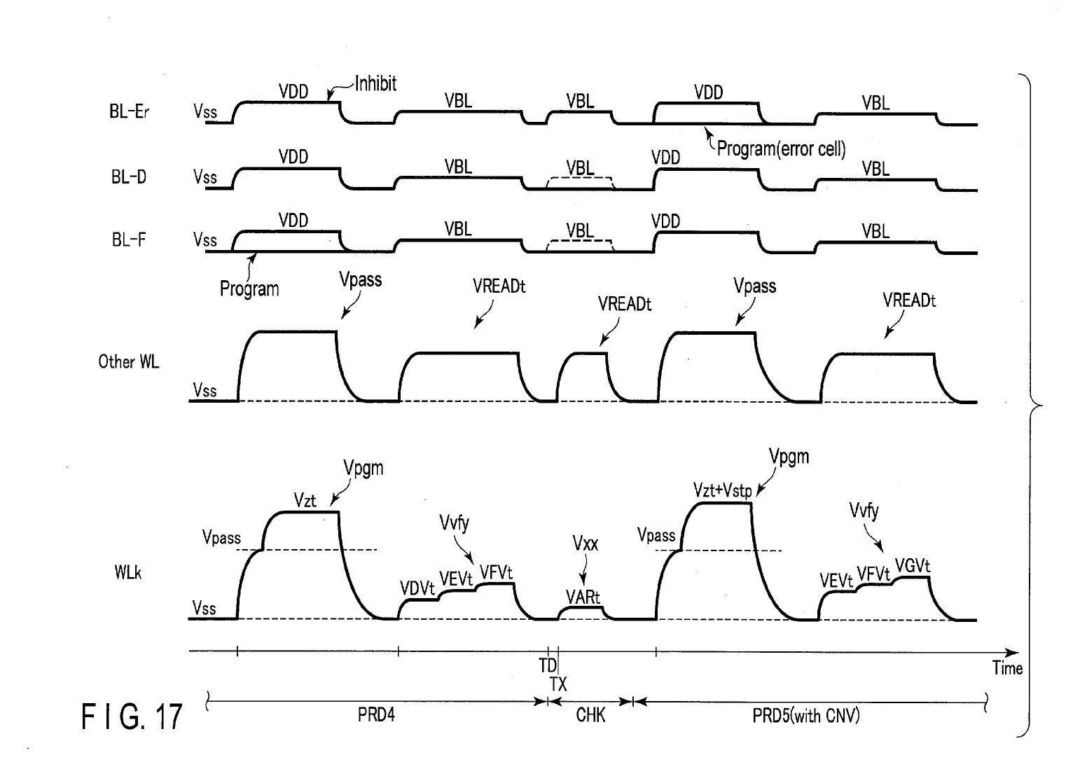

FIG. 17 shows a waveform chart of voltages applied to word lines and bit lines during write operation of the memory system according to the present embodiment.

As shown in FIG. 17, the program voltage Vpgm having a voltage value Vzt (≧V7t) is applied at a certain time.

At a certain time, the verify voltage Vvfy is applied to the selected word line WLk for program verification of the “D” level. For example, the verify voltage Vvfy includes the verify levels VDVt, VEVt, VFVt concerning the “D” level, the “E” level, and the “F” level in the program verification of the “D” level. Thus, in the write operation of the flash memory of TLC, the verify voltage Vvfy during programming includes, in addition to the verify level of the lowest level for the programming target, verify levels one level and two levels higher than the verify level of the programming target level. Incidentally, the verify voltage Vvfy in TLC may include two verify levels or four verify levels or more.

In the program verification in a period PRD4 when programming of levels equal to the “D” level or more is performed, if all memory cells MC that should hold data of the “D” level are verify-passed memory cells (if the number of write loops reaches a predetermined number of times), programming of the “D” level is completed. As shown in FIG. 16, the signal pcomp-D is set to the high level at time TD.

After programming for memory cells that should hold data of the “D” level is completed, an error check voltage Vxx including the reading level VARt is applied to the selected word line WLk for the error check operation in the period CHK beginning at time TX.

If memory cells that should hold data of the “Er” level are turned off when the reading level VARt is applied in the error check period CHK, memory cells of the “Er” level in an off state have a threshold voltage higher than the reading level VARt. That is, memory cells of the “Er” level in an off state when the reading level VARt is applied includes an error in data to be held.

Thus, memory cells in error concerning the “Er” level are detected by applying the error check voltage Vxx.

After the error check operation, programming of data of levels equal to the “E” level or more is performed using the program voltage Vpgm having a voltage value Vzt+Vstp for error cells of the “Er” level together with memory cells that should hold data of the “E” level.

After the program voltage Vpgm is applied, the verify voltage Vvfy concerning the “E” level is applied to the selected word line WLk. In a period PRD5 in which programming of levels equal to the “E” level or more is performed, the verify voltage Vvfy includes the verify levels VEVt, VFVt, VGVt concerning the “E” level, the “F” level, and the “G” level.

Based on the verify results, whether programming of the “E” level is passed is determined for each memory cell.

If the verify result of, among memory cells MT that should hold the “E” level, the memory cell MT is a failure, the voltage value of the program voltage is raised and then, a program operation and a verify operation are performed.

The signal pcomp-E is set to the high level at time TE when programming for the memory cells MT that should hold the “E” level is determined to be complete.

After programming for the memory cells that should hold data of the “E” level is completed, programming for memory cells that should hold data of the “F” level or the “G” level is performed in a period PRD6.

In the manner described above, writing of data of the “E” level into memory cells of the “Er” level including an error is performed.

If, as a result, an error bit arises in an “Er” level cell, data (“110” data) including an error in the lower bit is converted into data (“011” data) including an error in the upper bit.

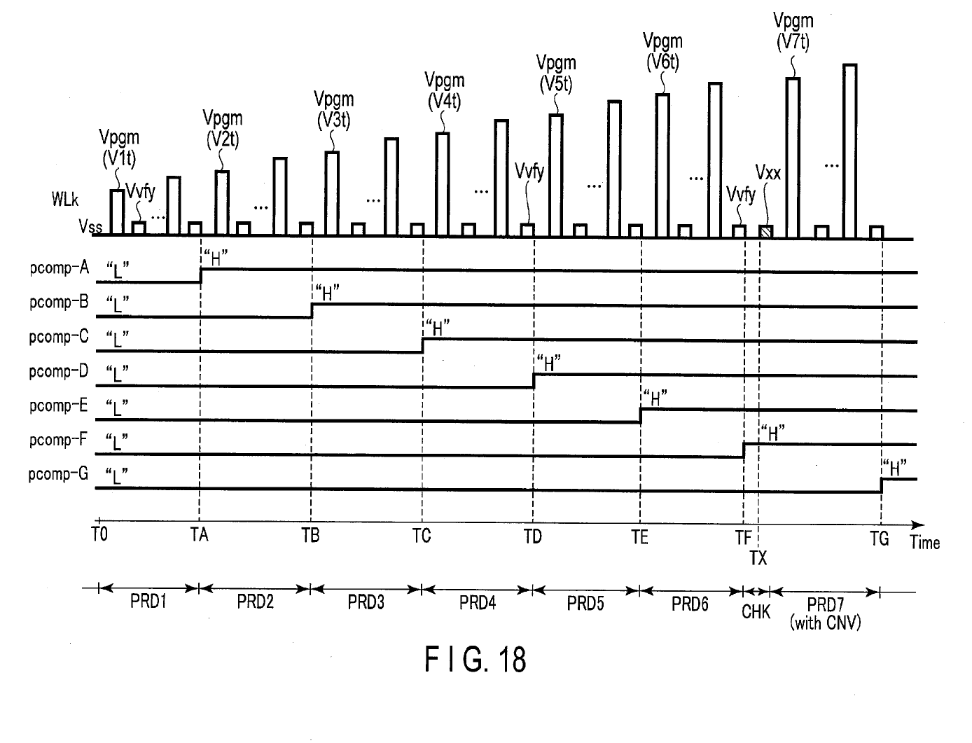

FIG. 18 is a timing chart showing a modification of the operation in FIGS. 16 and 17.

As shown in (b) of FIG. 15, regarding an error of a memory cell o the “Er” level, an error of the lower bit may be converted into an error of the middle bit.

In this case, as shown in FIG. 18, an error check operation is not performed after programming of the “D” level is completed and after programming of the “F” level is completed (after the signal pcomp-F changes from the low level to the high level), an error check operation using the reading level VARt is performed in the error check period CHK. While the error check operation is performed (error check period) CHK, programming of the “F” level is not completed and the signal pcomp-G is set to the low level.

Then, a program operation of the “G” level and program verification of the “G” level are performed for the detected error cells together with memory cells that should hold data of the “G” level.

If, as a result, an error bit arises in an “Er” level memory cell, data (“110” data) including an error in the lower bit is converted into data (“101” data) including an error in the middle bit.

Incidentally, an error check operation may be performed both after completion of programming of the “D” level and after completion of programming of the “F” level in one write operation. In this case, data of the “E” level or the “G” level is programmed into the detected error cell in accordance with the timing of the error check operation.

As described above, the memory system according to the present embodiment can suppress an uneven distribution of errors in a certain page and level the number of errors in a plurality of pages allocated to a certain word line.

Therefore, a memory system according to the present embodiment can improve reliability of data.

### (2b-2) Second Example

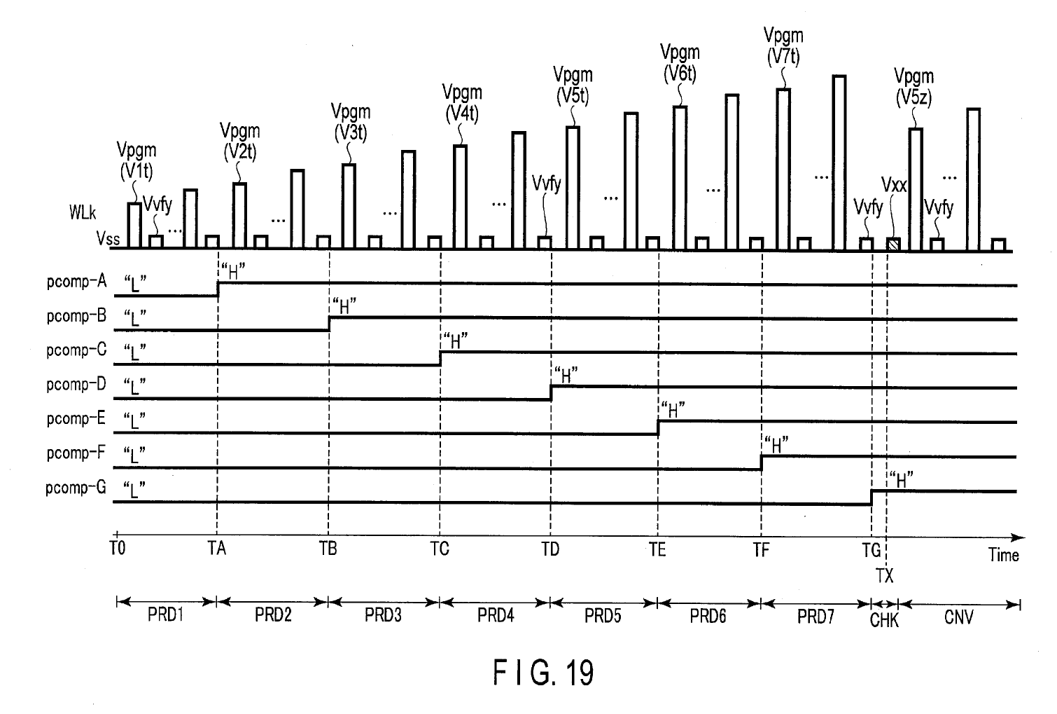

A second example of the operation example of the memory system according to the present embodiment will be described with reference to FIG. 19.

FIG. 19 is a timing chart schematically showing an overall flow of the write operation of the flash memory according to the present embodiment.

As shown in FIG. 19, programming of data is performed from the “A” level to the “G” level without error check operation. Then, after programming of the “G” level as the highest level of TLC is completed, an error check operation and an error conversion operation are performed.

At this point, the program operation for the error conversion operation may be a program operation using the program voltage Vpgm having the voltage value in the period PRD5 or a program operation using the program voltage Vpgm having the voltage value in the period PRD7.

Accordingly, in a memory cell of the “Er” level including an error, data (“110”) including an error of the lower bit is converted into data including an error (“011”) of the upper bit or an error (“101”) of the middle bit.

### (2c) Summary

As described above, a memory system according to the present embodiment can perform an error check operation and an error conversion operation on memory cells of the “Er” level for the flash memory including TLC.

In the memory system according to the present embodiment, an error of a certain one bit in data of a memory cell of the “Er” level is converted into an error of another one bit in the data.

As a result, even if the number of bits of data that can be held by one memory cell increases in the memory system according to the present embodiment, an uneven distribution of error bits in a certain page can be suppressed.

The memory system according to the present embodiment can, as described above, improve reliability of data and upgrade operation characteristics.

### (3) Third Embodiment

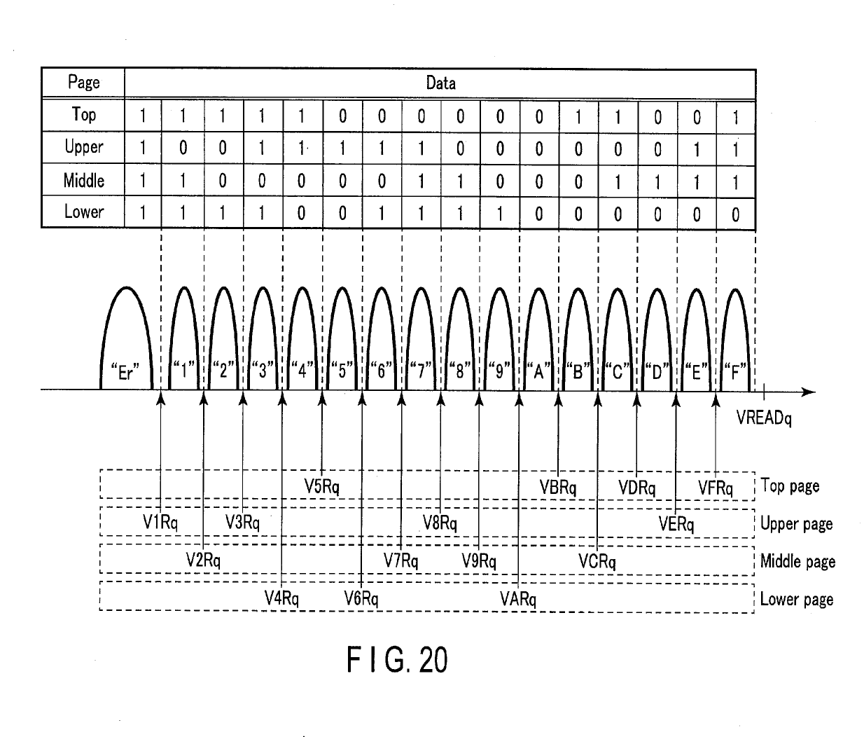

A memory system according to a third embodiment will be described with reference to FIGS. 20 to 23.

### (3a) Configuration Example

A configuration example of the memory system according to the third embodiment will be described using FIG. 20.

In the memory system according to the third embodiment, QLC (Quadruple Level Cell) is used for memory cells of a flash memory. In QLC, one memory cell can hold 4-bit data.

FIG. 20 is a diagram showing data that can be taken by each memory cell MT in QLC, the threshold distribution, and the voltage used for reading.

As shown in FIG. 20, 4-bit data for each memory cell MT includes a top bit, in addition to a lower bit, a middle bit, and an upper bit. The top bit is bit higher than the upper bit. When 4-bit data is written, the top bit, the upper bit, the middle bit, and the lower bit are written in this order as each digit of 4 bits from the left side toward the right side of the paper surface. A set of top bits is called a top page.

In a flash memory using QLC, four pages are allocated to one word line WL and a block BLK including eight word lines WL has the capacity for 32 pages.

Hereinafter, 16 levels corresponding to 4-bit data in QLC are called an “Er” level, a “1” level, a “2” level, . . . , a “E” level, and an “F” level in ascending order of threshold voltage.

The threshold voltage of the memory cell MT holding the “Er” level (“1111” data) is less than a reading level V1Rq and corresponds to an erase state. For example, the threshold voltage of the memory cell MT of the “Er” level a negative voltage.

The threshold voltage of the memory cell MT holding the “1” level (“1011” data) is equal to the reading level V1Rq or more and less than a reading level V2Rq(>V1Rq).

The threshold voltage of the memory cell MT holding the “2” level (“1001” data) is equal to the reading level V2Rq or more and less than a reading level V3Rq(>V2Rq).

The threshold voltage of the memory cell MT holding the “3” level (“1101” data) is equal to the reading level V3Rq or more and less than a reading level V4Rq(>V3Rq).

The threshold voltage of the memory cell MT holding the “4” level (“1100” data) is equal to the reading level V4Rq or more and less than a reading level V5Rq(>V4Rq).

The threshold voltage of the memory cell MT holding the “5” level (“0100” data) is equal to the reading level V5Rq or more and less than a reading level V6Rq(>V5Rq).

The threshold voltage of the memory cell MT holding the “6” level (“0101” data) is equal to the reading level V6Rq or more and less than a reading level V7Rq(>V6Rq).

The threshold voltage of the memory cell MT holding the “7” level (“0111” data) is equal to the reading level V7Rq or more and less than a reading level V8Rq(>V7Rq).

The threshold voltage of the memory cell MT holding the “8” level (“0011” data) is equal to the reading level V8Rq or more and less than a reading level V9Rq(>V8Rq).

The threshold voltage of the memory cell MT holding the “9” level (“0001” data) is equal to the reading level V9Rq or more and less than a reading level VARq(>V9Rq).

The threshold voltage of the memory cell MT holding the “A” level (“0000” data) is equal to the reading level VARq or more and less than a reading level VBRq(>VARq).

The threshold voltage of the memory cell MT holding the “B” level (“1000” data) is equal to the reading level VBRq or more and less than a reading level VCRq(>VBRq).

The threshold voltage of the memory cell MT holding the “C” level (“1010” data) is equal to the reading level VCRq or more and less than a reading level VDRq(>VCRq).

The threshold voltage of the memory cell MT holding the “D” level (“0010” data) is equal to the reading level VDRq or more and less than a reading level VERq(>VDRq).

The threshold voltage of the memory cell MT holding the “E” level (“0110” data) is equal to the reading level VERq or more and less than a reading level VFRq(>VERq).

The threshold voltage of the memory cell MT holding the “F” level (“1110” data) is equal to the reading level VERq or more and less than a non-selection voltage VREADq. Among 16 levels corresponding to 4-bit data, the “F” level corresponds to the highest level of threshold voltage.

When one memory cell MT holds 4-bit data, four latch circuits are provided to hold data to be stored. As, two latch circuits or more are provided for verify results (reading results) and operation processes.

In the example shown in FIG. 20, only the value of 1 bit of 4 bits changes between data corresponding to neighboring threshold distributions.

Even if the number of bits of data is 4 bits, the voltage corresponding to the boundary where the value (“0” or “1”) of the lower bit changes may be used to read the lower bit. This also applies to reading of the middle bit, the upper bit, and the top bit.

As shown in FIG. 20, three reading level V4Rq, V6Rq, VARq are used to read the lower page. The reading level V4Rq is used to distinguish between levels equal to the “3” level or less and levels equal to the “4” levels or more. The reading level V6Rq is used to distinguish between levels equal to the “5” level or less and levels equal to the “6” levels or more. The reading level VARq is used to distinguish between levels equal to the “9” level or less and levels equal to the “A” levels or more.

Reading of the middle page is performed using four reading levels V2Rq, V7Rq, V9Rq, vCRq. The reading level V2Rq is used to distinguish between levels equal to the “1” level or less and levels equal to the “2” levels or more. The reading level V7Rq is used to distinguish between levels equal to the “6” level or less and levels equal to the “7” levels or more. The reading level V9Rq is used to distinguish between levels equal to the “8” level or less and levels equal to the “9” levels or more. The reading level VCRq is used to distinguish between levels equal to the “B” level or less and levels equal to the “C” levels or more.

Reading of the upper page is performed using four reading levels V1Rq, V3Rq, V8Rq, VERq. The reading level V1Rq is used to distinguish between the “Er” level and levels equal to the “1” levels or more. The reading level V3Rq is used to distinguish between levels equal to the “2” level or less and levels equal to the “3” levels or more. The reading level V8Rq is used to distinguish between levels equal to the “7” level or less and levels equal to the “8” levels or more. The reading level VERq is used to distinguish between levels equal to the “D” level or less and levels equal to the “E” levels or more.

Reading of the top page is performed using four reading levels V5Rq, VBRq, VDRq, VFRq.

The reading level V5Rq is used to distinguish between levels equal to the “4” level or less and levels equal to the “5” levels or more. The reading level VBRq is used to distinguish between levels equal to the “A” level or less and levels equal to the “B” levels or more. The reading level VDRq is used to distinguish between levels equal to the “C” level or less and levels equal to the “D” levels or more. The reading level VFRq is used to distinguish between levels equal to the “E” level or lower and the “F” level.

In QLC, like in MLC and TLC, the threshold voltage of “Er” level cells may exceed the reading level V1Rq concerning the level (here, the “1” level) adjacent to the “Er” level.

Thus, in the flash memory using QLC, errors may unevenly be distributed in a certain page due to the rise of the threshold voltage of the memory cell MT of the “Er” level to the reading level V1Rq or more.

The memory system according to the present embodiment determines, like in the first and second embodiments, whether the threshold voltage of the memory cell MT of the “Er” level is equal to the reading level V1Rq or more between the “Er” level and the level adjacent to the “Er” level.

Based on the determination result, an error of the memory cell MT of the “Er” level is detected.

In the example shown in FIG. 20, the shift of the threshold voltage from the “Er” level to the “1” level in QLC causes an error of the upper bit. If the threshold voltage of the memory cell MT of the “Er” level shifts to the reading level V1Rq between the “Er” level and the “1” level or more, an error of the upper bit is caused in data.

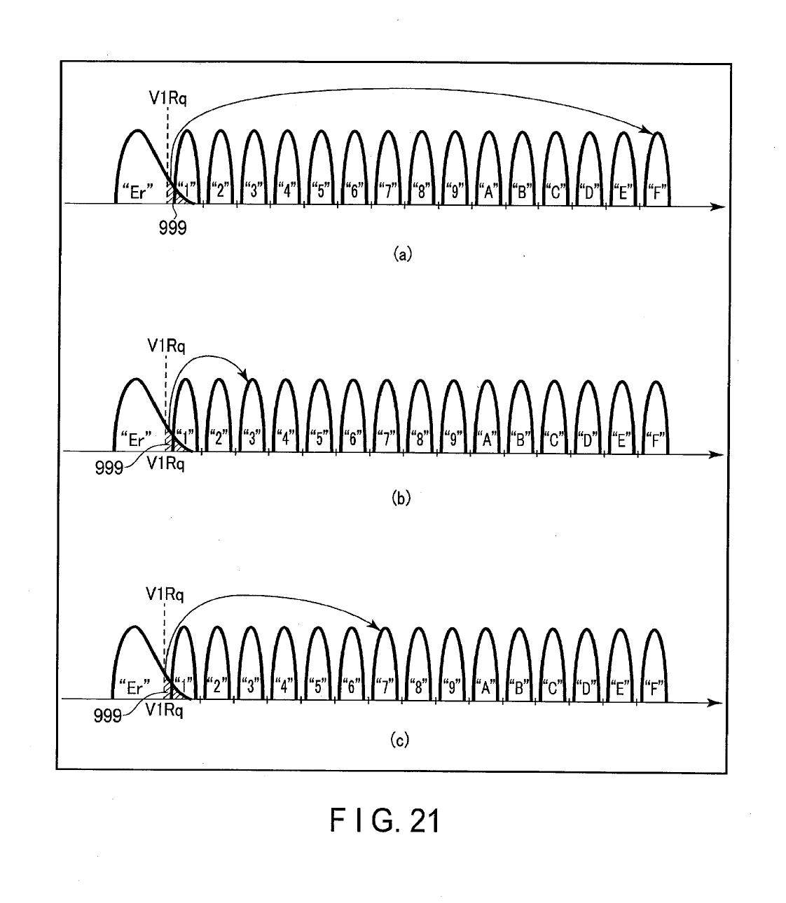

FIG. 21 is a pattern diagram illustrating an error conversion process in the memory system according to the present embodiment.

In the present embodiment, as shown in (a), (b) and (c) of FIG. 21, an error of the upper bit concerning the “Er” level can be converted into one of an error of the lower bit, an error of the middle bit, and an error of the top bit.

As shown in (a) of FIG. 21, data (“1011” data) in which an error of the upper bit at the “Er” level occurred can be converted into data (“1110”) including an error of the lower bit. In this case, the threshold voltage of the error cell at the “Er” level is shifted to the threshold voltage corresponding to the “F” level by a program operation.

As shown in (b) of FIG. 21, data including an error of the upper bit at the “Er” level may be converted into data (“1101” data) including an error of the middle bit. In this case, the threshold voltage of the error cell at the “Er” level is shifted to the threshold voltage corresponding to the “3” level by a program operation.

As shown in (c) of FIG. 21, data including an error of the upper bit at the “Er” level may be converted into data (“0111” data) including an error of the top bit. In this case, the threshold voltage of the error cell MT at the “Er” level is shifted to the threshold voltage corresponding to the “7” level by a program operation.

However, it is preferable to determine to shift the threshold voltage of a memory cell of the “Er” level including an error to the threshold voltage of which level based on at least one result of experiments and simulations by considering the frequency of occurrence of error bits of each bit of 4 bits.

When 4-bit data is coded for the threshold voltage of memory cells as shown in FIG. 20, the frequency of occurrence of errors of the upper bit is the highest, the frequency of occurrence of errors of the top bit is the second highest, and the frequency of occurrence of errors of the middle bit is the third highest. The frequency of occurrence of errors of the lower bit is the lowest. Thus, when coding in FIG. 20 is applied, in consideration of the frequency of occurrence of errors between pages, it is preferable to convert memory cells of the “Er” level including an error of the upper bit into those of the “F” level (lower bit error) or the “3” level (middle bit).

Bits where errors are more likely to occur at each level are different by 4-bit coding (arrangement of the top bit, the upper bit, the middle bit, and the lower bit at each level) being changed. As a tendency of occurrence of error bits, for example, the frequency of occurrence of error bits is the lowest in a page with a fewer number of times of determination by applying the reading level per page.

Thus, when a relation of data and the threshold voltage that is different from the example shown in FIG. 20 is applied to the NAND flash memory of QLC, it is preferable to appropriately determine the level (data) into which an error of the memory cell of the “Er” level is converted by considering the frequency of occurrence of error bits and the number of times of determination per page.

The memory system according to the present embodiment can, as described above, improve reliability of data and upgrade operation characteristics.

### (3b) Operation Example

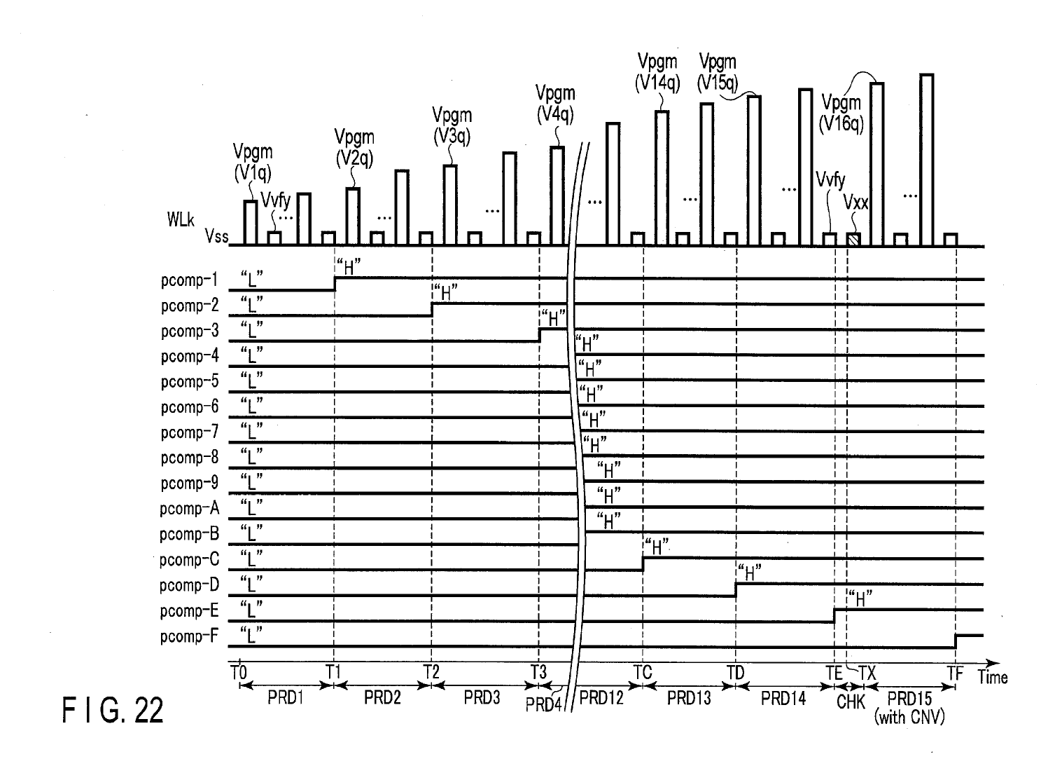

An operation example of the memory system according to the third embodiment will be described with reference to FIG. 22.

FIG. 22 is a timing chart illustrating a rough flow of the operation example of the memory system according to the present embodiment. In FIG. 22, an example in which when a memory cell of the “Er” level in the flash memory of QLC includes an error, data including the error is converted into data of the “F” level is shown.

Regarding more detailed waveforms of voltages applied to word lines/bit lines, only the voltage value of each voltage is different and waveforms thereof are substantially the same as those shown in FIGS. 17 to 19. Thus, in the present embodiment, a concrete description of more detailed voltage waveforms of word lines/bit lines is omitted.

As shown in FIG. 22, like the above example, a write operation of the flash memory of QLC is performed by the full sequence method. When, substantially like the above example, the completion of programming of a certain level is detected by a verify operation, signal levels of signals pcomp-1, pcomp-2, . . . , pcomp-F are controlled at times T1, T2, T3, . . . , TE, TF. In each period PRD1, PRD2, PRD3, . . . , PRD14, PRD15, programming of data is continued for memory cells for which writing of desired data is not completed.

After the completion of programming of the “E” level is detected based on the signal pcomp-E at the high level at time TE, in the period CHK, a voltage Vxx including the reading level V1Rq is applied to a selected word line WLk. An error check operation concerning the “Er” level using the reading level V1Rq is thereby performed.

During error check operation, memory cells in an off state among memory cells MT that should hold the “Er” level have a threshold voltage higher than the “Er” level and include an error in data that should be held by the memory cell MT.

In the memory system according to the present embodiment, writing of data of the “F” level into the error cell MT of the “Er” level is performed simultaneously with a program operation (and a verify operation) for the memory cells MT that should hold the “F” level in a period PRD15.

Accordingly, the position (digit, page) of the error bit in the data held by the memory cell MT is changed from the upper bit to the lower bit.

In the present embodiment, as a result, data (“1011” data) including an error of the upper bit is converted into data (“1110” data) of the “F” level in the error cell of the “Er” level.

Incidentally, in a flash memory using QLC, an error of a memory cell of the “Er” level detected during write operation may be converted into an error of the middle bit or the top bit.

When data including an error in the upper bit at the “Er” level is converted into an error of the middle bit, an error check operation of the “Er” level is performed by applying the reading level V1Rq to the selected word line WLk after the completion of programming for memory cells that should hold data of the “2” level is detected. If an error is detected by the error check operation after the completion of programming of data of the “2” level is detected, the threshold voltage of an error cell of the “Er” level is shifted to the value corresponding to the “3” level (“1101” data) by a program operation.

When data including an error in the upper bit at the “Er” level is converted into an error of the top bit, an error check operation concerning the “Er” level is performed after the completion of programming of data of the “6” level is detected. If an error is detected by the error check operation after the completion of programming of data of the “6” level is detected, the threshold voltage of an error cell of the “Er” level is shifted to the value corresponding to the “7” level (“1101” data) by a program operation.

Incidentally, an error conversion process of the error cell of the “Er” level into two levels or more of the “3” level, the “7” level, and the “F” level.

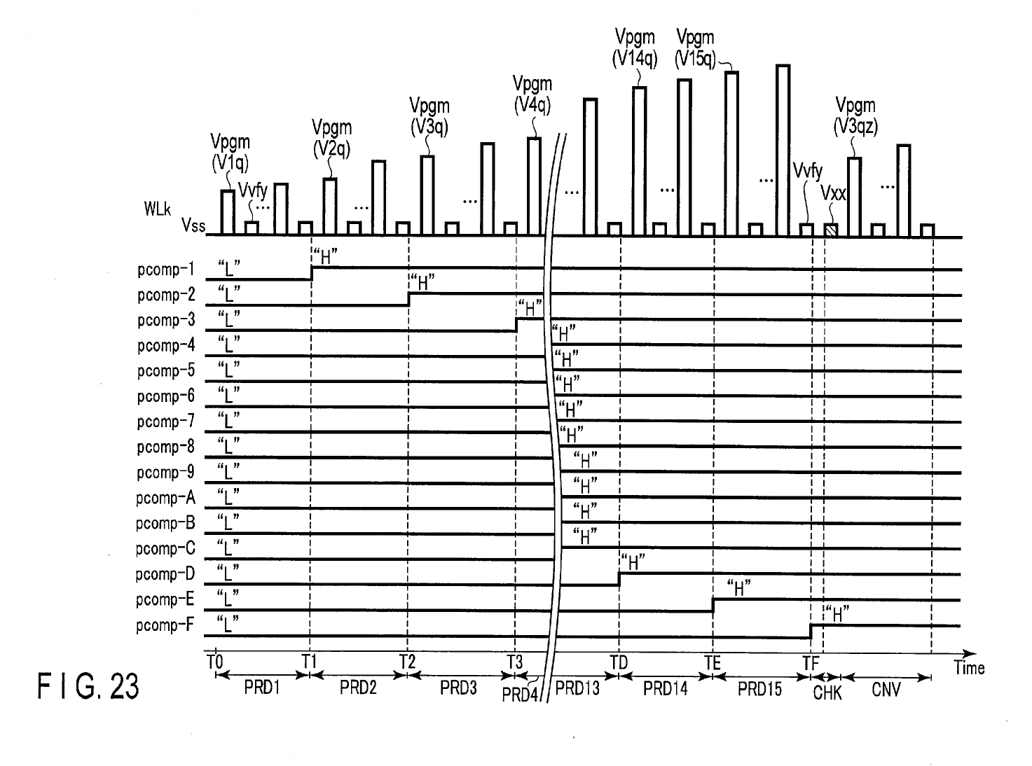

FIG. 23 is a pattern diagram showing a modification of the operation example of the flash memory of the memory system according to the present embodiment.

As shown in FIG. 23, an error check may be done after programming from the “1” level to the “F” level.

Programming (programming of the “3” level in FIG. 23) for the conversion process of an error bit of the “Er” level is performed based on the result of an error check operation after programming (after the period PRD15) for memory cells that should hold data of the “F” level as the highest level in QLC in the period CNV.

A program operation is performed for a memory cell of the “Er” level in such a way that an error of a certain digit (1 bit) included in the memory cell of the “Er” level is converted into an error of another digit.

When, for example, as shown in FIG. 21, an error that occurs in a memory cell of the “Er” level is an error of the upper bit, a program operation of at least one of the “3” level, the “7” level, and the “F” level is performed for the error cell of the “Er” level so that the error is converted into at least one of errors of the lower bit, the middle bit, and the top bit.

As described above, the memory system according to the third embodiment can, like the memory systems in the first and second embodiments, suppress an uneven distribution of error bits in a certain page and level the number of errors in the page between a plurality of page.

Therefore, the memory system according to the third embodiment can achieve substantially the same effects as the memory systems in the first and second embodiments.

### (4) Fourth Embodiment

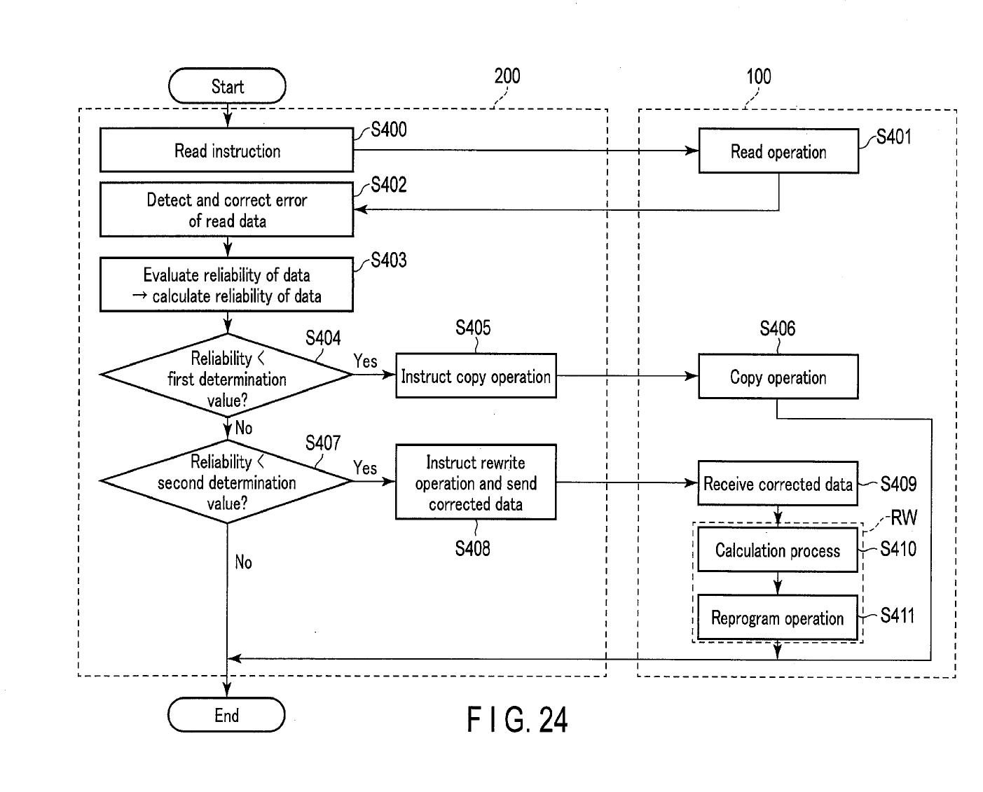

A memory system according to a fourth embodiment and a control method thereof will be described with reference to FIGS. 24 to 33.

The memory system according to the present embodiment performs, when an error of a memory cell of the “Er” level is detected by an ECC process for data read from a flash memory 100, a conversion process of the bit (page) where the error occurred is performed for the memory cell (error cell) where the error of data was detected.

In the flash memory, the threshold voltage of a memory cell may fall below a value corresponding to data to be stored due to aging. In such a case, an error occurs in data. An error in data caused by the fall of the threshold voltage of a memory cell can be corrected by additionally injecting charges into the charge storage layer of the memory cell.

The error cell of the data caused by the fall of the threshold voltage of the memory cell may be detected based on the result of the ECC process inside the read data so that a rewrite operation (program operation) of data is performed for the detected error cell.

When an error of data caused by the fall of the threshold voltage of a memory cell is detected based on the result of the ECC process when data is read, the memory system according to the present embodiment performs writing of data to be held into the error cell. Accordingly, the memory system according to the present embodiment corrects an error of data in the memory cell.

Accordingly, the memory system according to the present embodiment can reduce errors inside the memory cell array (blocks and pages).

### (4a) Operation Examples

Operation examples of the memory system according to the fourth embodiment will be described with reference to FIGS. 24 to 33.

### (4a-1) First Example

A first example of the operation example of the memory system according to the fourth embodiment will be described with reference to FIGS. 24 to 30.

In a standby state (period in which there is no access request from a host device 300) of a memory system 1, a patrol algorithm (hereinafter, called a patrol operation) may be performed as a background operation of the memory system 1 to manage the NAND flash memory 100.

In the memory system using the flash memory 100, the patrol operation is an algorithm that periodically performs reading of data and an ECC process of random pages before the flash memory 100 is degraded and data can no longer be read therefrom.

In the patrol operation, for example, the memory system 1 copies data of pages and blocks based on information obtained from results of the read operation.

As will be described below, the memory system 1 according to the present embodiment performs various processes to ensure reliability of data of the flash memory based on results of the read operation performed during patrol operation.

FIG. 24 is a flowchart illustrating the first example of the operation example of the memory system according to the present embodiment.

A controller 200 sends a read command and an address (for example, a randomly selected address) to the flash memory 100 without request from the host device 300 to perform a patrol operation (step S400).

In the NAND flash memory of MLC, for example, a command “02h” contained in the read command is a command to declare access to the upper page to the flash memory 100 and a command “00h” is a command indicating that an address will be input. When the lower page is accessed, “01h” is sent, instead of “02h”. The read commands “02h”, “00h” are stored in a command register 160 of the flash memory 100.

The controller 200 sends an address ADR of the area to be accessed and a command “30h” to the flash memory 100. The address ADR is stored in, for example, address register 150 and the command “30h” is stored in the command register 160. The command “30h” is a command to cause the flash memory 100 to perform a read operation.

In the flash memory 100, a sequencer 170 responds to the storage of the command “30h” in the command register 160 and starts a read operation of data from the page address held in the address register 150 (step S401). Accordingly, the flash memory 100 is made busy.

In the flash memory 100, a sense amplifier circuit 140 precharges a bit line BL to a predetermined potential. A row decoder 120 selects a word line WL corresponding to the address received from the controller 200. A driver circuit 130 applies a non-selection voltage VREADm to non-selected word lines WL and applies a read voltage to the selected word line WL. The read voltage includes one or more from a plurality of reading levels in FIG. 3 in accordance with the selected page. In the present embodiment, the read voltage includes a reading level VARm of the “A” level and a reading level VCRm of the “C” level during reading of the upper page.

Determination results using the reading levels VARm, VCRm are stored in latch circuits ADL, BDL, SDL. A calculation process of data in the latch circuits ADL, BDL, SDL is performed by the operation section OP. Accordingly, data of the selected page is determined. The determined data is transferred to a latch circuit XDL and the flash memory 100 is made ready.

As will be described below, the latch circuits ADL, BDL, SDL continue to hold data (determination results and calculation results) during reading of the upper page.

After the flash memory 100 being made ready, the controller 200 toggles a signal RE. In synchronization with the toggled signal RE, data in the latch circuit XDL is sent to the controller 200.

The controller 200 receives data read from the flash memory 100 (step S402). The controller 200 performs a detection process of error on the received data. If an error is detected, the controller 200 performs a correction process of the detected error.

In the present embodiment, reading of data may be repeated depending on whether or not the ECC process is successful. If, the example, the ECC process fails, reading of data from the memory cell of the selected address may be performed again after the value of the reading level is changed. For example, the value of the changed reading level may be set to a value obtained by adding a certain value dV to the reading level between neighboring threshold distributions or subtracting the value dV therefrom. Reading of data from a memory cell by determining whether or not the threshold voltage of the memory cell is higher than a certain reading level (or a corrected reading level) is called a hard bit determination (hard bit reading).

A soft bit determination (soft bit reading) using low density parity-check (LDPC) code or the like may be applied to the ECC process. For example, the soft bit determination is performed when an error of reading using a hard bit determination occurs.

In the soft bit determination, a plurality of determination levels is set to the boundary between two threshold distributions that should determine data (valley of distributions) and the neighborhood thereof. Data held by the memory cell is determined from the likelihood of a threshold voltage state of the memory cell based on the on/off determination result (soft bit information) of the memory cell using the plurality of determination levels. In the soft bit determination, for example, one reading level or more lower than a reading level used for the hard bit determination of a certain level (data) and one reading level or more higher than a reading level used for the hard bit determination of a certain level (data) are included.

In the present embodiment, the controller 200 evaluates reliability of data in the memory cell array using the read data (steps S404, S407).

For example, whether reliability of data in the flash memory 100 satisfies certain criteria is determined.

The controller 200 determines the operation to be performed to ensure reliability of data of the flash memory 100 based on the result of the ECC process using, for example, two different criteria (first and second determination values P1, P2).

The controller 200 generates an index (hereinafter, called a degree of reliability Q) indicating reliability of data in a memory cell array 110. The degree of reliability Q of data is calculated by a processor 230 based on at least one piece of information including information obtained from the hard bit determination and soft bit determination, the number of errors in the read data, the time needed for error detection and correction, information in a management table, and setting information in the flash memory.

The controller 200 determines processes to be performed on data in the flash memory 100 using the two determination values P1, P2. The first and second determination values P1, P2 are indexes indicating the extent to which it becomes impossible to read data due to degradation of the flash memory. The first and second determination values P1, P2 are, for example, values determined in advance based on experimental results, test processes or the like.

The controller 200 determines whether the degree of reliability Q is smaller than the first determination value P1 (step S404).

If the degree of reliability Q is smaller than the first determination value P1, the controller 200 instructs the flash memory 100 to perform a copy operation (step S405).

The flash memory 100 performs a copy operation so as to correspond to the instruction from the controller 200 (step S406). Based on known technology, the flash memory 100 copies data of a page whose reliability has been evaluated or data of a block including the page to a page or a block indicated by another address. Data read for the copy operation may be transferred to the controller 200, where an ECC process is performed thereon. With the completion of the copy operation, the patrol of the memory system 1 is finished.

If the degree of reliability Q is smaller than the first determination value P1, a high level of severity of the degradation of ECC-processed data is indicated. This indicates that physical degradation of a blocks BLK (for example, degradation of a tunnel dielectric film) is in an advanced stage. Thus, if reliability of data is determined to be low (degradation of data is serious) based on a certain criterium, it is preferable to perform a copy operation of data to ensure reliability of data.

If the degree of reliability. Q is equal to the first determination value P1 or more, the controller 200 determines whether the degree of reliability Q is smaller than the second determination value P2 (step S407). The second determination value P2 is a value larger than the first determination value P1.

If the degree of reliability Q is smaller than the second determination value P2, the controller 200 sends a command instructing to perform a rewrite operation (also called a refresh operation or additional writing) RW and data corrected by the ECC process to the flash memory 100 (step S408).

In the memory system 1 according to the present embodiment, the flash memory 100 performs a rewrite operation as described below.

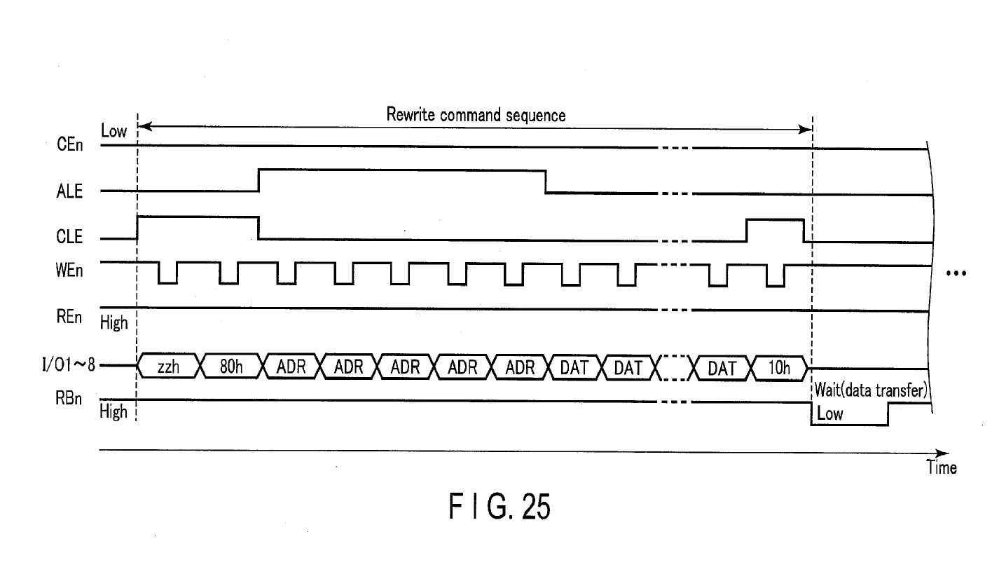

FIG. 25 is a timing chart of signals on a NAND bus of the rewrite operation of the flash memory in the memory system according to the present embodiment.

When, as shown in FIG. 25, a rewrite operation of data is performed, the controller 200 sends a prefix command “zzh” and a first write command 80h to the flash memory 100 while a signal CLE is asserted.

Subsequent to the commands “zzh”, “80h”, the controller 200 successively sends the address ADR and the data DAT to the flash memory 100 in substantially the same manner as the timing chart shown in FIG. 6. Here, data for one page is set to the flash memory 100. In the flash memory of MLC, however, data for two pages may be sent.

At this point, the controller 200 sends data (DAT) whose error has been corrected by the ECC process to the flash memory 100.

The data whose error has been corrected is data to be an expected value that should originally be stored in the flash memory 100. Hereinafter, data whose error has been corrected by the ECC process will be called corrected data (or expected value data). The flash memory 100 receives corrected data (step S409). The corrected data is stored in the latch circuit XDL.

After sending the address ADR and data DAT, the controller 200 asserts the signal CLE and sends a second write command “10h” to the flash memory 100. The flash memory 100 receives the command “10h” and stores data stored in the latch circuit XDL in the latch circuit.

The flash memory 100 starts an operation corresponding to the commands “zzh”, “80h”, “10h”. The flash memory 100 detects that the program operation to be performed is a rewrite operation during patrol operation based on the prefix command “zzh”.

The rewrite operation RW includes a calculation process (step S410) and a reprogram operation (step S411).

In the rewrite operation, the sequencer 170 performs a calculation process using corrected data and reading results from inside the latch circuits ADL, BDL, SDL by each sense amplifier unit SAU to determine whether programming of data in each memory cell in a page is needed (step S410). Accordingly, an error cell in the page is detected (identified).

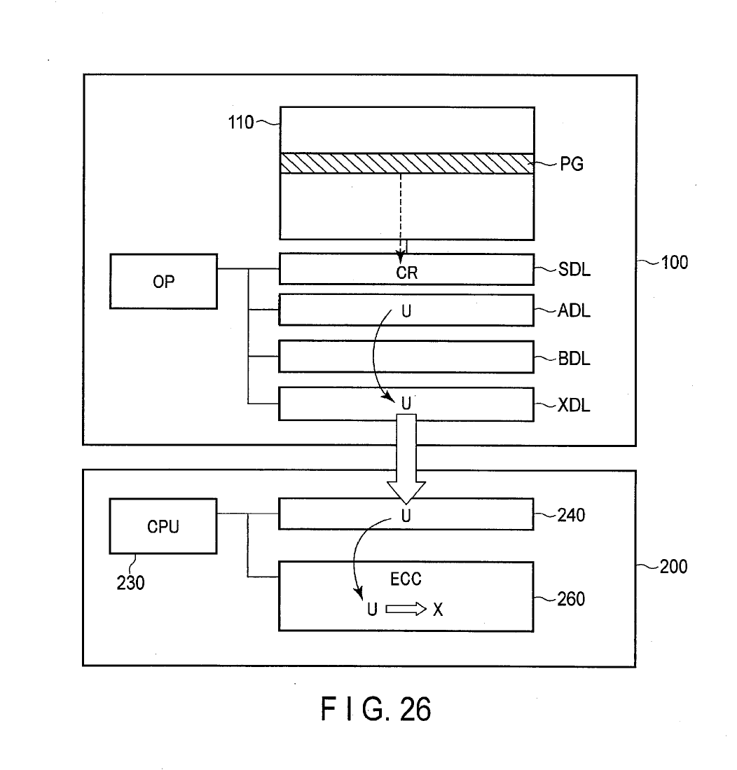

FIGS. 26 to 29 are pattern diagrams illustrating a determination process for a rewrite operation in the flash memory of the memory system according to the present embodiment.

Here, the determination process of a rewrite operation using corrected data when upper data in the flash memory of MLC is read will be described.

FIG. 26 schematically shows a data holding state of latch circuits of the flash memory when data is read in a patrol operation of the memory system (step S401 in FIG. 24).

As shown in FIG. 26, when an upper page is read in a patrol operation of the flash memory of MLC (step S401 described above), reading of the “C” level is performed after reading of the “A” level.

A reading result (upper data) U is determined by a calculation process of the operation section OP and data U is stored in the latch circuit ADL.

Thus, even if the determination process using two reading levels VARm, VCRm is performed when the upper page is read, only a reading result CR using the reading level VCRm is stored in the end inside the latch circuit SDL corresponding to each memory cell (bit line).

The upper data U is transferred from the latch circuit ADL to the latch circuit XDL.

The flash memory 100 sends the upper data U in the latch circuit XDL to the controller 200.

The controller 200 stores the upper data U in a buffer memory 240. In the controller 200, an ECC circuit 260 detects an error of the upper data U in the buffer memory 240 and corrects the detected error (step S402 described above). Accordingly, corrected data X is generated.

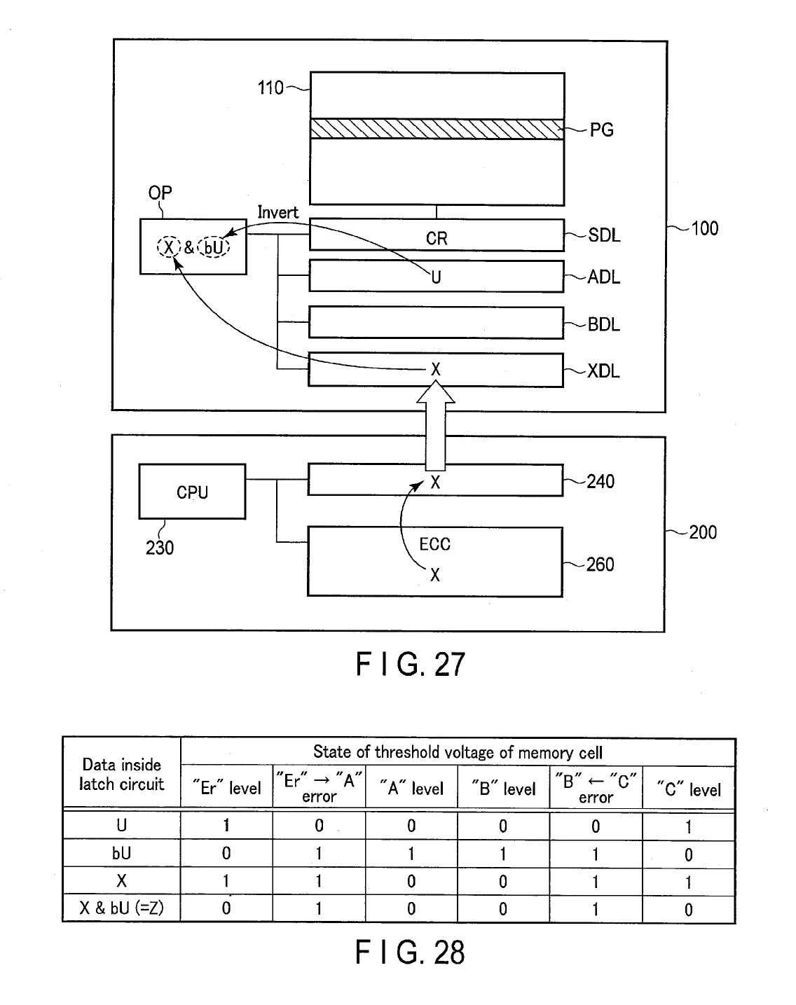

FIG. 27 schematically shows a data holding state of latch circuits of the flash memory when a determination process for the rewrite operation in the patrol operation of the memory system is performed.

As shown in FIG. 27, in steps S408, S409 described above, the corrected data X is transferred from the buffer memory 240 to the latch circuit XDL. The latch circuit XDL of each sense amplifier unit SAU has corresponding 1-bit data of a plurality of bits contained in the corrected data X stored therein.

In the ECC process by the controller 200, the latch circuit ADL continues a holding state of the upper data U inside the flash memory 100.

The operation section OP performs an AND operation (X&bU) of inverted data bU of the upper data U and the corrected data X.

Hereinafter, “&” indicates that the calculation process is an AND operation.

FIG. 28 is a diagram showing data in each latch circuit during rewrite operation.

As shown in FIG. 28, when the upper data U (data in the latch circuit ADL) read from the memory cell MT is “1”, the inverted data bU is “0”. When the reading result of the upper data U from the memory cell MT is “0”, the inverted data bU is “”.

In the latch circuits ADL, BDL, SDL corresponding to memory cells of the “Er” level, the inverted data bU is 0 and the data X is 1. Thus, regarding memory cell of the “Er” level, the result of an AND operation (X&bU) is 0.

In the latch circuits ADL, BDL, SDL corresponding to memory cells of the “A” level, the inverted data bU is 1 and the data X is 0. Thus, regarding memory cell of the “A” level, the result of an AND operation (X&bU) is 0.

In the latch circuits ADL, BDL, SDL corresponding to memory cells of the “B” level, the inverted data bU is 1 and the data X is 0. Thus, regarding memory cell of the “B” level, the result of an AND operation (X&bU) is 0.

In the latch circuits ADL, BDL, SDL corresponding to memory cells of the “C” level, the inverted data bU is 0 and the data X is 1. Thus, regarding memory cell of the “C” level, the result of an AND operation (X&bU) is 0.

Here, if the threshold voltage of a memory cell of the “Er” level changes to a value corresponding to data of the “A” level or more due to an unintended rise of the threshold voltage, the data U becomes 0. In this case, the result of an AND operation (X&bU) of the data X (X=1) and the data bU (bU=1) is 1.

Also, if the threshold voltage of a memory cell of the “C” level changes to a value corresponding to data of the “B” level due to an unintended fall of the threshold voltage, like an error of the upper bit of a memory cell of the “Er” level, the data U becomes 0. In this case, the result of an AND operation (X&bU) of the data X (X=1) and the data bU (bU=1) is 1.

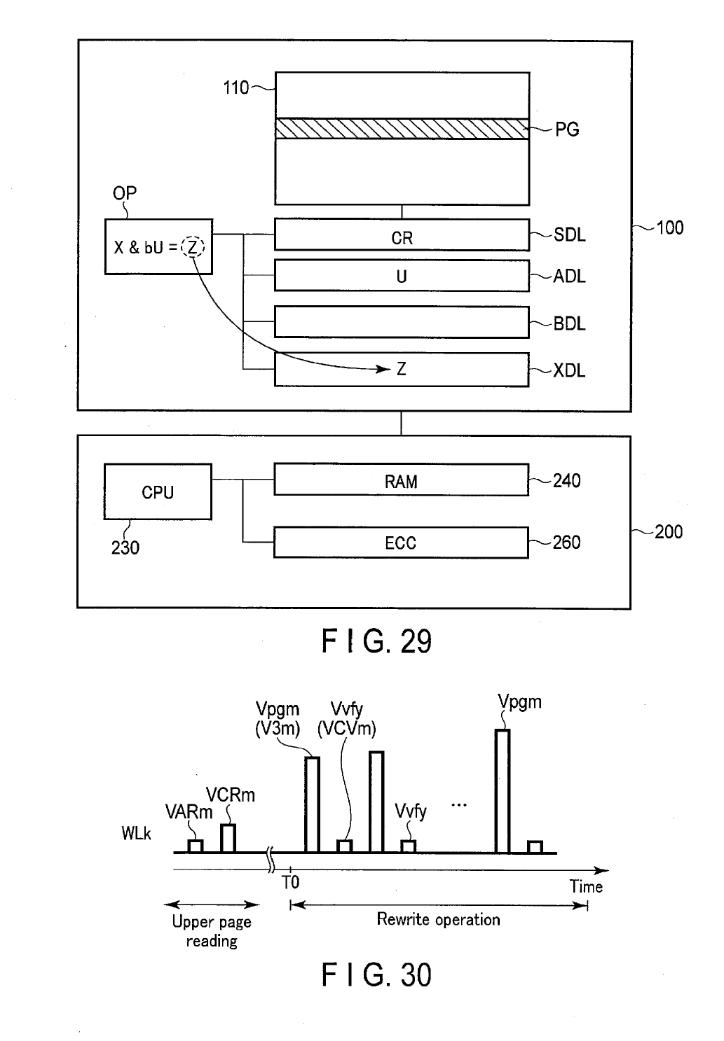

FIG. 29 schematically shows a data holding state of latch circuits of the flash memory when a determination process for the rewrite operation of the patrol operation of the memory system is performed.

As shown in FIG. 29, a result Z (=X&bU) of an AND operation is stored in the latch circuit XDL in each sense amplifier unit SAU. Here, the result of an AND operation of the corrected data X and the inverted data bU in each sense amplifier unit SAU is one of “0” and “1”.

As shown in FIG. 28 described above, if the result Z of an AND operation in a certain sense amplifier unit SAU (memory cell MT) is “0”, the corrected data X and the data U in the latch circuit ADL match. In this case, regarding the upper data (upper bit) held by the sense amplifier unit SAU, the result Z of calculation of “0” indicates that no error has occurred in the data U.

If the result Z of an AND operation in a certain sense amplifier unit SAU is “1”, the upper data IT is “0” (bU=“1”) and the corrected data X is “1”.

In this case, regarding the upper data (upper bit) held by the sense amplifier unit SAU, the result of an AND operation of “1” indicates the existence of an error due to the rise of the threshold voltage of the memory cell MT from the “Er” level to the “A” level or the existence of an error due to the fall of the threshold voltage of the memory cell MT from the “C” level to the “B” level.

In this manner, a memory cell in which an error occurs in the upper bit is detected by an AND operation process using the corrected data X and the reading result U (bU) from inside latch circuits.

The flash memory 100 performs programming (reprogramming) of the “C” level for the memory cell MT corresponding to the latch circuit XDL holding the result Z of calculation of “1” (step S411).

FIG. 30 is a timing chart showing a rough flow of the reprogramming operation during patrol operation in the memory system according to the present embodiment. Incidentally, voltages applied to the word lines and bit lines in the present example are similar to those shown in FIG. 8 or FIG. 11 and thus, an illustration and a description thereof here are omitted.

During read operation (step S401) before the rewrite operation, as shown in FIG. 30, reading levels VARm, VCRm of the “A” level and the “C” level are applied to the selected word line WLk to read upper data. The memory cell to be reprogrammed is detected based on the determination process in FIGS. 27 to 29 based on the reading result and the result of the ECC process.

The voltage of 0 V is applied to the bit line BL corresponding to the memory cell (error cell) to be reprogrammed based “1” data in the latch circuit XDL obtained by the determination process (see FIG. 28). Based on “0” data in the latch circuit XDL, the voltage VDD is applied to the bit line BL corresponding to reprogramming inhibited memory cells (memory cells in which no error is detected).

The program voltage Vpgm having a certain voltage value V3m is applied to the selected word line WLk for programming of the “C” level.

The threshold voltage of the error cell of the “Er” level is shifted toward the value corresponding to the “C” level by applying the program voltage Vpgm.

Programming of the “C” level is performed for the error cell of the “C” level simultaneously with the error conversion process for memory cells of the “Er” level. Accordingly, the threshold voltage of the error cell of the “C” level is brought back from the value corresponding to the “B” level to the value corresponding to the “C” level.

After the program voltage Vpgm is applied, the verify voltage Vvfy is applied to the selected word line WLk. The voltage value of the verify voltage Vvfy is set to the verify level VCVm of the “C” level.

When a verify-failed memory cell is detected, a step-up voltage of certain magnitude is added to the voltage value of the program voltage Vpgm in the last write loop to perform the next write loop. In the next write loop, after reprogramming for the verify-failed memory cell, the verify level VCVm is applied to the selected word line WLk. Accordingly, the threshold voltage of memory cells in reprogramming of the next write loop is verified.

In this manner, the write loop during rewrite operation is repeated until no verify-failed memory cell is detected.

If, for example, no verify-failed memory cell is detected (or the number of write loops reaches the number of times based on setting information), the signal pcomp-C is set to the high level. Accordingly, the rewrite operation during patrol operation is finished.

Regarding memory cells including errors from the “Er” level to the “A” level, as described above, the bit (digit, page) where an error exists is changed from the upper bit to the lower bit.

Also in the present embodiment, regarding memory cells including errors from the “C” level to the “B” level, errors of data are corrected.

Thus, the number of error bits in the page is leveled and also, errors in the page are corrected by the rewrite operation based on results of the ECC process.

With the above steps, the rewrite operation during patrol operation of the memory system 1 is completed.

Incidentally, if the read data is determined to satisfy reliability of data by a determination process (steps S404, S407) using the first and second determination values P1, P2, the memory system 1 terminates the patrol operation by performing none of the rewrite operation and the copy operation.

In the manner described above, memory cells in which an error occurs in data due to the rise of the threshold voltage in the flash memory 100 and memory cells in which an error occurs in data due to the fall of the threshold voltage are detected using read data during patrol operation of the memory system 1 according to the present embodiment.

The memory system 1 according to the present embodiment performs a program operation for memory cells including an error based on the result of detection thereof.

Accordingly, the memory system according to the present embodiment can level errors due to the rise of the threshold voltage of memory cells between a plurality of pages.

Also, the memory system according to the present embodiment can correct errors due to the fall of the threshold voltage of memory cells. Accordingly, the memory system according to the present embodiment can reduce errors in a page.

### (4a-2) Second Example

A second example of the operation example of the memory system according to the present embodiment will be described with reference to FIGS. 31 to 33.

The memory system 1 according to the present embodiment may also detect memory cells to be reprogrammed in a rewrite operation by a process as shown in FIGS. 31 to 33.

FIGS. 31 to 33 schematically show a data holding state of latch circuits of the flash memory when a determination process for the rewrite operation of the patrol operation of the memory system is performed.

After the upper data U is sent to the controller 200, as shown in FIG. 31, the latch circuit SDL holds a reading result CR of a determination level VCRm and the latch circuit ADL holds the data U. If a rewrite operation is instructed to be performed (step S408) after the ECC process (step S402) by the controller 200, the corrected data X is sent from the controller 200 to the flash memory 100. The corrected data X is stored in the latch circuit XDL (step S409).

The operation section OP performs an AND operation of the corrected data X in the latch circuit XDL and the inverted data bU of the upper data U in the latch circuit ADL.

The result Z(=X&bU) of an AND operation of the corrected data X and the inverted data bU is stored in the latch circuit BDL.

Here, as described using FIG. 28, the result Z of calculation of “1” in an AND operation of the two pieces of data X, bU indicates that the upper data (upper bit) U in the page (memory cell) includes an error. On the other hand, the result Z of calculation of “0” indicates that the upper data U includes no error.

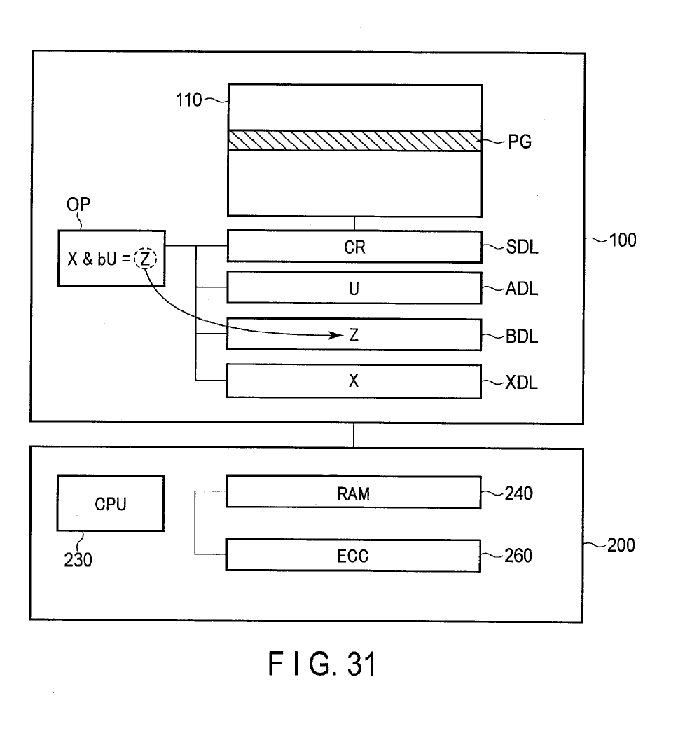

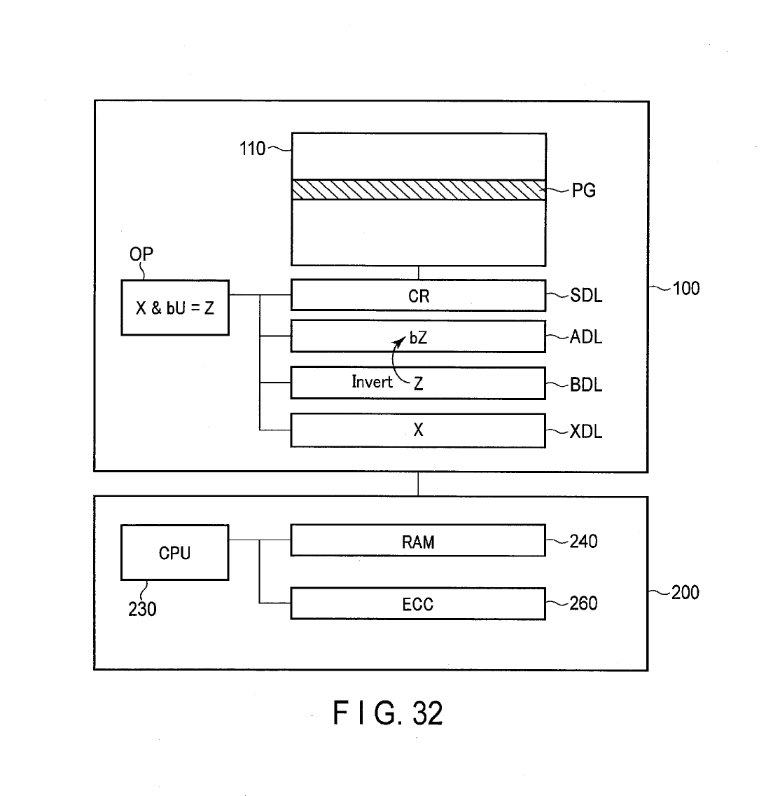

As shown in FIG. 32, inverted data bZ of data Z in the latch circuit BDL is stored in the latch circuit ADL. The latch circuit ADL holds the data bZ.

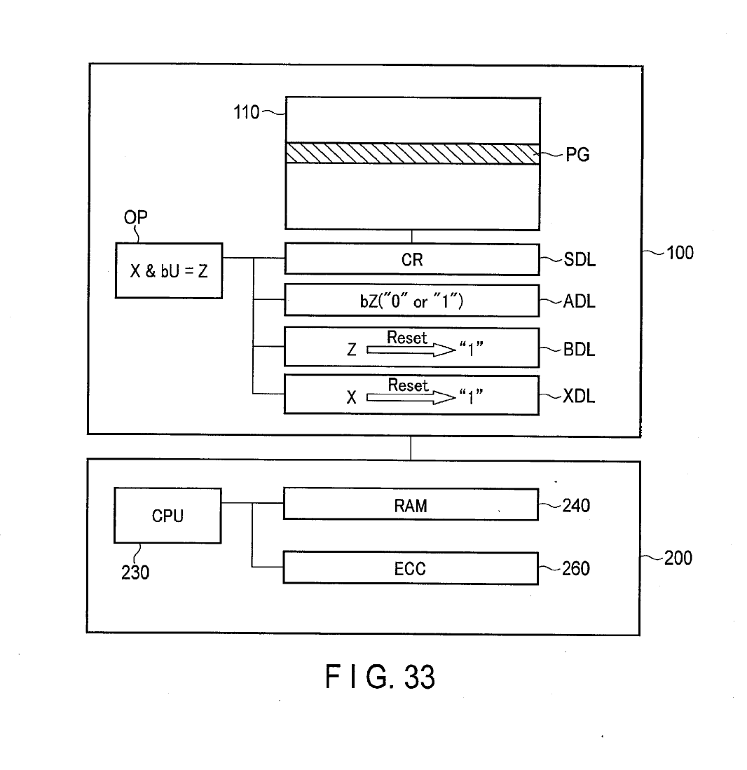

As shown in FIG. 33, after the data bZ is stored in the latch circuit ADL, a reset operation for the latch circuit BDL and the latch circuit XDL is performed. Accordingly, data in the latch circuits BDL, XDL is set to “1”.

The data bZ in the latch circuit ADL is based on an inversion result of an AND operation of the corrected data X and the inverted upper data bU. If the data bZ in the latch circuit ADL is “0”, the memory cell corresponding to the latch circuit ADL is an error cell.

Because a reset operation has been performed for the latch circuit BDL, the data inside the latch circuit BDL is “1”. Similarly, the data inside the latch circuit XDL is “1” due to a reset operation for the latch circuit XDL.

When the latch circuit BDL holds “1” data and the latch circuit ADL holds “0” data, a selective program operation for an error cell is performed for the memory cell corresponding to the latch circuits ADL, BDL.

Due to “1” data of the latch circuit BDL and “0” data of the latch circuit ADL, the data holding state of the latch circuits ADL, BDL is the same as a holding state of “10” data corresponding to the “C” level during the rewrite operation. Accordingly, the sequencer 170 and the sense amplifier unit SAU determine that the memory cell corresponding to the latch circuits ADL, BDL of “10” data is intended for reprogramming of the “C” level.

When “11” data is held in the latch circuits ADL, BDL of the sense amplifier unit SAU, the data holding state of the latch circuits ADL, BDL is the same as that of memory cells of the “Er” level. Thus, the sequencer 170 and the sense amplifier unit SAU determine that the memory cell corresponding to the latch circuits ADL, BDL of “11” data is programming-inhibited.

In the present example, therefore, the error cell is identified in accordance with the data held in the latch circuits ADL, BDL. While a reset operation is performed for the latch circuit BDL, a reset operation for the latch circuit XDL may not be performed.

Then, the flash memory 100 performs the reprogram operation shown in FIG. 30 for the identified memory cell.

Accordingly, the memory system according to the present embodiment can perform reprogramming for an error cell in accordance with data held inside the latch circuits ADL, BDL of each sense amplifier unit SAU.

In the memory system according to the present embodiment, as described above, even if the process shown in FIGS. 31 to 33 is used, the rewrite operation for the error conversion process and the error correction process can be controlled.

### (4a-3) Third Example

In the first and second examples described above, the patrol operation as a background operation of the memory system is taken as an example to describe an example of performing the conversion/correction process of an error in the flash memory using data read from the flash memory.

However, when data in response to a read request from the host device is read, rewriting for the conversion process of an error bit and the correction process of an error bit may be performed using corrected data.

In the memory system 1 according to the present embodiment, the controller 200 issues a read command based on a request from the host device 300. When data is read from the flash memory 100 based on a request from the host device 300, the flash memory 100 performs the process described using FIGS. 25 to 33.

In the third example, data corrected in step S402 is transferred not only to the flash memory 100 when the rewrite operation is performed, but also to the host device 300.

In the memory system 1 according to the present embodiment, therefore, even if data read in accordance with a request from the host device 300 is used, the rewrite operation for the error conversion process and the error correction process can be controlled.

### (4b) Summary

In a flash memory, the threshold voltage of a memory cell may fall from the value when data is written with the passage of time (for example, about one year from the time when data is written).

An error may be caused in data that should be held by memory cells by the fall of the threshold voltage. As a result, reliability of data stored in a memory system is damaged.

A memory system according to the present embodiment performs a write operation for error cells caused by the rise of the threshold voltage and also performs a write operation for error cells caused by the fall of the threshold voltage based on evaluation results of reliability of data of the flash memory during patrol operation or when data is read based on a request from a host.

Accordingly, the memory system according to the present embodiment can suppress degradation of data of the flash memory caused by aging together with leveling of the number of error bits between pages.

In the memory system including a flash memory, a copy operation of data in units of page or block is performed to maintain reliability of data in the flash memory. The load of the copy operation in units of page or block on memory cells is high and an increase of the bit cost may result.

When, like the present embodiment, reliability of data is maintained by adding charges into the charge storage layer of memory cells where threshold voltage falls, when compared with the copy operation in units of page/block, the load on memory cells can be reduced. Thus, the memory system according to the present embodiment can suppress degradation of memory cells and also suppress an increase of the bit cost.

The patrol operation for the NAND flash memory is an operation in which no host device is interposed.

Therefore, the memory system according to the present embodiment can make processes in the memory system more efficient by performing a leveling process and a correction process of errors in the flash memory while the patrol function is performed.

The memory system according to the present embodiment can, as described above, improve reliability of data.

### (5) Fifth Embodiment

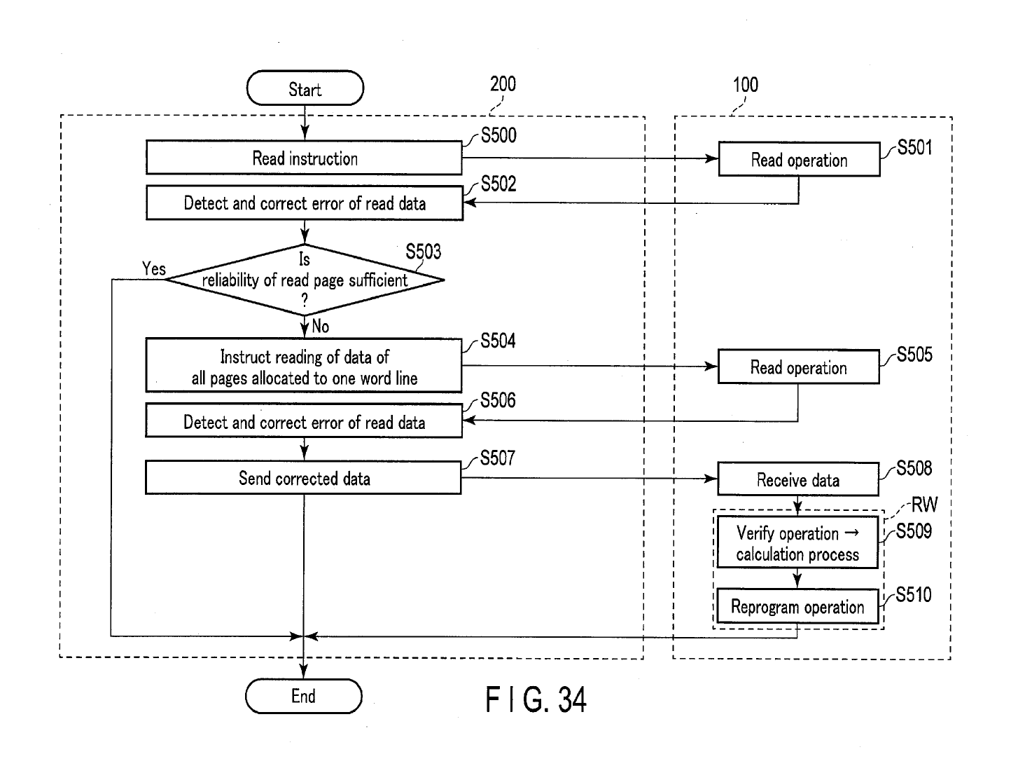

A memory system according to a fifth embodiment and a control method thereof will be described with reference to FIGS. 34 to 53.

The memory system according to the fifth embodiment includes a flash memory of TLC.

In the memory system including a NAND flash memory 100 using TLC, an error conversion process and a rewrite operation may be performed for an error cell during data reading or patrol operation.

Regarding the error conversion process and the rewrite operation during patrol operation of the flash memory using TLC, the basic operation thereof is similar to that of the error conversion process and the rewrite operation during data reading/patrol operation of the flash memory using MLC.

However, the number of bits that can be held per memory cell is different between TLC and MLC and thus, the determination process for the error conversion process and the rewrite operation in the flash memory using TLC is different from the determination process performed by the flash memory using MLC.

As will be described below, a memory system 1 according to the present embodiment converts or corrects an error in data in memory cells by a rewrite operation (injection of charges into the charge storage layer) based on results of the read operation and the ECC process.

### (5a-1) First Example

A first example of the operation example of the memory system according to the fifth embodiment will be described using FIGS. 34 to 47.

FIG. 34 is a flowchart illustrating an operation example of the memory system according to the present embodiment.

As shown in FIG. 34, a controller 200 sends a read command to the NAND flash memory 100 based on, for example, a request from a host device 300 or the patrol function (step S500).

In response to the read command, the flash memory 100 performs a read operation similar to that in the above example (S501). The flash memory 100 sends the read data to the controller 200.

The controller 200 performs an ECC process on data from the flash memory 100 (step S502).

When data is read based on a request from the host device 300, the controller 200 sends the ECC-processed data to the host device 300.

After the ECC process, the controller 200 evaluates reliability of data in a memory cell array 110 based on the read data and the result of the ECC process on the data (step S503). The evaluation of reliability of data may be performed in substantially the same manner as the process (steps S403 to 3408 in FIG. 24) described in the fourth embodiment. Incidentally, a copy operation may be performed based on the evaluation of reliability of data.

If the controller 200 determines that the read data may not satisfy reliability based on specifications/performance of the flash memory, the controller 200 sends read commands and addresses to the flash memory 100 such that data of all pages allocated to the word line corresponding to the selected address ADR is read (step S504).

The flash memory 100 performs a read operation of all pages allocated to the selected word line corresponding to the address (step S505).

When the flash memory 100 of TLC is used for the memory system 1, data of the lower page, the middle page, and the upper page allocated to one word line are read from the flash memory 100 into the controller 200.

The controller 200 performs an ECC process on data of each page to correct the detected error (step S507).

The controller 200 sends corrected data of each page to the flash memory 100 (step S507). In the memory system 1 including the flash memory 100 of TLC, the controller 200 sends corrected data of each of the lower, middle, and upper pages to the flash memory 100. For example, sending of corrected data is performed in a refresh mode of the memory system 1.

For example, the controller 200 sends the commands “ZZh”, “80h”, “00h”, the address ADR, and data (corrected data) based on the command sequence in FIG. 26.

The flash memory 100 receives the corrected data, address, and corrected data (step S508). Th corrected data of each page is stored in the corresponding latch circuits ADL, BDL, CDL.

The flash memory 100 performs a rewrite operation (refresh operation) RW.

In the present embodiment, the rewrite operation of the flash memory 100 of TLC includes a pre-verify operation (and a calculation process) and a reprogram operation.

The flash memory 100 of TLC performs the pre-verify operation before the reprogram operation (step S509).

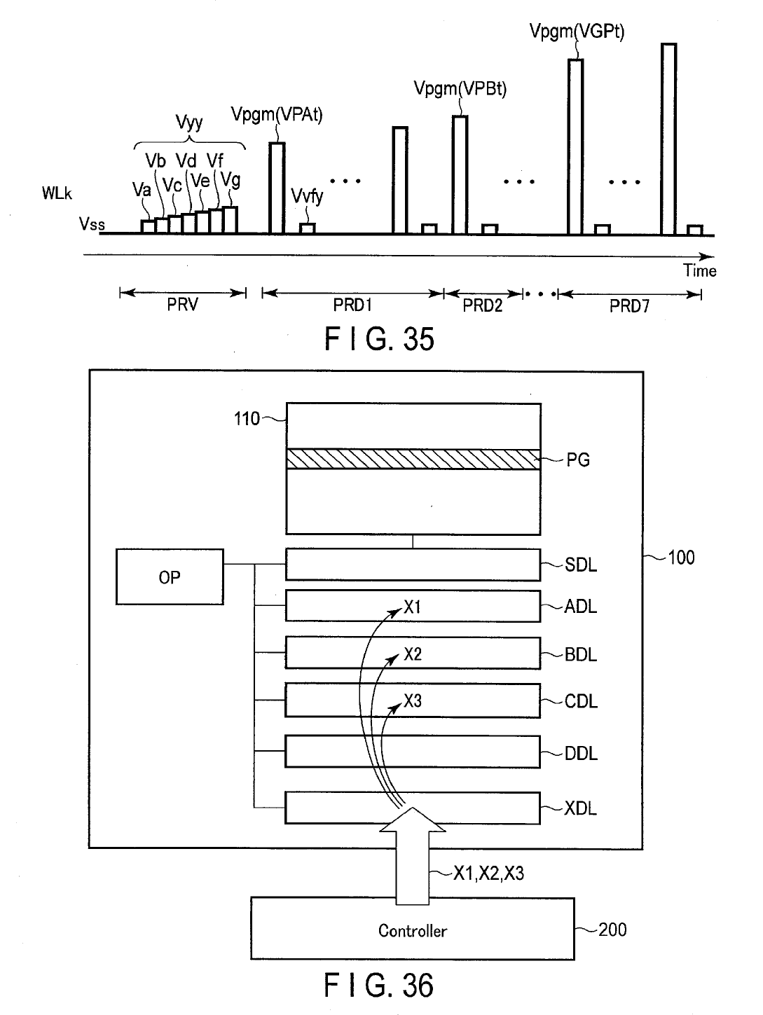

FIG. 35 is a timing chart schematically showing an overall flow of the rewrite operation of the memory system according to the present embodiment. In FIG. 35, the voltage applied to the selected word line WLk of the flash memory is schematically shown. Incidentally, the control of the voltage applied to the word line and bit line in the present example is similar to the control of the voltage applied to the word line and bit line in FIGS. 17 and 19 and thus, an illustration and a description thereof are omitted.

To perform the pre-verify operation in step S509, a voltage VBL is applied to the bit line and a pre-verify voltage Vyy is applied to the selected word line WLk. The pre-verify voltage Vyy includes determination levels (pre-verify levels) Va, Vb, . . . , Vf, Vg corresponding to each level from the “A” level to the “G” level in the flash memory 100 of TLC. The pre-verify level may have the same voltage value as that of the reading level (or the verify level) in TLC or a different voltage value from that of the reading level.

For example, each pre-verify level has a voltage value obtained by adding a predetermined value (dV) to the normal reading level. Each pre-verify level is higher than the corresponding reading level. In this case, each pre-verify level may be the same as the corresponding verify level.

The result of a pre-verify operation is stored in the latch circuit SDL.

The memory cell where charges should be injected into the charge storage layer in a reprogram operation is detected (identified) based on the result of a pre-verify operation and corrected data.

FIGS. 36 to 47 are diagrams schematically showing the flow of a determination process whether a rewrite operation is performed in the memory system according to the present embodiment.

FIG. 36 shows a data holding state of the latch circuits in the initial state of a rewrite operation in the memory system according to the present embodiment.

As shown in FIG. 36, corrected data X1, X2, X3 from the controller 200 is stored in the latch circuits ADL, BDL, CDL in each sense amplifier unit SAU. The corrected data X1 of the lower page (lower bit) is stored in the latch circuit ADL. The corrected data X2 of the middle page (middle bit) is stored in the latch circuit BDL. The corrected data X3 of the upper page (upper bit) is stored in the latch circuit CDL.

On/Off of memory cells by the pre-verify operation is detected. A signal (data) corresponding to On/Off of the memory cell MT is stored in the latch circuit SDL as the result of the pre-verify operation.

As will be described below, based on the corrected data X1, X2, X3 and a result Y of the pre-verify operation at each level, memory cells in which an error of data should be converted and memory cells in which an error of data should be corrected are detected.

<Detection of Memory Cells of the Erase Level in which an Error Occurred>

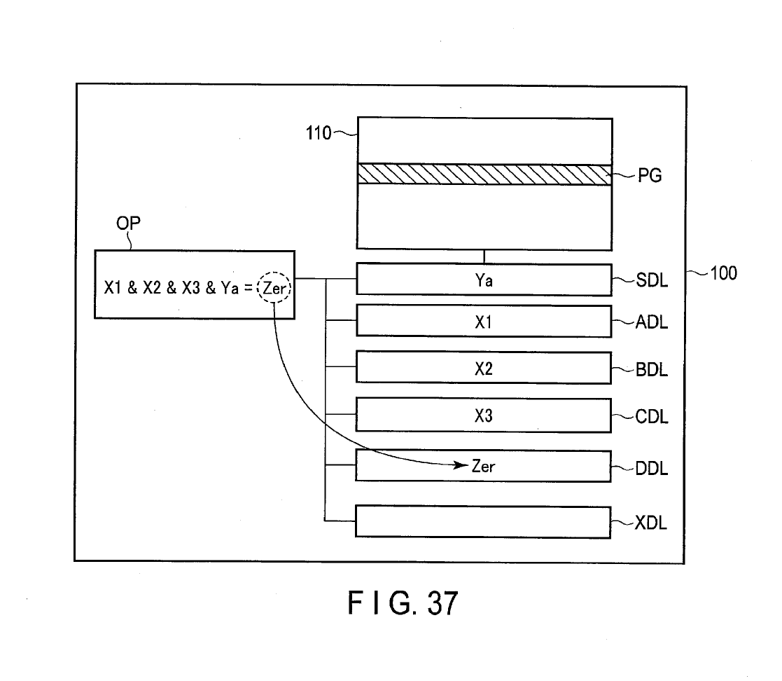

FIG. 37 is a pattern diagram showing a data holding state of the latch circuits when a calculation process of pre-verify results and corrected data is performed in the memory system according to the present embodiment.

In FIG. 37, a sequencer 170 detects memory cells whose threshold voltage changes from the value corresponding to the “Er” level to the value corresponding to the “A” level.

The sequencer 170 applies the pre-verify level Va (for example, Va=VARt) to the selected word line WLk during pre-verify operation to detect whether the memory cell MT connected to the word line WLk is turned off or on.

A result Ya of the pre-verify operation using the pre-verify level Va is stored in the latch circuit SDL.

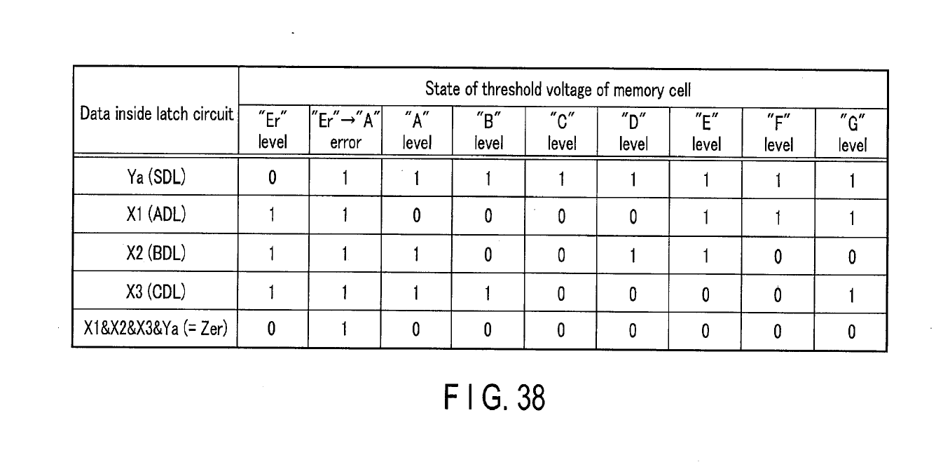

FIG. 38 shows a data holding state of each latch circuit after verification using the pre-verify level Va.

If, as shown in FIG. 38, the memory cell MT that should hold the “Er” level is turned off by the application of the pre-verify level Va, “1” data is held in the latch circuit SDL as the pre-verify result Ya. If the memory cell MT that should hold the “Er” level is turned on by the application of the pre-verify level Va, “0” data is held in the latch circuit SDL as the pre-verify result Ya.

The memory cell turned off by the application of the verify level Va has a threshold voltage higher than the pre-verify level Va. Thus, if a memory cell whose expected value data is the “Er” level is turned off when the pre-verify level Va is applied, the memory cell includes an error.

A memory cell having a threshold voltage higher than the pre-verify level Va like memory cells of the “A” to “G” levels is in an off state when the pre-verify level Va is applied. Thus, the data Ya in the latch circuit SDL corresponding to memory cells of the “A” to “G” levels is “1” data.

The operation section OP performs a calculation process based on the pre-verify result (data in the latch circuit SDL) Ya and the corrected data X1, X2, X3.

The operation section OP performs an AND operation of four data X1, X2, X3, Ya to obtain a calculation result Zer for error detection at the “Er” level. The calculation result Zer of the AND operation (X1&X2&X3&Ya) is stored in a latch circuit DDL.

If the memory cell that should hold the “Er” level is turned on by the application of the pre-verify level Va (the pr-verify result Ya is “0”), the result Zer of the AND operation is “0”.

If the memory cell that should hold the “Er” level is turned off by the application of the pre-verify level Va (the pr-verify result Ya is “1”), the result Zer of the AND operation is “1”.

Thus, the memory cell of the “Er” level in which an error occurred is indicated by the latch circuit DDL holding “1” data.

At least one piece of the data X1, X2, X3, Ya of the four latch circuits ADL, BDL, CDL, SDL includes “0” data regarding memory cells that should hold any one level from the “A” level to the “G” level. Thus, the result Zer of the AND operation (X1&X2&X3&Ya) used to detect an error of the “Er” level regarding memory cells of levels other than the “Er” level becomes “0”.

The operation section OP changes data in the latch circuits ADL, BDL, CDL to data to be converted based on a calculation process of the calculation result (data in the latch circuit DDL) Zer and the corrected data X1, X2, X3 in the latch circuits ABL, BBL, CDL.

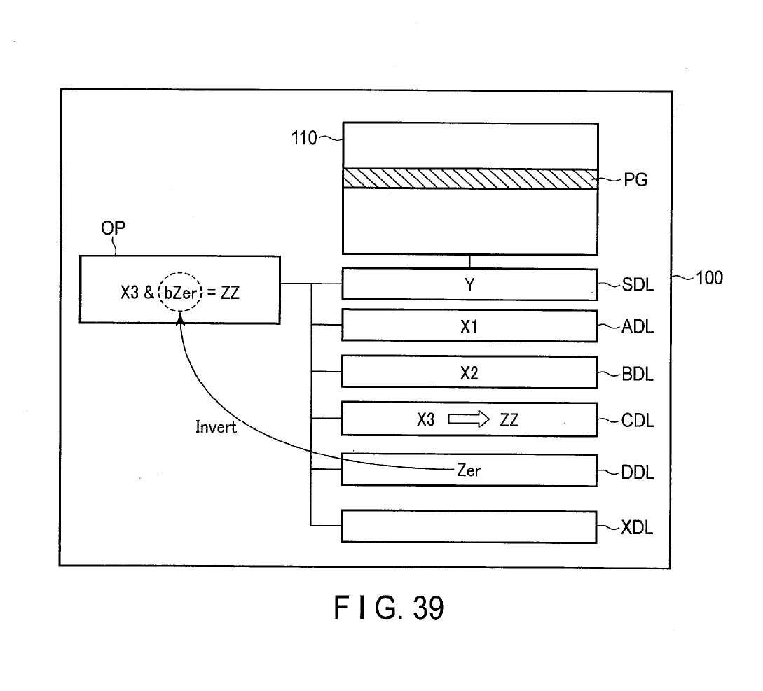

FIG. 39 is a pattern diagram showing a data conversion process of the latch circuit corresponding to the memory cell including an error in the memory system according to the present embodiment.

When data of a memory cell of the “Er” level including an error in data is converted into data of the “E” level (“111” data is converted into “011” data), as shown in FIG. 38 described above, the operation section OP performs an AND operation of the data X3 in the latch circuit CDL and inverted data bZer of the data Zer in the latch circuit DDL. The data X3 in the latch circuit CDL is converted in accordance with the data Zer in the latch circuit DDL.

The operation section OP transfers a calculation result ZZ(=X3&bZer) to the latch circuit CDL.

When the data Zer in the latch circuit DDL is “0” (the inverted data bZer is “1”), the calculation process by the operation section OP is an AND operation of “1” and “1”. In this case, “1” data in the latch circuit CDL is held constant.

When the data Z in the latch circuit DDL is “1” (the inverted data bZ thereof is “0”), the calculation process by the operation section OP is an AND operation of “1” and “0”. In this case, the data X3 in the latch circuit CDL is converted, into “0” data.

“1” data in the latch circuits ADL, BDL is held constant without being subjected to a calculation process.

As a result of the calculation process, 3-bit data formed from data in the three latch circuits ADL, BDL, CDL corresponding to the error cell MT of the “Er” level becomes “011” data.

Thus, when an error occurs in a memory cell that should hold the “Er” level, data including an error of the lower bit is converted into data including an error of the upper bit.

Incidentally, if the data X3 in the latch circuit CDL is “0” and the data Zer in the latch circuit DDL is “0”, a result ZZ of an AND operation of the data X3 and the inverted data bZer (“1”) is “0”. If the data X3 is “1” and the data Zer is “0”, the result ZZ of an AND operation of the data X3 and the inverted data bZer is “1”. Thus, if the data Zer in the latch circuit DDL is “0”, the value of data of the latch circuit CDL does not change even if an AND operation of the data X3 of the latch circuit CDL and the inverted data bZ of the latch circuit DDL is performed. Thus, the data X3 of the latch circuit CDL does not change in the sense amplifier unit SAU in which data of the “A” to “G” levels is held in the latch circuits ADL, BDL, CDL.

As described above, regarding memory cells of the “Er” level including an error of the lower bit, data held by the memory cells may be converted into data of the “G” level (“101” data).

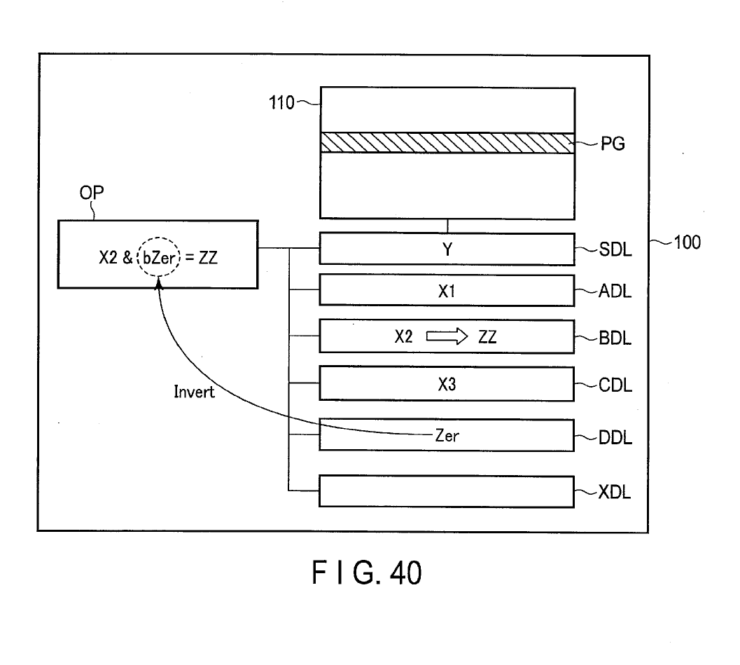

FIG. 40 is a pattern diagram showing an example of the data conversion process of the latch circuit that is different from FIG. 39 in the memory cell including an error in the memory system.

When data of an error cell of the “Er” level is converted into data of the “G” level (“111” data is converted into “101” data), as shown in FIG. 40, the operation section OP performs an AND operation (X2&bZer) of the data X2 in the latch circuit BDL and inverted data bZer of the data Zer in the latch circuit DDL. Accordingly, the value (“0” or “1”) of data in the latch circuit BDL is determined in accordance with the data Zer in the latch circuit DDL.

If the data Zer in the latch circuit DDL is “0” (the inverted data bZer is “1”), data in the latch circuit BDL after an AND operation is held constant in value of the data X2 before the AND operation regardless of whether the data in the latch circuit BDL is “1” data or “0” data.

If the data Zer in the latch circuit DDL is “1” (the inverted data bZer is “0”), “1” data in the latch circuit BDL is converted into “0” data.

Thus, 3-bit data formed from data in the three latch circuits ADL, BDL, CDL corresponding to memory cells of the “Er” level including an error becomes “101” data.

Like the example in FIG. 39, even if the same calculation process as that for the latch circuits ADL, BDL, CDL holding data of the “Er” level is performed for latch circuits holding data of any one of the “A” to “G” levels, the data holding state of the latch circuits ADL, BDL, CDL holding data of the “A” to “G” levels does not change.

Among memory cells of the “Er” level, memory cells in which an error occurred are detected by the operation process of corrected data and pre-verify results as described above. Based on the result of the calculation process, data in the latch circuits is converted such that the digit of an error bit in a memory cell of the “Er” level is converted into another digit.

<Detection of Memory Cells in which an Error Occurred Due to the Fall of the Threshold Voltage>

The memory system according to the present embodiment can reduce errors (fail bits) in a page by performing, in addition to the above error bit conversion process of memory cells of the “Er” level in which an error occurred, writing (additional writing) of expected value data described below for memory cells in which the threshold voltage fell.

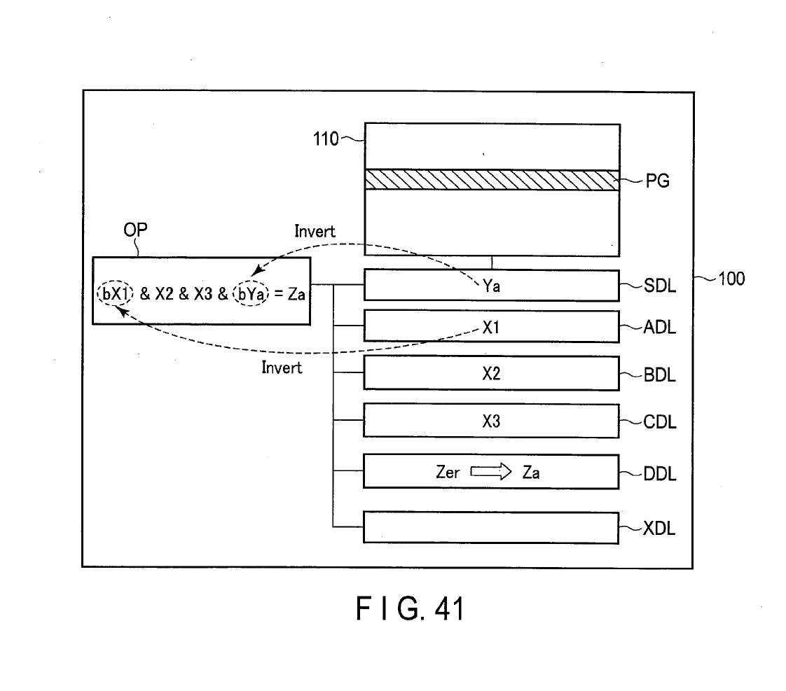

In the flash memory of TLC, as shown in FIGS. 41 to 47, memory cells including an error caused by the fall of the threshold voltage in data are detected by a pre-verify operation.

In a pre-verify operation, pre-verification of each level and an operation process on the result of the pre-verification are successively performed in the order from the “A” level toward the “G” level.

In parallel with the detection of error cells of the “Er” level, error cells of the “A” level are detected. Here, an error of the “A” level is an error caused by the change of the threshold voltage of a memory cell from the value corresponding to the “A” level to the value corresponding to the “Er” level. For example, the threshold voltage of an error cell of the “A” level is equal to the reading level VARt or less.

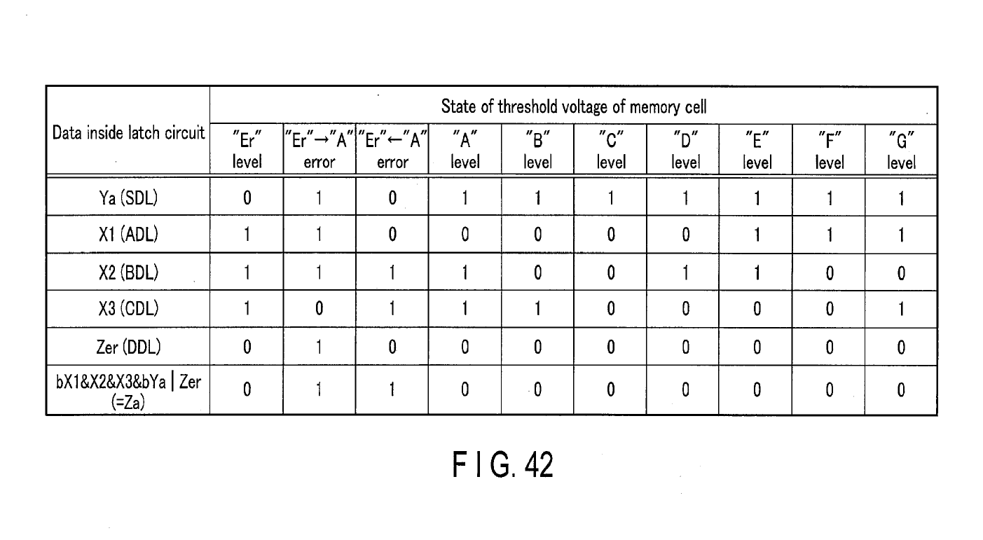

FIGS. 41 and 42 are pattern diagrams illustrating a calculation process to detect, among memory cells whose expected value data is the “A” level (memory cells that should hold the “A” level), memory cells whose threshold voltage has fallen to the “Er” level.

As shown in FIG. 41, the pre-verify level Va is applied to the selected word line WLk to detect, among memory cells that should hold the “A” level, memory cells including an error. The result Ya of pre-verification is stored in the latch circuit SDL. During pre-verification of memory cells of the “A” level, the application of the pre-verify level Va is common (simultaneous) to (with) the application of the pre-verify level Va to detect an error of the “Er” level.

Among memory cells that should hold the “A” level, memory cells in an on state when the pre-verify level Va is applied are memory cells having a threshold voltage equal to the pre-verify level Va or less and memory cells in which an error occurred in data to be held. If no error occurs in data of memory cells of the “A” level, memory cells of the “A” level (memory cells having a threshold voltage higher than the voltage Va) are in an off state when the pre-verify level Va is applied.

The latch circuit SDL holds “1” or “0” data in accordance with the result Ya of pre-verification at the pre-verify level Va. The latch circuit SDL corresponding to a memory cell in an on state holds “0” data and the latch circuit SDL corresponding to a memory cell in an off state holds “1” data.

In a determination process based on pre-verification of the “A” level, the operation section OP performs an AND operation (bX1&X2&X3&bYa) using inverted data bX1 of the data X1 in the latch circuit ADL, the data X2 in the latch circuit BDL, the data X3 in the latch circuit CDL, and inverted data bYa of the result Ya of pre-verification in the latch circuit SDL in each sense amplifier unit SAU. The operation section OP stores a result Za of the AND operation in the latch circuit DDL.

FIG. 42 shows a data holding state of each latch circuit after verification using the pre-verify level Va.

In the memory cell MC that should hold the “A” level (“110” data), as shown in FIG. 42, “0” data is held in the latch circuit ADL as the data X1, “1” data is held in the latch circuit BDL as the data X2, and “1” data is held in the latch circuit CDL as the data X3. The inverted data bX1 of the corrected data X1 held in the latch circuit ADL is “1” data.

Thus, in the memory cell MT that should hold the “A” level, the result of an AND operation of the inverted data bX1 of the latch circuit ADL and the data X2, X3 of the latch circuits BDL, CDL is “1” and thus, the result Za of the AND operation is determined as “0” or “1” in accordance with the result Ya of pre-verification in the latch circuit SDL

If the memory cell MT of the “A” level is turned on at the pre-verify level Va (data of the memory cell MT is in error), the result Ya of pre-verification is indicated by, like memory cells of the “Er” level, “0” data. In this case, the inverted data bYa of the latch circuit SDL is “1” data. Thus, the result of the AND operation (bX1&X2&X3&bYa) of the corrected data and the result of pre-verification of the “A” level is “1”.

If the memory cell MT of the “A” level is turned off at the pre-verify level Va (data of the memory cell MT is normal), the result Ya of pre-verification is indicated by “1” data. In this case, the inverted data bYa of the latch circuit SDL is “0” data and the result of the AND operation (bX1&X2&X3&bYa) of the corrected data and the result of pre-verification is “0”.

An OR operation of the result of the AND operation and the data Zer in the latch circuit DDL is performed. The result Za of the OR operation is stored in the latch circuit DDL. If, like a memory cell of the “Er” level including an error, the data Zer is “1” data and the result of the AND operation (bX1&X2&X3&bYa) is “0” data, the result Za of the OR operation is “1”. If, like a memory cell of the “A” level including an error, the data Zer is “0” data and the result of the AND operation is “1” data, the result Za of the OR operation is “1”. If, like a memory cell of the “A” level without error, the data Zer is “0” data and the result of the AND operation (bX1&X2&X3&bYa) is “1” data, the result Za of the OR operation is “0”.

Thus, if data of a memory cell of the “A” level is in error after the calculation process of pre-verification of the “A” level, the latch circuit DDL holds “1” data. If data of a memory cell of the “A” level is normal, the latch circuit DDL holds “0” data.

Incidentally, memory cells of the level higher than the “A” level are turned off when the pre-verify level Va of the “A” level is applied. Thus, when the pre-verify level Va is applied, “1” data is stored in the latch circuit SDL corresponding to memory cells from the “B” level to the “G” level as the result Ya of pre-verification. Regarding memory cells from the “B” level to the “G” level, the inverted data bYa of the result Ya of pre-verification of the “A” level is “0” and thus, the result of the AND operation (bX1&X2&X3&bYa) based on data when the “A” level is determined is “0”. Therefore, “0” data is stored in the respective latch circuits DDL corresponding to memory cells of any level other than the “A” level as the result Za of the operation process corresponding to the pre-verification of the “A” level.

Consequently, regarding memory cells having a threshold voltage higher than a certain pre-verify level, the result Ya of pre-verification held in the latch circuit SDL is “1”. If the data held in the latch circuit SDL is “1”, the calculation result of an AND operation by the operation section OP based on the result Ya of pre-verification is “0” data without depending on the values of corrected data in the latch circuits ADL, BDL, CDL.

Also, the inverted data bX1 of the data X1 is “0” in latch circuits corresponding to memory cells of the “Er” level. Therefore, the result of the AND operation (bX1&X2&X3&bYa) is “0” for data of the latch circuits corresponding to memory cells of the “Er” level (memory cells of the “Er” level after error detection). The data of the latch circuit DDL is “0”. Further, after an error of the “Er” level is detected, data of the latch circuit BDL or the latch circuit CDL is converted into data intended for error conversion. Therefore, even if data of the latch circuit DDL changes after error detection of the “Er” level, an error conversion process from the “Er” level to other levels can be performed.

Subsequent to the pre-verification of the “A” level, pre-verification of the “B” level is performed. Memory cells that should hold the “B” level are set as targets for error detection.

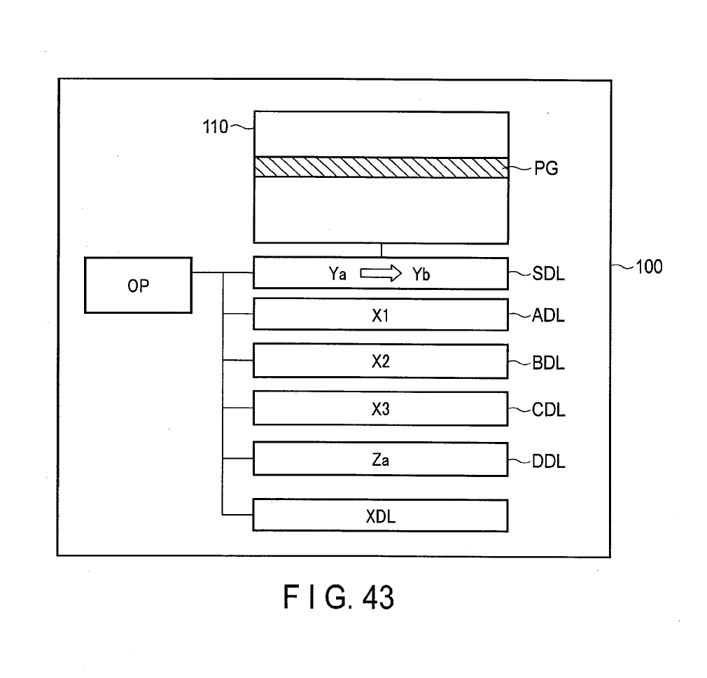

FIGS. 43 to 45 are pattern diagrams illustrating a calculation process to detect, among memory cells whose expected value data is the “B” level (memory cells that should hold the “B” level), memory cells whose threshold voltage has fallen to the “A” level or less.

The pre-verify level Vb of the “B” level is applied to the selected word line WLk.

Among memory cells that should hold the “B” level, memory cells MT that are turned on at the pre-verify level Vb are detected by applying the pre-verify level Vb.

As shown in FIG. 43, a result Yb of pre-verification concerning the “B” level is stored in the latch circuit SDL. The data in the latch circuit SDL changes from the data Ya to the data Yb.

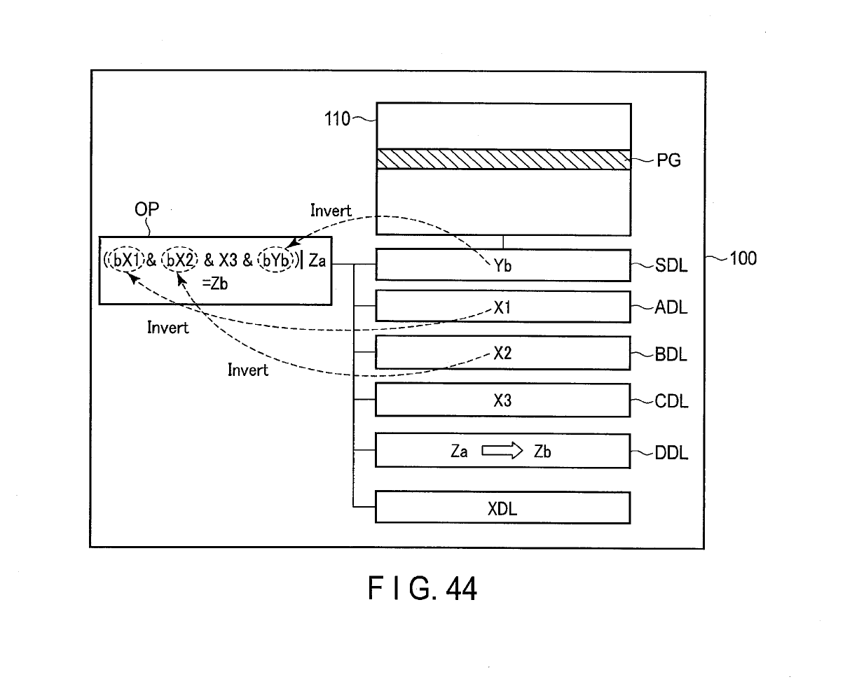

As shown in FIG. 44, the latch circuit SDL holds “1” or “0” data in accordance with the result Yb of pre-verification at the pre-verify level Vb.

In each sense amplifier unit SAU, the operation section OP generates inverted data bX1, bX2 of the data X1, X2 of the latch circuits ADL, BDL.

The operation section OP performs an AND operation of the inverted data bX1 of the latch circuit ADL, the inverted data bX2 of the latch circuit BDL, the data X3 of the latch circuit CDL, and inverted data bYb of the latch circuit SDL. The operation section OP performs an OR operation of the result of the AND operation and the data Za in the latch circuit DDL. Then, the data in the latch circuit DDL is converted into the result of the OR operation.

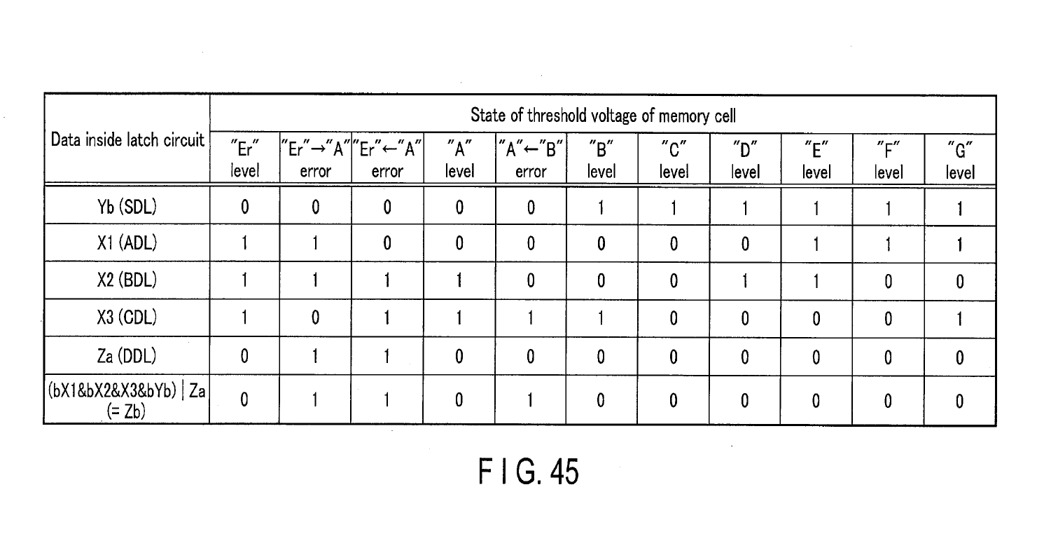

FIG. 45 shows a data holding state of each latch circuit after verification using the pre-verify level Vb.

In FIG. 45, as described above (see FIGS. 37 to 40), an example in which regarding error cells of the “Er” level, the data X1, X2, X3 in the latch circuits is converted into data of the “E” level is shown. However, the data X1, X2, X3 in the latch circuits of error cells of the “Er” level may be converted into data of the “G” level.

In the memory cell MT that should hold the “B” level, as shown in FIG. 45, “0” data is held in the latch circuit ADL, “0” data is held in the latch circuit BDL, and “1” data is held in the latch circuit CDL. In the latch circuits ADL, BDL corresponding to memory cells of the “B” level, the inverted data bX1 of the latch circuit ADL is “1” data and the inverted data bX2 of the latch circuit BDL is “1”.

Thus, in the latch circuits ADL, BDL, CDL corresponding to memory cells of the “B” level, the result of an AND operation based on corrected data is “1” and thus, the result of the AND operation is determined to be “0” or “1” in accordance with the result Yb of pre-verification in the latch circuit SDL.

If memory cells that should hold the “B” level are turned on (an error caused by the fall of the threshold voltage occurs in data) when the pre-verify level Vb is applied, the result Yb of pre-verification in the latch circuit SDL is “0” data.

In this case, the inverted data bYb obtained from the latch circuit SDL is “1” data and the result of the AND operation (bX1&bX2&X3&bYb) is “1”.

If memory cells that should hold the “B” level are turned off when the pre-verify level Vb is applied, the result Yb of pre-verification is “1” data. In this case, the inverted data bYb obtained from the latch circuit SDL is “0” data and the result of the AND operation (bX1&bX2&X3&bYb) is “0”.

The latch circuit DDL holds the result Za of calculation during pre-verification of the previous level (here, the “A” level). An OR operation of the result of the AND operation concerning the “B” level is performed with the data Za in the latch circuit DDL.

Each memory cell of the “B” level to the “G” level is turned off during pre-verification of the “A” level. Thus, as described above, “0” data is held in the latch circuit DDL corresponding to memory cells of the “B” level during pre-verification of the “B” level.

If the result of an AND operation at the “B” level is “0” and the data Za in the latch circuit DDL is “0”, a result Zb of an OR operation is “0” If at least one of the result of an AND operation and the data Za in the latch circuit DDL is “1”, the result Zb of an OR operation is “1”.

The operation section OP stores the result Zb of calculation of the OR operation in the latch circuit DDL as the final result of pre-verification of the “B” level.

The result of a calculation process corresponding to levels other than the level intended for error detection is as described below.

If the value of each bit of corrected data corresponding to levels (the “Er” level, the “A” level, and the “C” to “G” levels) other than the level intended for error detection is inverted/non-inverted in the same digits as those of each bit of data at the level intended for error detection (here, the “B” level), at least one bit of three corrected data controlled to be inverted/non-inverted includes “0” data at levels excluding the level intended for error detection. Thus, at levels excluding the level intended for error detection, the result of an AND operation using corrected data is “0”. Also, data of the latch circuit SDL corresponding to the memory cells MT in an off state when the pre-verify level is applied is “1” data. Data of the latch circuit SDL corresponding to the memory cells MT in an on state when the pre-verify level is applied is “0” data.

If the data Za of the latch circuit DDL is “1”, the result Zb (bX1&bX2&X3&bYb|Za) of a calculation process corresponding to levels other than the level intended for error detection is “1”. If the data Za of the latch circuit DDL is “0”, the result Zb of the calculation process corresponding to levels other than the level intended for error detection is “0”.

If data of a memory cell of the “B” level is in error (the threshold voltage of the memory cell has fallen from the “B” level to the “A” level or less) after the calculation process of pre-verification of the “B” level, the latch circuit DDL holds “1” data. If data of a memory cell of the “B” level is normal, the latch circuit DDL holds “0” data.

After the pre-verification of the “B” level, pre-verification of the “C” level is performed. Memory cells that should hold the “C” level becomes targets for error detection.

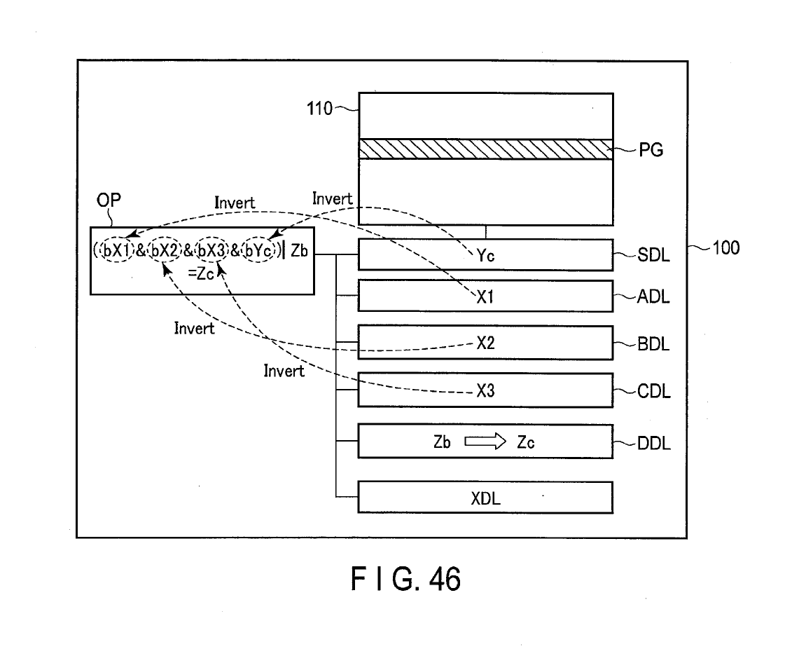

FIG. 46 is a pattern diagram illustrating a process to detect, among memory cells whose expected value data is the “C” level (memory cells that should hold the “C” level), memory cells whose threshold voltage has fallen to the “B” level or less.

Among memory cells that should hold the “C” level, memory cells in an on state are detected by the application of the pre-verify level Vc. A result Yc of pre-verification concerning the “C” level is stored in the latch circuit SDL.

The latch circuit SDL holds “1” or “0” data in accordance with the result Yc of pre-verification at the pre-verify level Vc.

The operation section OP performs an AND operation using inverted data bX1, bX2, bX3 of the data X1, X2, X3 in the latch circuits ADL, BDL, CDL and inverted data bYc of the result Yc of pre-verification in the latch circuit SDL. Further, the operation section OP performs an OR operation of a result of the AND operation and the data Zb in the latch circuit DDL. Then, the operation section OP converts data in the latch circuit DDL into a result Zc of the OR operation.

In the memory cell MT that should hold the “C” level, as shown in FIG. 45 described above, “0” data is held in the latch circuit ADL, “0” data is held in the latch circuit BDL, and “0” data is held in the latch circuit CDL. Thus, regarding memory cells of the “C” level, the inverted data bX1, bX2, bX3 of the latch circuits ADL, BDL, CDL is “1” data and thus, the result of an AND operation of the inverted data bX1, bX2, bX3 is “1”.

Therefore, like the error detection process of the “A” level and the “B” level, the result of an AND operation concerning memory cells of the “C” level is determined to be “0” or “1” in accordance with the result Yc (bYc) of pre-verification in the latch circuit SDL.

If the memory cell MT that should hold the “C” level is turned on when the pre-verify level Vc is applied, the latch circuit SDL corresponding to the memory cell MT holds “0” data as the result Yc of pre-verification of the “C” level. In this case, the inverted data bYc of the latch circuit SDL is “1” data and thus, the result of the AND operation (bX1&bX2&bX3&bYc) of the data bX1, bX2, bX3, bYc is “1”.

If the memory cell MT that should hold the “C” level is turned off at the pre-verify level Vc (there is no error in data), the latch circuit SDL holds “1” data as the result Yc of pre-verification. In this case, the inverted data bYc of the latch circuit SDL is “0” data and thus, the result of the AND operation (bX1&bX2&bX3&bYc) is “0”.

The operation section OP performs an OR operation of the result of the AND operation (bX1&bX2&bX3&bYc) and the data (calculation result during pre-verification of the “B” level) Zb in the latch circuit DDL. The operation section OP writes the result of calculation of the OR operation into the latch circuit DDL as the result Zc of pre-verification of the “C” level.

If data of a memory cell of the “C” level is in error (the threshold voltage of the memory cell has fallen from the “C” level to the “B” level or less) after the calculation process of pre-verification of the “C” level, the latch circuit DDL holds “1” data. If data of a memory cell of the “C” level is normal, the latch circuit DDL holds “0” data.

The result of an AND operation of the inverted data bX1, bX2, bX3 of corrected data of the latch circuits ADL, BDL, CDL and the inverted data bYc of the pre-verification result of the latch circuit SDL is “0” regarding levels other than the “C” level (the “A” level, the “B” level, and the “D” to “G” levels) during pre-verification of the “C” level for the same reason as that for the calculation process for error detection of the “B” level. Thus, if the latch circuit DDL holds “1” data as the result of an OR operation of the result of the AND operation and the data Zb of the latch circuit DDL, the result of the OR operation is “1”. On the other hand, if the latch circuit DDL holds “0” data, the result of the OR operation is “0”. Thus, data of the latch circuit DDL corresponding to memory cells of levels other than the “C” level does not change during pre-verification of the “C” level.

In the pre-verification of the “C” level, therefore, memory cells of the “C” level including an error in data are detected by a process similar to that used for pre-verification of the “B” level.

Regarding pre-verification of the “D”, “E”, “F”, and “G” levels, memory cells to be rewritten at each level (memory cells in which charges should be injected into the charge storage layer) are also detected by a process similar to the process in pre-verification of the “B” and “C” levels.

The operation section OP controls inversion and non-inversion of data of the latch circuits ADL, BDL, CDL. Regarding each of memory cells that should hold data of the “D”, “E”, “F”, or “G” level, the operation section OP inverts “0” data of data corresponding to the level intended for pre-verification to the “1” data.

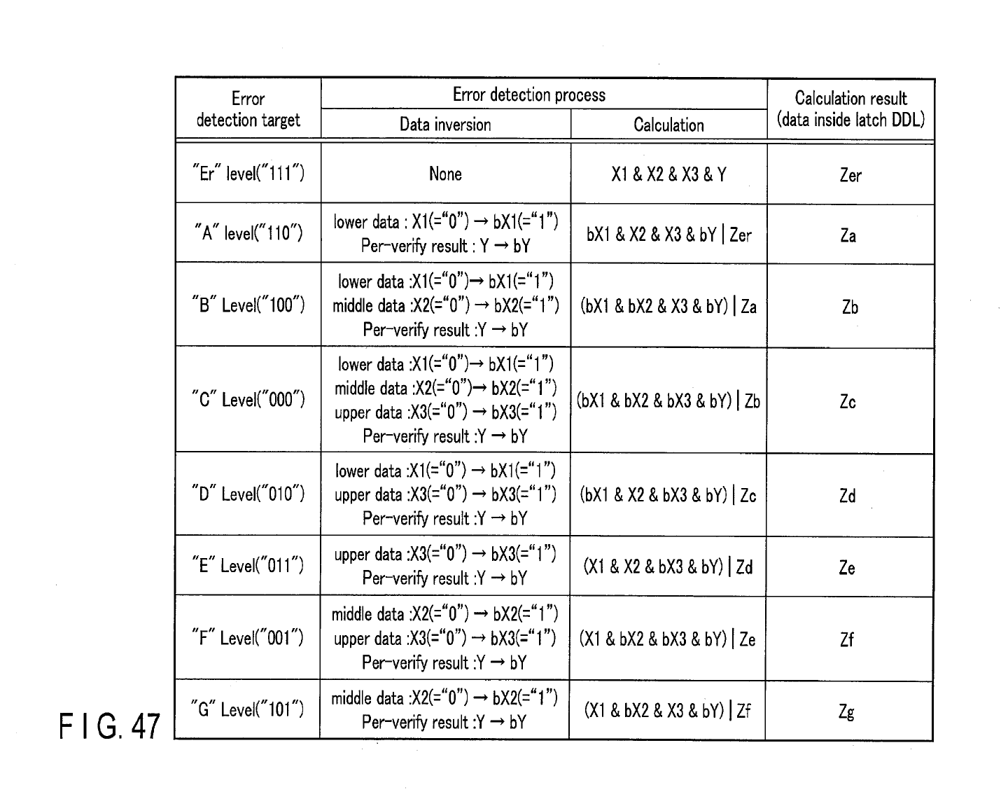

FIG. 47 is a diagram illustrating a detection process of memory cells including an error based on the result of pre-verification of each level.

As shown in FIG. 47, the inverted data bX1, bX3 of the data X1, X3 in the latch circuits ADL, CDL and the inverted data bY(bYd) of the result Y of pre-verification of the “D” level in the latch circuit SDL are used for an AND operation during pre-verification of the “D” level. Also, the result Zc of pre-verification of the “C” level in the latch circuit DDL is used for an OR operation at the “D” level.

The inverted data bX3 of the data X3 in the latch circuit CDL and inverted data bY(bYe) of the result Y of pre-verification of the “E” level in the latch circuit SDL are used for an AND operation during pre-verification of the “E” level. Also, a result Zd of calculation of pre-verification of the “D” level in the latch circuit DDL is used for an OR operation at the “E” level.

The inverted data bX2, bX3 of the data X2, X3 in the latch circuits BDL, CDL and inverted data bY(bYf) of the result Y of pre-verification of the “F” level in the latch circuit SDL are used for an AND operation during pre-verification of the “F” level. A result Ze of calculation of pre-verification of the “E” level in the latch circuit DDL is used for an OR operation at the “F” level.

The inverted data bX2 of the data X2 in the latch circuit BDL and inverted data bY(bYg) of the result Y of verification of the “G” level in the latch circuit SDL are used for an AND operation during pre-verification of the “G” level. A result Zf of calculation of pre-verification of the “F” level is used for an OR operation at the “G” level.

Thus, inversion/non-inversion of data of the latch circuits ADL, BDL, CDL is controlled such that each bit of 3-bit data of the latch circuits ADL, BDL, CDL corresponding to memory cells of the level intended for pre-verification becomes “1”. The data Z of the latch circuit DDL indicating the determination result of the previous pre-verification is used for a calculation process for memory cells of the level to be pre-verified.

When the error detection process of the “Er” level described using FIGS. 37 to 40 is performed, data in the latch circuit BDL or the latch circuit CDL of memory cells of the “Er” level including an error is converted into data intended for error bit conversion (for example, from “111” to “011” or from “111” to “101”). Thus, the calculation process based on the result of pre-verification of the “E” or “G” level is performed for memory cells of the “Er” level in which an error was detected as detection targets of an error of the “E” or “G” level. Even if the threshold voltage rises, memory cells of the “Er” level are turned on at the pre-verify level Ve, Vg of the “E” or “G” level. Thus, memory cells of the “Er” level in which an error was detected are determined to be in error also concerning the “E” or “G” level.

Incidentally, even if the calculation process of each level is successively performed as described above, calculation results of pre-verification of levels lower than the level to be pre-verified are held constant in value before the calculation process.

In the latch circuit DDL, final data (rewrite information) Z indicating memory cells to be reprogrammed in the page is determined by the above calculation process.

Thus, the memory system according to the present embodiment can detect the memory cells MT intended for a reprogram operation while corrected data is held in the latch circuits ADL, BDL, CDL of the flash memory 100.

<Reprogram and Verify Operations>

The memory system according to the present embodiment selectively performs programming (injection of charges) of data for memory cells including an error in data based on the calculation result obtained by pre-verification of each level for the conversion process of an error and the correction process of an error.

In the present embodiment, the error conversion process for memory cells of the “Er” level including an error caused by the rise of the threshold voltage is performed substantially simultaneously with the reprogram operation for memory cells including an error caused by the fall of the threshold voltage of the level (for example, the “E” level) intended for error conversion.

Incidentally, the control of the potential of the word line and the potential of the bit line in the reprogram operation (programming) is substantially the same as that of the example described using FIGS. 16 to 19.

The flash memory 100 performs a reprogram operation and a verify operation for memory cells for which the result of a pre-verify operation is a failure.

The operation section OP inverts data Z (Zer, Za, Zf, Zg) in each latch circuit DDL. Accordingly, the latch circuit DDL holds the data bZ. If the data bZ in the latch circuit DDL is “0”, a reprogram operation of each level in accordance with data of the latch circuits ADL, BDL, CDL is performed for the memory cells MT corresponding to the latch circuit DDL holding “0” data.

During reprogram operation, a sense amplifier circuit 140 controls the potential of the bit line BL in accordance with the data bZ in the latch circuit DDL. When the latch circuit DDL holds “0” data, 0 V is applied to the bit line BL. When the latch circuit DDL holds “1” data, the voltage VDD is applied to the bit line BL.

As shown in FIG. 35 described above, a program voltage Vpgm is applied to the selected word line WLk. Accordingly, charges are injected into the charge storage layer in the memory cells MT corresponding to the latch circuit DDL holding “0” data. On the other hand, charges are not injected into the charge storage layer in the memory cells corresponding to the latch circuit DDL holding “1” data.

After the application of the program voltage Vpgm, a verify operation (program verification) is performed. Regarding the program verification, whether reprogramming is correct is determined by a process similar to pre-verification (see FIG. 47).

A verify voltage Vvfy including the verify level VAVt of the “A” level is applied to the selected word line WLk to perform verification concerning the “A” level.

The result Ya of verification of the “A” level is stored in the latch circuit SDL.

If the memory cell MT is turned on by applying the verify level VAVt of the “A” level (the verification fails concerning programming of the “A” level), “0” is stored in the latch circuit SDL corresponding to the memory cell MT in an on state as the result Ya of verification of the “A” level. If the memory cell MT is turned off by applying the verify level VAVt of the “A” level (the verification passes concerning programming of the “A” level), “1” is stored in the latch circuit SDL corresponding to the memory cell MT in an off state as the result Ya of verification of the “A” level.

Regarding, among memory cells MT that should hold data of the “A” level, memory cells MT in an off state, as described below, data of the latch circuit DDL corresponding to the memory cells MT in an off state is set to “1” based on the result of verification in the latch circuit SDL when the verify level VAVt of the “A” level is applied.

The operation section OP performs an AND operation process of the inverted data bX1 of the data of the latch circuit ADL, the data X2 of the latch circuit BDL, the data X3 of the latch circuit CDL, and data Ya of the latch circuit SDL when programming of the “A” level is verified. The operation section OP performs an OR operation of the result of the AND operation and the data bZ of the latch circuit DDL. The operation section OP stores the result of the OR operation in the latch circuit DDL.

Here, data of the latch circuit DDL during reprogramming is inverted data of data of the latch circuit DDL before reprogramming (during error detection operation). If, in consideration of the above, FIG. 42 described above and similar to program verification during reprogramming is referred to, the latch circuit DDL holds “0” as the data bZ for memory cells to be reprogrammed and holds “1” as the data bZ for memory cells other than memory cells to be reprogrammed.

If, regarding the memory cell MT of the “A” level, data of the latch circuit SDL is “0” (the verification of the memory cell of the “A” level fails), the result of an AND operation is “0”.

If the result of an AND operation is “0” and the data bZ of the latch circuit DDL is “0”, the result of an OR operation is “0”. “0” as the result of the OR operation is stored in the latch circuit DDL.

Thus, in the memory cell of the “A” level failed to be verified, “0” data of the latch circuit DDL is held constant. Thus, the verify-failed memory cell MT of the “A” level continues to be set as a programming target.

If, regarding the memory cell of the “A” level, the data Ya of the latch circuit SDL is “1” (the verification of the memory cell of the “A” level passes), the result of the AND operation (bX1&X2&X3&Ya) is “1”.

If the result of an AND operation is “1” and the data bZ of the latch circuit DDL is “0”, the result of an OR operation (bX1&X2&X3&Ya|bZ) is “1”. “1” as the result of the OR operation is stored in the latch circuit DDL.

Thus, in the memory cell of the “A” level whose verification passed, data of the latch circuit DDL is changed from “0” to “1”. Thus, among memory cells of the “A” level to be rewritten, memory cells of the “A” level whose verification passed are set to a programming inhibited state in the next program operation (next write loop).

If data of the latch circuit DDL in a memory cell of the “A” level is “1” (a memory cell is not an error cell), the memory cell is not intended for programming. In this case, the calculation result (bX1&X2&X3&Ya|bZ) using “1” data of the latch circuit DDL is “1” regardless of the result of verification and the result of an AND operation. Thus, memory cells of the “A” level including no error is set to a programming inhibited state.

Regarding each memory cell from the “B” level to the “F” level, the result of an AND operation of data in the latch circuits is, like during pre-verification of the “A” level described above, “0” when programming of the “A” level is verified. Thus, the result of an OR operation of “0” and the data bZ in the latch circuit DDL depends on the value of the data bZ in the latch circuit DDL. Therefore, data in the latch circuit DDL in memory cells from the “B” level to the “F” level does not change.

After the program voltage Vpgm is applied to the selected word line WLk and the program verification of the “A” level, the program verification concerning the “B” level is performed.

Here, referring to FIG. 45 described above and similar to the program verification during reprogramming, in the program verification concerning the “B” level, “1” data is stored in the latch circuit SDL concerning, among memory cells that should hold data of the “B” level, the memory cells MT in an off state (verify passed) and “0” data is stored in the latch circuit SDL concerning memory cells in an on state (verify failed).

When programming of the “B” level is verified, like during pre-verification of the “B” level, inversion/non-inversion of data of the latch circuits ADL, BDL, CDL is controlled such that an AND operation of 3-bit corrected data of the “B” level to be verified is “1”.

The operation section OP performs an AND operation of the inverted data bX1 of the data of the latch circuit ADL, the inverted data bX2 of the data of the latch circuit BDL, the data X3 of the latch circuit CDL, and the data Yb of the latch circuit SDL. The operation section OP performs an OR operation (bX1&bX2&X3&Yb|bZ) of the result of the AND operation and the data bZ of the latch circuit DDL. The operation section OP stores the result of the OR operation in the latch circuit DDL.

When programming of the “B” level is verified, the result of an AND operation is “1” if the memory cell of the “B” level is a verify-passed memory cell. On the other hand, if the memory cell of the “B” level is a verify-failed memory cell, the result of an AND operation is “0”.

Here, the latch circuit DDL holds “0” as the data bZ for memory cells to be reprogrammed. The latch circuit DDL holds “1” as the data bZ for memory cells not to be reprogrammed (programming inhibited memory cells).

If the result of a 4-bit AND operation (bX1&bX2&X3&Yb) is “1” and the data bZ of the latch circuit DDL is “0”, the result of an OR operation is “1”. In this case, memory cells corresponding to the latch circuit holding “1” data are set to be programming-inhibited.

If the result of an AND operation (bX1&bX2&X3&Yb) is “0” and the data bZ of the latch circuit DDL is “0”, the result of an OR operation is “0”. In this case, memory cells corresponding to the latch circuit holding “0” data are set to be for programming.

Incidentally, when programming of the “B” level is verified, regarding memory cells of levels other than the “B” level, at least one piece of data X1, X2, X3, Y is, like during pre-verification of the “B” level, “0” and thus, the result of an AND operation (bX1&bX2&X3&Yb) is “0”. Thus, regardless of whether data of the latch circuit DDL is “0” or “1”, data of the latch circuit DDL does not change.

Also in the program verification from the “C” level to the “G” level, the operation substantially the same as that of the program verification of the “A” and “B” levels is performed.

After reprogramming of the “B” level is completed, reprogramming and program verification at each level from the “C” level to the “G” level are successively performed by an operation similar to that of programming and program verification of the “A” and “B” levels. Inversion/non-inversion of the data X1, X2, X3 in the latch circuits ADL, BDL, CDL during program verification is controlled at each level like during pre-verify operation by a calculation process substantially similar to the process in FIG. 47.

When data of a memory cell of the “Er” level whose threshold voltage has risen to the reading level of the “A” level or more is converted into data of the “E” level, an error conversion process for the memory cell of the “Er” level is performed as described below.

In memory cells of the “Er” level including an error, data of the latch circuits ADL, BDL, CDL is converted into data of the “E” level by the above error detection process (see FIG. 39).

During reprogramming of the “E” level, programming of the “E” level is performed for memory cells of the “Er” level in error detected by the result of a pre-verify operation in substantially the same manner as the program operation described using FIGS. 16 and 17 simultaneously with programming for memory cells of the “E” level whose threshold voltage is equal to the pre-verify level Ve of the “E” level or less.

Data of memory cells of the “Er” level whose threshold voltage changes to the reading level of the “A” level or more may be converted into data of the “G” level (see FIG. 40). In this case, in memory cells of the “Er” level including an error, data of the latch circuits ADL, BDL, CDL is converted into data of the “G” level by the above error detection process.

During reprogramming of the “G” level, programming of the “G” level is performed for memory cells of the “Er” level in error detected by the result of a pre-verify operation in substantially the same manner as the program operation described using FIG. 18 simultaneously with programming for memory cells of the “G” level whose threshold voltage is equal to the pre-verify level Vg or less.

With the above process, the reprogram operation in a memory system according to the present embodiment is completed.

Incidentally, if reliability of read data is satisfied, the patrol operation or reading of data requested from the host is finished without performing a rewrite operation (and a copy operation).

The memory system 1 including a flash memory of TLC in the present embodiment performs, as described above, a process to detect an error of memory cells caused by the rise or fall of the threshold voltage for errors of data in memory cells caused after data is written during patrol operation of the memory system.

Based on the result of error detection of memory cells, the memory system 1 according to the present embodiment performs at least one of the conversion process of error bits and the reprogram process.

Accordingly, the memory system 1 according to the present embodiment can level errors in the flash memory and reduce errors.

The memory system according to the fifth embodiment can, as described above, improve reliability of data.

### (5a-2) Second Example

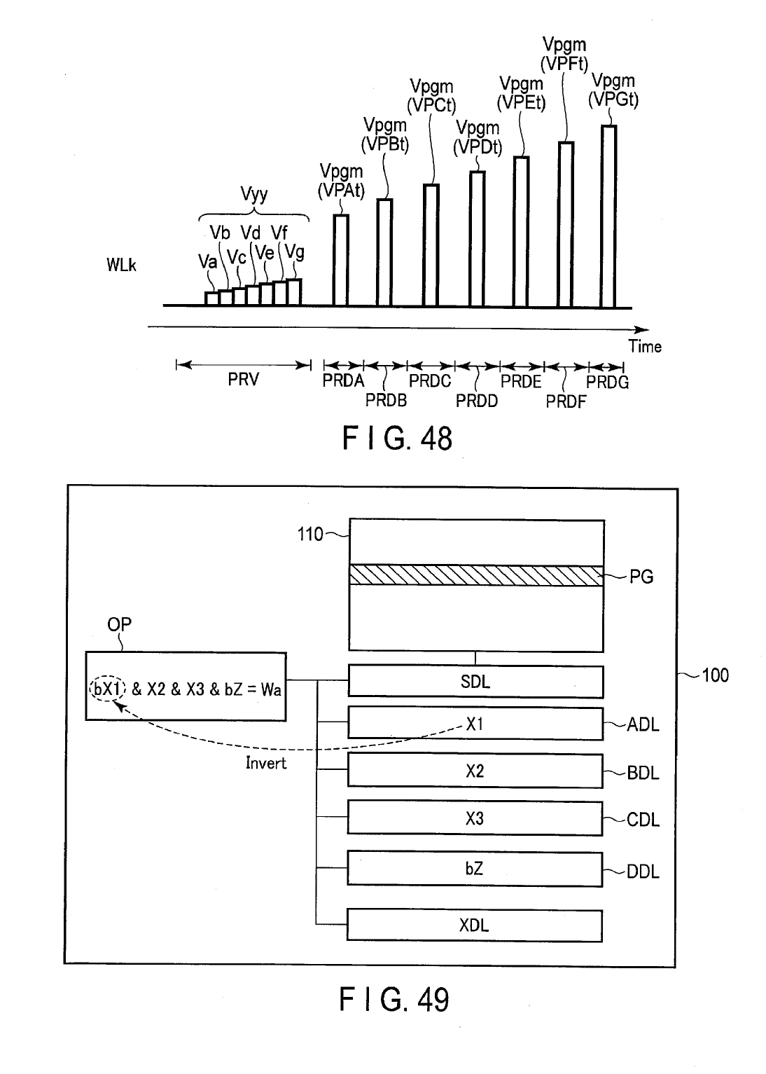

A second example of the operation example of the memory system according to the fifth embodiment will be described with reference to FIGS. 48 to 51.

FIG. 48 is a pattern diagram illustrating the second example of the memory system according to the present embodiment.

As shown in FIG. 48, a verify operation (program verification) may be omitted during reprogram operation.

In this case, the application of program voltage is continuously performed by changing the magnitude of the program voltage for each level corresponding to data without program verification. For example, in periods PRDA, PRDB, PRDC, . . . , PRDF, PRDG of reprogramming of each level, the application of the program voltage Vpgm is performed once. However, a plurality of (for example, two or three) program voltages Vpgm may be applied to one level.

After the above pre-verify operation is performed, the program voltage Vpgm of the voltage values VPAt, VPBt, VPCt, . . . , VPGt corresponding to each level in the order of the “A” level, the “B” level, the “C” level, . . . , the “G” level is successively applied to the selected word line WLk.

In the present example, memory cells for which reprogramming should be performed are identified based on the data X1, X2, X3, Z (bZ) in the latch circuits ADL, BDL, CDL, DDL.

For example, memory cells that should hold data of the “A” level are detected based on data in the latch circuits ADL, BDL, CDL. Based on data in the latch circuit DDL, among memory cells that should hold data of the “A” level, memory cells including an error are detected. If, in the present example, as described above, the latch circuit DDL corresponds to a memory cell including an error, the latch circuit DDL hold data Z of “1” (the data bZ of “0”).

FIG. 49 is a diagram illustrating a detection process of memory cells including an error based on the result of pre-verification of the “A” level. Incidentally, the latch circuits ADL, BDL, CDL corresponding to memory cells of the “A” level have the data holding state shown in FIGS. 42 and 49 describe above.

Like in the first example, the operation section OP controls inversion/non-inversion of the data X1, X2, X3 of the latch circuits ADL, BDL, CDL such that the result of a AND operation of the latch circuits ADL, BDL, CDL holding corrected data of the level to be reprogrammed is “1”. The operation section OP uses the inverted data bZ of the data Z (Za) of the latch circuit DDL for the calculation process to detect memory cells to be reprogrammed.

During reprogramming (period PRDA) of the “A” level, as shown in FIG. 42 described above, the operation section OP performs an AND operation of the inverted data bX1, the data X2, the data X3, and the inverted data bZ to detect (identify) memory cells to be reprogrammed. For example, the operation section OP holds a result Wa of the AND operation (bX1&X2&X3&bZ) in a node of the sense amplifier unit SAD as a potential (high/low level).

Here, regarding memory cells of the “A” level, the data bX1, X2, X3 is “1” and thus, the result of an AND operation is “0” or “1” in accordance with the inverted data bZ of the data Z(Za) of the latch circuit DDL.

When an error occurs in data of the memory cell MT, the data bZ of the latch circuit DDL is “0”. In this case, in memory cells of the “A” level, the result Wa of the AND operation (bX1&X2&X3&bZ) is “1”.

When no error occurs in data of the memory cell MT, the data bZ of the latch circuit DDL is “1”. In this case, in memory cells of the “A” level, the result Wa of the AND operation (bX1&X2&X3&bZ) is “0”.

When memory cells for which reprogramming of the “A” level should be performed are detected, regarding memory cells from the “B” level to the “G” level, data of the latch circuits ADL, BDL, CDL includes at least one “0” and thus, the result of an AND operation of the data bX1, X2, X3 of the latch circuits ADL, BDL, CDL is “0”. Thus, the result Wa of calculation is “0” for each of memory cells from the “B” level to the “G” level.

The potential of the bit line BL is set to a ground potential Vss based on “1” data as a result W of calculation concerning the “A” level and the potential of the bit line BL is set to a potential VDD based on “0” data as the result W of calculation. The program voltage Vpgm having a voltage value VPAt for programming of the “A” level is applied to the selected word line WLk.

Accordingly, charges are injected into the charge storage layer of, among memory cells that should hold the “A” level, memory cells in which data of the latch circuit DDL is “1”. Memory cells from the “B” level to the “G” level are set to a writing inhibited state and thus, charges are hardly injected into the charge storage layer.

Thus, reprogramming of the “A” level is selectively performed for error cells of the “A” level using data of the latch circuits ADL, BDL, CDL, DDL of the “A” level.

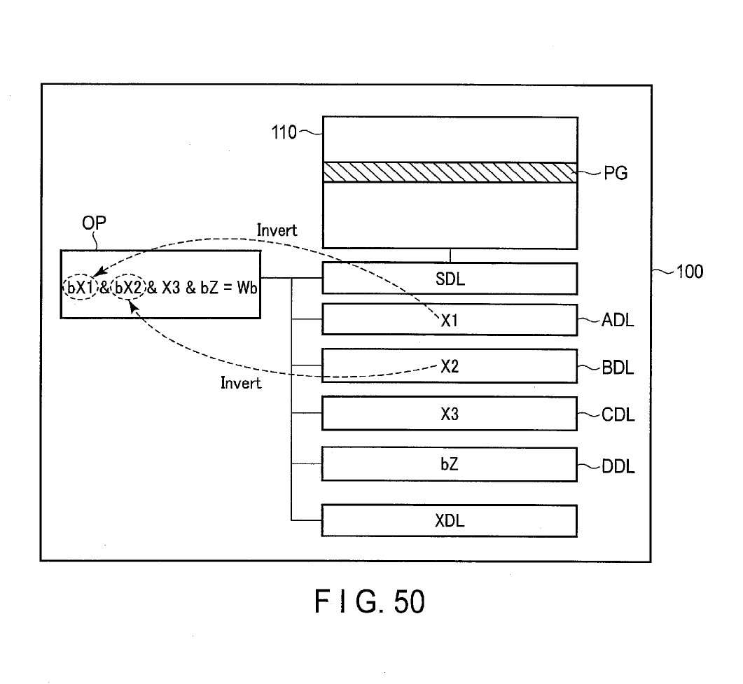

FIG. 50 is a diagram illustrating a detection process of memory cells including an error based on the result of pre-verification of the “B” level. Incidentally, the latch circuits ADL, BDL, CDL corresponding to memory cells of the “B” level have the data holding state shown in FIGS. 45 and 49.

As shown in FIG. 50, when memory cells of the “B” level including an error are detected, the inverted data bX1 of the latch circuit ADL, the inverted data bX2 of the latch circuit BDL, the data X3 of the latch circuit CDL, and the inverted data bZ (bZb) of the latch circuit DDL are used for the AND operation (bX1&bX2&X3&bZ). Accordingly, a result Wb of calculation is “0” or “1” in accordance with the data bZ indicating the result of pre-verification.

Also for the latch circuits ADL, BDL, CDL, DDL corresponding to memory cells of levels other than the “B” level, the same calculation process (bX1&bX2&X3&bZ) as that for the latch circuit ADL, BDL, CDL, DDL corresponding to memory cells of the “B” level is performed. However, at least one piece of the data bX1, bX2, X3, bZ is “0” in memory cells of levels other than the “B” level and thus, the result Wb of calculation is “0”.

Then, error cells are identified based on “1” data of the latch circuit DDL and in the period PRDB, the program voltage having the voltage value VPBt for programming of the “B” level is applied to the selected word line WLk so that the threshold voltage of an error cell rises.

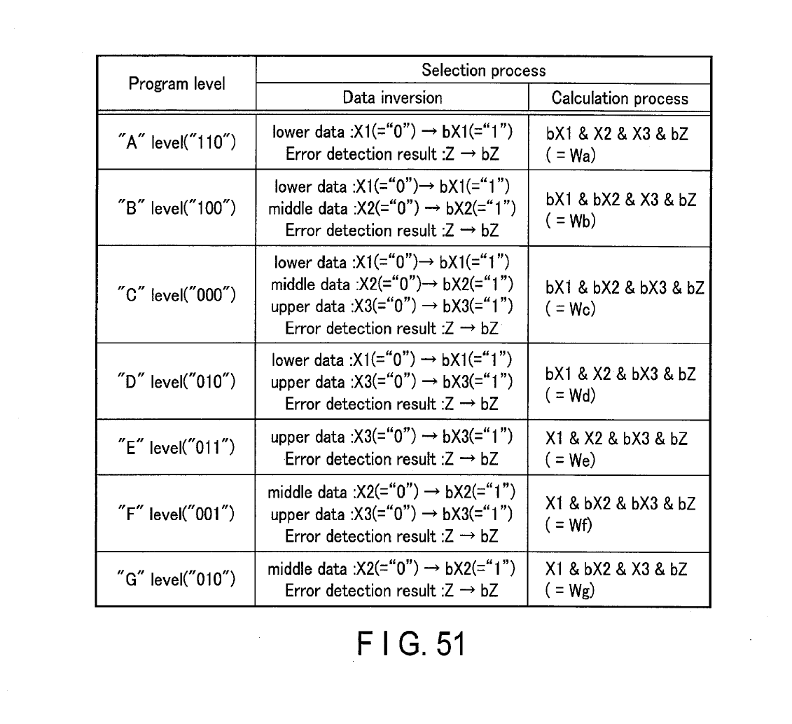

FIG. 51 is a diagram illustrating a calculation process to detect memory cells including an error at each level.

As shown in FIG. 51, also regarding memory cells from the “C” level to the “G” level, among memory cells of each level, memory cells including an error bit are detected by a calculation process similar to that of the “A” and “B” levels. Reprogramming of the program voltage Vpgm(VPCt, VPDt, . . . , VPGMt) appropriate for programming of each level is selectively performed for detected memory cells in each period PRDC, PRDD, PRDE, PRDF, PRDG.

In memory cells of the “C” level, the inverted data bX1, bX2, bX3 of data in the latch circuits ADL, BDL, CDL is used for a calculation process. Also, the inverted data bZ of data in the latch circuit DDL is used for a calculation process. Error cells of the “C” level are selected by the calculation process of “bX1&bX2&bX3&bZ”.

In memory cells of the “D” level, the inverted data bX2, bX3 of data in the latch circuits ADL, CDL is used for a calculation process. Also, the inverted data bZ of data in the latch circuit DDL is used for a calculation process. Accordingly, the calculation process of “bX1&X2&bX3&bZ” is performed to select error cells of the “D” level.

In memory cells of the “E” level, the inverted data bX3 of data in the latch circuit CDL is used for a calculation process. Also, the inverted data bZ of the latch circuit DDL is used for a calculation process. The calculation process of “X1&X2&bX3&bZ” is performed to select error cells of the “E” level.

In memory cells of the “F” level, the inverted data bX2, bX3 of data in the latch circuits BDL, CDL is used for a calculation process. The inverted data bZ of data in the latch circuit DDL for pre-verification of the “E” level is used for a calculation process. The calculation process of “X1&bX2&bX3&bZ” is performed to select error cells of the “F” level.

In memory cells of the “G” level, the inverted data bX2 of data in the latch circuit BDL is used for a calculation process. The inverted data bZ of data in the latch circuit DDL during pre-verification of the “F” level is used for a calculation process. The calculation process of “X1&bX2&X3&bZ” is performed to select error cells of the “G” level.

With the above determination process, memory cells including an error at each level are detected and programming of each level is selectively performed for memory cells including an error.

Therefore, in the second example of the operation example of the memory system according to the present embodiment, like in the first example, memory cells including an error are detected using corrected data and the result of a pre-verify operation during background operation or read operation and data to be held is rewritten into the memory cells including an error.

With the operation in FIGS. 49 to 51, the memory system according to the present embodiment can omit program verification. Therefore, the memory system according to the present embodiment can shorten the period for a rewrite operation. As a result, the memory system according to the present embodiment can suppress degradation of data transfer efficiency caused by the rewrite operation.

### (5a-3) Third Example

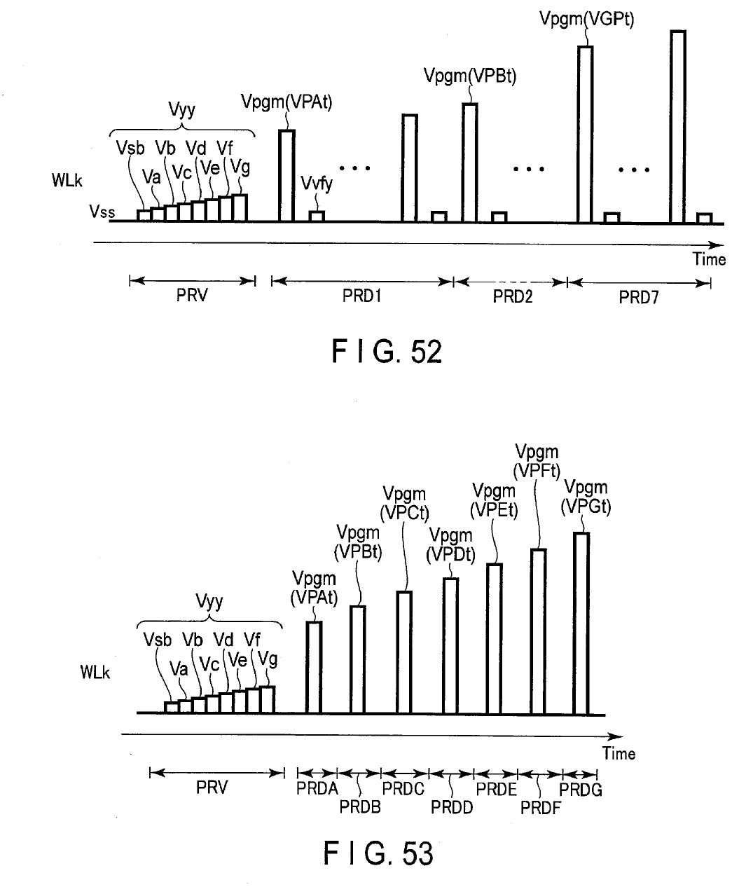

A third example of the operation example of the memory system according to the present embodiment will be described with reference to FIGS. 52 and 53.

The present example is different from the first and second examples in the verify level used for pre-verify operation during rewrite operation of the memory system.

FIG. 52 is a timing chart schematically showing an overall flow of the rewrite operation of the flash memory.

As shown in FIG. 52, the pre-verify voltage Vyy is applied to the selected word line WLk during pre-verify operation.

As the pre-verify level included in the pre-verify voltage Vyy, a voltage value (soft bit level) Vsb used for soft bit determination may also be used. The pre-verify level Vsb is a voltage value used to obtain threshold voltage information of memory cells of the “Er”/“A” level in the soft bit determination.

The value of the verify level Vsb is lower than the value of the pre-verify level Va of the “A” level. For example, the value of the verify level Vsb is higher than the reading level VARt of the “A” level.

A plurality of soft bit levels may be included in the pre-verify voltage Vyy as a plurality of pre-verify levels Vsb.

An error detection process using the result of the pre-verify level Vsb is substantially the same as the process shown in FIGS. 35 to 39.

If the memory cell MT of the “Er” level is turned on by applying the pre-verify level Vsb, the memory cell MT is normal concerning the pre-verify level Vsb. In this case, “0” data is stored in the latch circuit DDL corresponding to memory cells in an on state.

If the memory cell of the “Er” level is turned off by applying the pre-verify level Vsb, the memory cell MT is in error concerning the pre-verify level Vsb. In this case, “1” data is stored in the latch circuit DDL corresponding to memory cells in an off state.

Like the above example, in memory cells of the “Er” level turned off by the pre-verify level Vsb, an error of data is converted by reprogramming of the “E” level or the “G” level.

Memory cells turned on by the pre-verify level Vsb are not reprogrammed. That is, in the memory cell MT turned on by the pre-verify level Vsb, an error of data is not corrected by reprogramming and is corrected by the soft bit determination during read operation.

Memory cells of the “Er” level to be reprogrammed are identified by, like the above example, the AND operation (X1&X2&X3&Y) of non-inverted data of the latch circuits ADL, CDL, BDL, SDL. Data conversion of the latch circuits ADL, CDL, BDL for reprogramming is also performed by, like the above example, a calculation process using the data Z held in the latch circuit DDL.

FIG. 53 is a diagram showing a modification of the rewrite operation in FIG. 52.

As shown in FIG. 52, after performing a pre-verify operation using the pre-verify voltage Vyy including the soft bit level Vsb, a reprogram operation of each level may continuously be performed without program verification.

The reprogram operation of each level is substantially the same as the example described using FIGS. 46 to 48.

In the present example, as described above, the determination level in the soft bit determination is used as one determination level of the pre-verify operation.

The memory system in the present example can detect, based on the determination level of the soft bit determination, memory cells that can read data (and correct data) by the soft bit determination.

If, like the present example, data can be corrected by the soft bit determination in error cells, the memory system according to the present embodiment does not perform reprogramming of data for error cells. Thus, the memory system according to the present embodiment can detect and correct errors more efficiently than when data of memory cells is rewritten by preferentially correcting errors that can be corrected by the soft bit determination through the ECC process of the controller.

Therefore, in the present example, the memory system according to the present embodiment can make operations more efficient.

### (5b) Summary

A memory system according to the present embodiment includes a flash memory of TLC.

The memory system according to the present embodiment detects memory cells including an error in a flash memory by using the result of an ECC process on data read from the flash memory of TLC.

The memory system according to the present embodiment performs a rewrite operation for memory cells including a detected error. Accordingly, the memory system according to the present embodiment converts an error bit and corrects an error for memory cells.

Therefore, the memory system according to the present embodiment can improve reliability of data and upgrade operation characteristics.

### (6) Modification

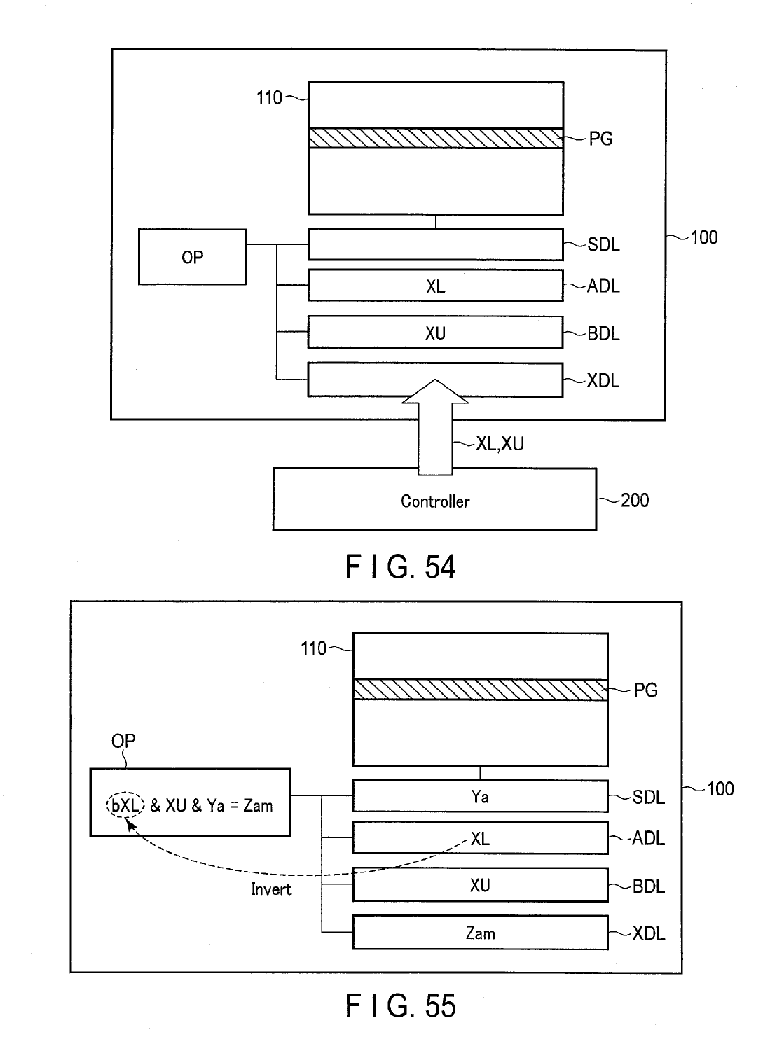

A modification of the memory system according to an embodiment will be described with reference to FIGS. 54 to 57.

The memory system according to an embodiment may correct an error of memory cells caused by the fall of the threshold voltage based on the result of an ECC process of data read from the flash memory without error conversion process of memory cells of the “Er” level.

FIGS. 54 to 57 are diagrams illustrating an operation example when the memory system according to the present modification includes a flash memory of MLC.

Reliability of data read from the flash memory of MLC is evaluated in the same manner as the process in FIG. 34. If reliability of data does not meet a desired standard, data for two pages allocated to a certain word line is read and an ECC process is performed on the data.

As shown in FIG. 54, the controller 200 sends error-corrected data for two pages to the flash memory 100 of MLC. Corrected data XL, XU is stored in the latch circuits ADL, BDL in the flash memory 100.

After the corrected data XL, XU is stored in the latch circuits ADL, BDL, a pre-verify operation is performed.

Like FIG. 35 (or FIG. 48) described above, the pre-verify voltage Vyy is applied to the selected word line WLk. In the flash memory 100 of MLC, the pre-verify voltage Vyy includes a pre-verify level of the “A” level, a pre-verify level of the “B” level, and a pre-verify level of the “C” level.

As shown in FIG. 55, the pre-verify level of the “A” level is applied and a pre-verify result Ya of the “A” level is stored in the latch circuit SDL.

The operation section OP performs an AND operation (XL&bXU&Ya) using the data XL, inverted data bXU of the data XU, and the pre-verify result Ya.

A result Zam of the AND operation is stored in the latch circuit (for example, the latch circuit XDL). If, for example, the result Zam is “1” concerning an error detection result of the “A” level, the result indicates an error of data of memory cells. If the result Zam is “0”, by contrast, the result indicates that data of memory cells is normal.

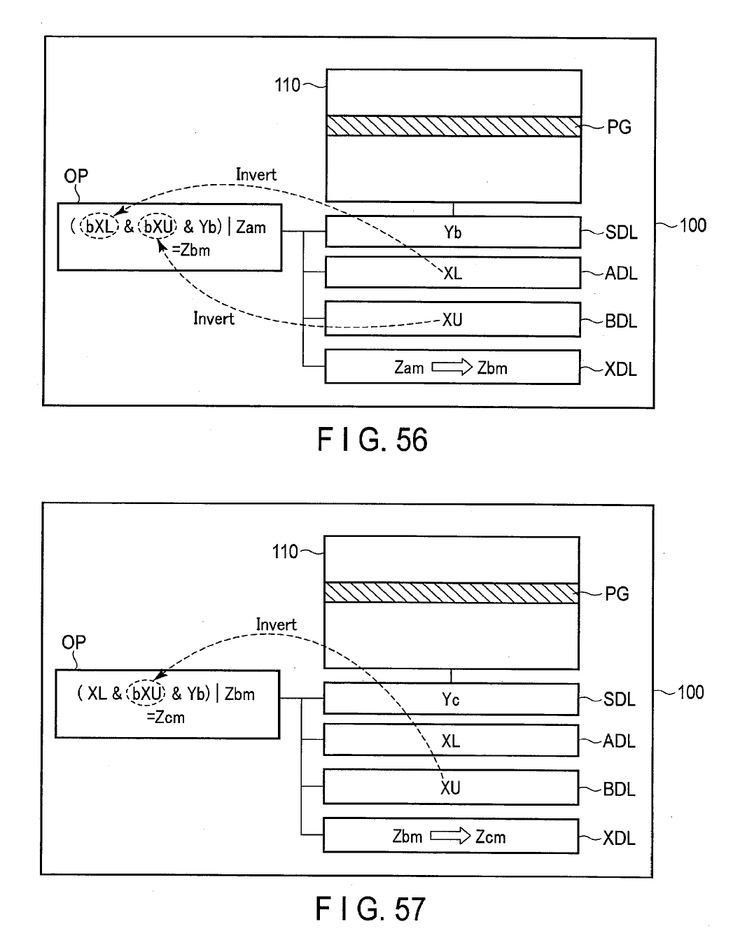

As shown in FIG. 56, the pre-verify level of the “B” level is applied to the selected word line WLk and a pre-verify result Yb of the “B” level is stored in the latch circuit SDL.

The operation section OP performs an AND operation (bXL&bXU&Yb) using inverted data bXL of the data XL, the inverted data bXU of the data XU, and the pre-verify result Yb.

The operation section OP performs an OR operation of the result of the AND operation and the data Zam in the latch circuit XDL. The result of the OR operation is stored in the latch circuit XDL as a detection result Zbm.

Regarding the error detection result of the “B” level, the result Zbm of “1” indicates that data of memory cells is in error and the result Zbm of “0” indicates that data of memory cells is normal.

As shown in FIG. 57, the pre-verify level of the “C” level is applied to the selected word line WLk and a pre-verify result Yc of the “C” level is stored in the latch circuit SDL.

The operation section OP performs an AND operation (bXL&XU&Yc) using the inverted data bXL of the data XL, the data XU, and the pre-verify result Yc. The operation section OP performs an OR operation (bXL&XU&Yc|Zbm) of the result of the AND operation and the data Zbm in the latch circuit XDL. The result of the OR operation is stored in the latch circuit XDL as a detection result Zcm of an error cell.

Regarding the error detection result of the “C” level, the result Zcm of “1” indicates that data of memory cells is in error and the result Zcm of “0” indicates that data of memory cells is normal.

Like in the fifth embodiment, when an error of a memory cell of a certain level is detected, at least one piece of data used for an AND operation is “0” in the sense amplifier unit SAU corresponding to levels other than the level intended for error detection. If data in the latch circuit XDL is “0”, the calculation result is “0”. If data in the latch circuit XDL is “1”, the calculation result is “1”. Thus, data in the latch circuit XDL holding the result of pre-verification is held constant in value in the sense amplifier unit SAU corresponding to levels other than the level intended for error detection even if an OR operation is performed.

After the pre-verify operation is completed, data of the latch circuit XDL of each sense amplifier unit SAU is inverted by the operation section OP. Accordingly, the final result Z in detection of error cells at each level is determined. The determined result Z may be transferred from the latch circuit XDL to the latch circuit SDL.

Then, a reprogram operation is performed based on the calculation result Z (bZ) in substantially the same manner as the example described using FIG. 35. In the present modification, the potential (charge and discharge) of the bit line BL when the program voltage is applied is controlled by a calculation process using the result Z stored in a latch circuit.

Incidentally, the program verification may be omitted during reprogram operation. When no program verification is performed, like the process similar to that described using FIGS. 45 to 48, reprogramming for each level is performed based on a calculation result of non-inversion/inversion data of the latch circuits ADL, BDL and the result (data of the latch circuit XDL) of pre-verification using the program voltage of each level.

Also when a pre-verify operation and a reprogram operation in the flash memory of MLC are performed, the pre-verify voltage Vyy may include a determination level to read threshold voltage information of the “Er” level in a soft bit determination.

A memory system including the flash memory of TLC can correct only errors caused by the fall of the threshold voltage by a process using FIGS. 41 to 53 being performed without the error conversion process (FIGS. 37 to 40) of memory cells of the “Er” level.

As described above, a memory system according to the present modification can improve reliability of data.

### (5) Others

In each of the above embodiments, examples that level error bits caused by the rise of the threshold voltage of memory cells of the erase level have been described.

In the present embodiment, however, a conversion process of pages including an error may be performed by a program operation for error bits in which the threshold voltage of memory cells of levels other than the erase level rises to the voltage value of another level.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory system comprising:
a memory device including a first memory cell, the first memory cell capable of storing a piece of data among first data, second data, and third data, each piece of the first to third data including a first bit and a second bit, the first data having the first and second bits set to a first value, the second data having the first bit set to a second value different from the first value and the second bit set to the first value, and the third data having the first bit set to the first value and the second bit set to the second value; and
a controller configured to control the memory device,
wherein
a threshold voltage of the first memory cell storing the first data has a first voltage,
the threshold voltage of the first memory cell storing the second data has a second voltage, and
the threshold voltage of the first memory cell storing the third data has a third voltage,
when the threshold voltage of the first memory cell into which the first data is programmed is higher than a first determination level between the first voltage and the second voltage, the memory device programs the third data to the first memory cell.

2. The system of claim 1, wherein
the memory device converts a bit where an error in data held by the first memory cell occurs from the first bit into the second bit.

3. The system of claim 1, wherein
a plurality of memory cells including the first memory cell is connected to a word line,
the first bit belongs to a first access unit of the plurality of memory cells allocated to the word line and the second bit belongs to a second access unit of the plurality of memory cells allocated to the word line, and
a frequency of occurrence of errors in data read in the first access unit is higher than that of errors in data read in the second access unit.

4. The system of claim 1, wherein
the second voltage is higher than the first voltage and the third voltage is higher than the second voltage.

5. The system of claim 1, wherein
detection of the first memory cell having the threshold voltage equal to the second voltage or more is carried out when data is programmed into the memory device.

6. The system of claim 5, wherein
the memory device further includes a second memory cell and a third memory cell,
programming of the third data into the third memory cell is performed after programming of the second data into the second memory cell is performed,
the detection is carried out before the third data is programmed, and
the threshold voltage of the first memory cell is changed to the third voltage simultaneously with the programming of the third data.

7. The system of claim 5, wherein
the detection is carried out after programming of data into the memory device is completed, and
based on a result of the detection, an operation to program the third data to the first memory cell is performed.

8. The system of claim 7, wherein
the memory device further includes a second memory cell,
the third data is programmed into a second memory cell,
the second memory cell having a threshold voltage smaller than the third voltage is further detected by the detection, and
based on the result of the detection, the threshold voltage of the second memory cell having the threshold voltage smaller than the third voltage is set to the third voltage by the operation.

9. The system of claim 5, wherein
the detection is carried out by using a first determination voltage between the first voltage and the second voltage.

10. The system of claim 1, wherein
detection of the first memory cell having the threshold voltage equal to the second voltage or more is carried out when data is read from the memory device.

11. The system of claim 10, wherein
the controller reads data from the memory device to generate corrected data in which an error of the data read is corrected,
the detection is carried out based on the corrected data, and
based on a result of the detection, first programming is performed for the first memory cell having the threshold voltage equal to the second voltage or more to change the threshold voltage of the first memory cell to the third voltage.

12. The system of claim 11, wherein
the memory device includes a data holding circuit that holds data read from the first memory cell, and
the detection is carried out by a calculation process using the corrected data and the data in the data holding circuit.

13. The system of claim 12, wherein
the memory device further includes a second memory cell,
before the data is read, the third data is programmed into the second memory cell,
the second memory cell having the threshold voltage smaller than the third voltage is further detected by the detection, and
based on the result of the detection, the first programming is performed for the second memory cell having the threshold voltage smaller the third voltage to set the threshold voltage of the second memory cell to the third voltage.

14. The system of claim 11, wherein
before the first programming, first verification to verify the threshold voltage of the first memory cell is performed and
the detection is carried out by a calculation process of the result of the first verification and the corrected data.

15. The system of claim 14, wherein
the memory device further includes a second memory cell,
before the data is read, the second data is programmed into the second memory cell,
before the first programming, second verification to verify the threshold voltage of the second memory cell is performed,
the detection further includes the calculation process of the result of the second verification and the corrected data, and
based on the result of the detection, second programming is performed for the second memory cell having the threshold voltage smaller the second voltage to set the threshold voltage of the second memory cell to the second voltage.

16. The system of claim 15, wherein
the first programming and the second programming are continuous.

17. The system of claim 14, wherein
the memory device further includes a second memory cells,
before the data is read, the third data is programmed into the second memory cell,
before the first programming, third verification to verify the threshold voltage of the second memory cell is performed,
the detection further includes the calculation process of the result of the third verification and the corrected data, and
based on the result of the detection, the first programming is performed for the second memory cell having the threshold voltage smaller the third voltage to set the threshold voltage of the second memory cell to the third voltage.

18. The system of claim 14, wherein
reading of the data includes:
first reading to distinguish the first data and the second data using a first determination voltage between the first voltage and the second voltage and
second reading to distinguish the first data and the second data based on information concerning the threshold voltage of the first memory cells determined by using a second determination voltage,
the second determination voltage is smaller than the first determination voltage, and
the first verification is performed by using the first determination level and the second determination level.

19. The system of claim 1, wherein
the memory device is a flash memory and
the first voltage corresponds to an erase state of the memory cell.

20. A memory device comprising:
a memory cell connected to a word line; and
a control circuit configured to control the memory cell,
wherein
a first program voltage is applied to the word line,
a first determination voltage including in a first determination value is applied to the word line after the first program voltage is applied to the word line,
a second determination voltage including a second determination value lower than the first determination value is applied to the word line after the first determination voltage is applied to the word line, and
a second program is applied to the word line after the second determination voltage is applied to the word line.
